(19) United States
(12) Patent Application Publication
(10) Pub. No.: US 2023/0236502 A1
(43) Pub. Date: Jul. 27, 2023

(54) ACTINIC RAY-SENSITIVE OR RADIATION-SENSITIVE RESIN COMPOSITION, RESIST FILM, PATTERN FORMING METHOD, AND METHOD FOR MANUFACTURING ELECTRONIC DEVICE

(71) Applicant: FUJIFILM Corporation, Tokyo (JP)

(72) Inventors: Masafumi KOJIMA, Haibara-gun (JP); Aina Ushiyama, Haibara-gun (JP); Yosuke Bekki, Haibara-gun (JP); Akiyoshi Goto, Haibara-gun (JP); Michihiro Shirakawa, Haibara-gun (JP)

(73) Assignee: FUJIFILM Corporation, Tokyo (JP)

(21) Appl. No.: 18/185,115

(22) Filed: Mar. 16, 2023

Related U.S. Application Data
(63) Continuation of application No. PCT/JP2021/032833, filed on Sep. 7, 2021.

(30) Foreign Application Priority Data
Sep. 24, 2020 (JP) 2020-159972

(51) Int. Cl. G03F 7/021; G03F 7/031; G03F 7/00; G03F 7/20; G03F 7/32

(52) U.S. Cl. CPC G03F 7/0217; G03F 7/031; G03F 7/0035; G03F 7/2002; G03F 7/32; G03F 7/0015

(57) ABSTRACT

The present invention provides an actinic ray-sensitive or radiation-sensitive resin composition capable of obtaining a pattern having a good shape, a resist film, a pattern forming method, and a method for manufacturing an electronic device. The actinic ray-sensitive or radiation-sensitive resin composition of an embodiment of the present invention includes a salt including a cation represented by Formula (X) and a resin of which polarity increases through decomposition by the action of an acid.

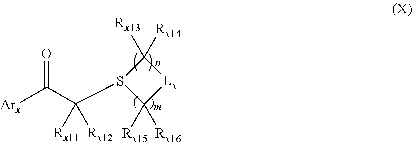

### CROSS-REFERENCE TO RELATED APPLICATIONS

This application is a Continuation of PCT International Application No. PCT/JP2021/032833 filed on Sep. 7, 2021, which claims priority under 35 U.S.C. § 119(a) to Japanese Patent Application No. 2020-159972 filed on Sep. 24, 2020. The above applications are hereby expressly incorporated by reference, in their entirety, into the present application.

### BACKGROUND OF THE INVENTION

### 1. Field of the Invention

The present invention relates to an actinic ray-sensitive or radiation-sensitive resin composition, a resist film, a pattern forming method, and a method for manufacturing an electronic device.

### 2. Description of the Related Art

Since the advent of a resist for KrF excimer laser (light at a wavelength of 248 nm), a pattern forming method utilizing chemical amplification has been used in order to compensate for a decrease in sensitivity due to light absorption. For example, in a positive tone chemical amplification method, first, a photoacid generator included in the exposed portion decomposes upon irradiation with light to generate an acid. Then, in a post-exposure baking (PEB) step and the like, a solubility in a developer changes by, for example, changing an alkali-insoluble group contained in a resin included in an actinic ray-sensitive or radiation-sensitive resin composition to an alkali-soluble group by the catalytic action of an acid thus generated. Thereafter, development is performed using a basic aqueous solution, for example. As a result, the exposed portion is removed to obtain a desired pattern.

For miniaturization of semiconductor elements, the wavelength of an exposure light source has been shortened and a projection lens with a high numerical aperture (high NA) has been advanced, and currently, an exposure machine using an ArF excimer laser having a light at a wavelength of 193 nm as a light source is under development. In addition, in recent years, a pattern forming method using extreme ultraviolet rays (EUV light) and an electron beam (EB) as a light source has also been studied. Under such circumstances, various configurations have been proposed as the resist composition.

For example, JP2019-014704A discloses a salt represented by Formula (I) as a component included in an actinic ray-sensitive or radiation-sensitive resin composition.

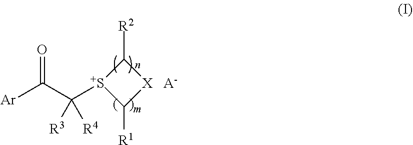

### SUMMARY OF THE INVENTION

The present inventors have conducted studies on the actinic ray-sensitive or radiation-sensitive resin composition described in JP2019-014704A, and have thus found that a pattern formed using the actinic ray-sensitive or radiation-sensitive resin composition easily has a non-rectangular cross-sectional shape (tapered shape). Specifically, in a case where in a pattern after development, a pattern line width at the bottom of the pattern is taken as Lb and a pattern line width at the top of the pattern is taken as La, it was found that a value of La/Lb is excessive in a case of a positive tone development, and Lb/La is excessive in a case of a negative tone development. That is, the present inventors have found that there is room for further improvement (further rectangularization) of the shape of a pattern.

Therefore, an object of the present invention is to provide an actinic ray-sensitive or radiation-sensitive resin composition with which a pattern having a good shape can be obtained.

Moreover, another object of the present invention is to provide a resist film, a pattern forming method, and a method for manufacturing an electronic device, each relating to the actinic ray-sensitive or radiation-sensitive resin composition.

The present inventors have found that the objects can be accomplished by the following configurations.

[1] An actinic ray-sensitive or radiation-sensitive resin composition comprising:

a salt including a cation represented by Formula (X) which will be described later; and

a resin of which polarity increases through decomposition by an action of an acid.

[2] The actinic ray-sensitive or radiation-sensitive resin composition as described in [1],

in which in Formula (X), Ar_{X} is an aryl group substituted with a group selected from the group consisting of a group including a fluorine atom and a group including an iodine atom.

[3] The actinic ray-sensitive or radiation-sensitive resin composition as described in [1] or [2],

in which in Formula (X), L_{X} is a divalent linking group including an oxygen atom.

[4] The actinic ray-sensitive or radiation-sensitive resin composition as described in any one of [1] to [3],

in which in Formula (X), at least one of R_{X11}, . . . , or R_{X12} is a hydrocarbon group.

[5] The actinic ray-sensitive or radiation-sensitive resin composition as described in any one of [1] to [4],

in which the salt including the cation represented by Formula (X) is at least one selected from the group consisting of the compounds (I) and (II),

compound (I):

a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation,

structural site X: a structural site which consists of an anionic site A₁⁻ and a cationic site M₁⁺, and forms a first acidic site represented by HA₁ upon irradiation with actinic rays or radiation,

structural site Y: a structural site which consists of an anionic site A₂ and a cationic site M₂⁺, and forms a second acidic site represented by HA₂ upon irradiation with actinic rays or radiation,

provided that at least one of the cationic site M₁⁺ in one or more structural sites X or the cationic site M₂⁺ in one or more structural sites Y represents the cation represented by Formula (X),

in addition, the compound (I) satisfies the following condition I,

condition I: a compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1,

compound (II):

a compound having two or more sites of the structural site X and one or more sites of the following structural site Z, the compound generating an acid including a compound that generates an acid including two or more sites of the first acidic site derived from the structural site X and the structural site Z upon irradiation with actinic rays or radiation,

structural site Z: a nonionic site capable of neutralizing an acid,

provided that at least one of the cationic sites M₁⁺ in the two or more structural sites X represents a cation represented by Formula (X).

[6] The actinic ray-sensitive or radiation-sensitive resin composition as described in any one of [1] to [5],

in which the resin of which polarity increases through decomposition by the action of an acid includes an acid group.

[7] The actinic ray-sensitive or radiation-sensitive resin composition as described in any one of [1] to [6],

in which the resin of which polarity increases through decomposition by the action of an acid includes a repeating unit having an acid group.

[8] The actinic ray-sensitive or radiation-sensitive resin composition as described in any one of [1] to [7], further comprising a solvent.

[9] A resist film formed of the actinic ray-sensitive or radiation-sensitive resin composition as described in any one of [1] to [8].

[10] A pattern forming method comprising:

a step of forming a resist film on a substrate using the actinic ray-sensitive or radiation-sensitive resin composition as described in any one of [1] to [8];

a step of exposing the resist film; and

a step of developing the exposed resist film using a developer.

[11] A method for manufacturing an electronic device, comprising the pattern forming method as described in [10].

According to the present invention, it is possible to provide an actinic ray-sensitive or radiation-sensitive resin composition with which a pattern having a good shape can be obtained.

In addition, according to the present invention, it is possible to provide a resist film, a pattern forming method, and a method for manufacturing an electronic device, each relating to the actinic ray-sensitive or radiation-sensitive resin composition.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

In notations for a group (atomic group) in the present specification, in a case where the group is noted without specifying whether it is substituted or unsubstituted, the group includes both a group having no substituent and a group having a substituent as long as this does not impair the spirit of the present invention. For example, an “alkyl group” includes not only an alkyl group having no substituent (unsubstituted alkyl group), but also an alkyl group having a substituent (substituted alkyl group). In addition, in the present specification, an “organic group” refers to a group including at least one carbon atom.

The substituent is preferably a monovalent substituent unless otherwise specified.

In the present specification, “actinic rays” or “radiation” means, for example, a bright line spectrum of a mercury lamp, far ultraviolet rays typified by an excimer laser, extreme ultraviolet rays (EUV light), X-rays, and an electron beam (EB).

In the present specification, “light” means actinic rays or radiation.

In the present specification, unless otherwise specified, “exposure” encompasses not only exposure by a bright line spectrum of a mercury lamp, far ultraviolet rays typified by an excimer laser, extreme ultraviolet rays (EUV light), X-rays, or the like, but also lithography by particle beams such as electron beams and ion beams.

In the present specification, a numerical range expressed using “to” is used in a meaning of a range that includes the preceding and succeeding numerical values of “to” as the lower limit value and the upper limit value, respectively.

In the present specification, a bonding direction of a divalent group noted is not limited unless otherwise specified. For example, in a case where Y in a compound represented by Formula “X—Y—Z” is —COO—, Y may be —CO—O— or —O—CO—. In addition, the compound may be “X—CO—O—Z” or may be “X—O—CO—Z”.

In the present specification, (meth)acrylate represents acrylate and methacrylate, and (meth)acryl represents acryl and methacryl.

In the present specification, a weight-average molecular weight (Mw), a number-average molecular weight (Mn), and a dispersity (hereinafter also referred to as a “molecular weight distribution”) (Mw/Mn) are defined as values expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

In the present specification, an acid dissociation constant (pKa) represents a pKa in an aqueous solution, and is specifically a value determined by computation from a value based on a Hammett's substituent constant and database of publicly known literature values, using the following software package 1. Any of the pKa values described in the present specification indicate values determined by computation using the software package.
Software Package 1: Advanced Chemistry Development (ACD/Labs) Software V 8.14 for Solaris (1994-2007 ACD/Labs).

In addition, the pKa can also be determined by a molecular orbital computation method. Examples of a specific method therefor include a method for performing calculation by computing H⁺ dissociation free energy in an aqueous solution based on a thermodynamic cycle. With regard to a computation method for H⁺ dissociation free energy, the H⁺ dissociation free energy can be computed by, for example, density functional theory (DFT), but various other methods have been reported in literature and the like, and are not limited thereto. Furthermore, there are a plurality of software applications capable of performing DFT, and examples thereof include Gaussian 16.

In the present specification, as described above, the pKa refers to a value determined by computation from a value based on a Hammett's substituent constant and database of publicly known literature values, using the software package 1, but in a case where the pKa cannot be calculated by the method, a value obtained by Gaussian 16 based on density functional theory (DFT) shall be adopted.

In addition, in the present specification, the pKa refers to a “pKa in an aqueous solution” as described above, but in a case where the pKa in an aqueous solution cannot be calculated, a “pKa in a dimethyl sulfoxide (DMSO) solution” shall be adopted.

[Actinic Ray-Sensitive or Radiation-Sensitive Resin Composition]

The actinic ray-sensitive or radiation-sensitive resin composition (hereinafter also referred to as a “resist composition”) of an embodiment of the present invention includes a salt (hereinafter also referred to as a “compound (X)”) including a cation represented by Formula (X) (hereinafter also referred to as a “specific cation”), and a resin of which polarity increases through decomposition by the action of an acid (hereinafter also referred to as an “acid-decomposable resin” or a “resin (A)”).

Examples of features of the resist composition of the embodiment of the present invention include a fact that the composition includes the compound (X), and thus, a pattern having a good shape can be obtained by the configuration.

Although the details of mechanism by which a desired effect is obtained in a case where the resist composition of the embodiment of the present invention is used are not clear, the present inventors have speculated as follows.

The compound (X) is a salt including a specific cation and usually acts as a photoacid generator. Alternatively, in the compound (X), the specific cation has an aryl group substituted with a group including a halogen atom. The present inventors have speculated that such a compound (X) hardly diffuses within the resist film after exposure due to an interaction between a proton of an acid generated and an aryl group substituted with a group including a halogen atom (in particular, a group including a halogen atom), and as a result, a cross-sectional shape of a pattern thus formed is rectangularized.

Hereinafter, in the present specification, a capability of obtaining a pattern having a better shape can also be expressed as the effect of the present invention being excellent.

Hereinafter, the resist composition of the embodiment of the present invention will be described in detail.

The resist composition may be either a positive tone resist composition or a negative tone resist composition. In addition, the resist composition may be either a resist composition for alkali development or a resist composition for organic solvent development.

The resist composition is typically a chemically amplified resist composition.

Hereinbelow, various components of the resist composition will first be described in detail.

[Photoacid Generator]

The resist composition includes the compound (X).

The compound (X) functions a compound that generates an acid upon irradiation with actinic rays or radiation (photoacid generator).

Furthermore, the resist composition may further include another photoacid generator (hereinafter also referred to as a “photoacid generator (B)”) other than the compound (X) as described later.

First, the compound (X) will be described below.

<Compound (X)>

The compound (X) is a salt including a specific cation.

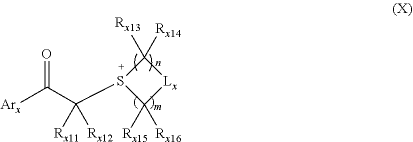

In Formula (X), Ar_{X} represents an aryl group substituted with a group including a halogen atom.

The aryl group represented by Arₓ may be a monocycle or a polycycle. In addition, the aryl group may be a heterocyclic ring including an oxygen atom, a nitrogen atom, a sulfur atom, or the like.

Examples of the heterocyclic ring include a pyrrole ring, a furan ring, a thiophene ring, an indole ring, a benzofuran ring, and a benzothiophene ring.

The number of carbon atoms of the aryl group (the number of carbon atoms of Ar_{X}) is preferably 6 to 20, more preferably 6 to 15, and still more preferably 6 to 10.

The group including a halogen atom means a halogen atom itself or a group including a halogen atom as a part of a substituent.

Examples of the halogen atom include a fluorine atom, a chlorine atom, a bromine atom, and an iodine atom, and the fluorine atom or the iodine atom is preferable.

Examples of the group including a halogen atom include a halogen atom, an alkyl halide group, an alkoxy halide group, and an aryl halide group.

The number of the halogen atoms contained in the aryl group is preferably 1 to 20, more preferably 1 to 15, and still more preferably 1 to 10.

The number of the groups including a halogen atom contained in the aryl group is preferably 1 to 10, more preferably 1 to 5, and still more preferably 1 to 3.

The aryl group may be further substituted with a group including no halogen atom, in addition to the group including a halogen atom. As the group including no halogen atom, an alkyl group (preferably having 1 to 6 carbon atoms), an alkoxy group, or an alkoxycarbonyl group is preferable, and the alkyl group (preferably having 1 to 6 carbon atoms) or the alkoxy group (preferably having 1 to 6 carbon atoms) is more preferable.

As the aryl group, a phenyl group or a naphthyl group is preferable, and the phenyl group is more preferable.

R_{X11} to R_{X16} each independently represent a hydrogen atom or a hydrocarbon group.

It is preferable that at least one of R_{X11} or R_{X12} is the hydrocarbon group. R_{X13} to R_{X16} each preferably represent the hydrogen atom.

The hydrocarbon group may be linear, branched, or cyclic.

Examples of the hydrocarbon group include an alkyl group, a cycloalkyl group, an alkenyl group, and an aryl group, and the alkyl group is preferable.

The hydrocarbon group preferably has 1 to 20 carbon atoms, more preferably has 1 to 10 carbon atoms, and still more preferably has 1 to 5 carbon atoms.

R_{X11} and R_{X12} may be bonded to each other to form a ring, and R_{X11} and at least one of R_{X13}, . . . , or R_{X16}, or R_{X12} and at least one of R_{X13}, . . . , or R_{X16} may be bonded to each other to form a ring.

n and m each independently represent an integer of 1 or more.

n and m are preferably an integer of 1 to 10, more preferably an integer of 1 to 5, still more preferably an integer of 1 to 3, and particularly preferably 2. In addition, it is preferable that n and m represent the same integer.

In a case where n represents an integer of 2 or more, two or more R_{X13}'s and two or more R_{X14}'s may be the same as or different from each other. In addition, in a case where m represents an integer of 2 or more, two or more R_{X15}'s and two or more R_{X16}'s may be the same as or different from each other.

L_{X} represents a divalent linking group.

Examples of the divalent linking group include —CO—, —NR_{A}—, —O—, —S—, —SO—, —SO₂—, —N(SO₂—R_{A})—, an alkylene group, a cycloalkylene group, an alkenylene group, and a divalent linking group formed by combination of a plurality of these groups, and the divalent linking group is preferably a divalent linking group including an oxygen atom.

Examples of the divalent linking group including an oxygen atom include —CO—, —O—, —SO—, —SO₂—, —N(SO₂—R_{A})—, and a divalent linking group formed by combination of a plurality of these groups. Examples of R_{A} include a hydrogen atom or an alkyl group having 1 to 6 carbon atoms.

Among those, as the divalent linking group including an oxygen atom, —O—, —CO—, or —N(SO₂—R_{A})— is preferable, and —O— or —CO— is more preferable.

The divalent linking group including an oxygen atom means an oxygen atom itself and a divalent linking group including an oxygen atom as a part of the divalent linking group.

The number of oxygen atoms contained in the divalent linking group including an oxygen atom is preferably 1 to 3, more preferably 1 or 2, and still more preferably 1.

As the specific cation, a cation represented by Formula (X-1) is preferable.

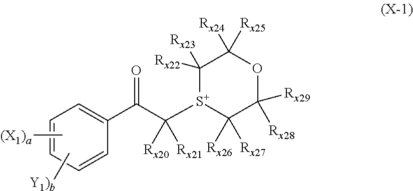

In Formula (X-1), X₁ represents a group including a halogen atom.

In Formula (X) mentioned above, X₁ has the same definition as the group including a halogen atom contained in Ar_{X}, and a suitable range thereof is also the same.

Y₁ represents a group including no halogen atom.

As the group including no halogen atom, an alkyl group (preferably having 1 to 6 carbon atoms), an alkoxy group, or an alkoxycarbonyl group is preferable, and the alkyl group (preferably having 1 to 6 carbon atoms) or the alkoxy group is more preferable.

The group including no halogen atom means a group including no halogen atom as a part of the substituent. That is, Y₁ represents a group other than the group including a halogen atom represented by X₁.

a represents an integer of 1 to 5, b represents an integer of 0 to 4, and a+b is 1 to 5.

a is preferably an integer of 1 to 4. b is preferably an integer of 1 to 4.

R_{X20} to R_{X29} each independently represent a hydrogen atom or a hydrocarbon group.

R_{X20} and R_{X21} have the same definitions as R_{X11} to R_{X12} in Formula (X) mentioned above, and suitable ranges thereof are also the same.

The hydrocarbon group represented by each of R_{X22} to R_{X29} may be linear, branched, or cyclic.

Examples of the hydrocarbon group represented by each of R_{X22} to R_{X29} include an alkyl group, a cycloalkyl group, an alkenyl group, and an aryl group, and the alkyl group is preferable.

The hydrocarbon group represented by each of R_{X22} to R_{X29} preferably has 1 to 20 carbon atoms, more preferably has 1 to 10 carbon atoms, and still more preferably has 1 to 5 carbon atoms.

R_{X20} and R_{X21} may be bonded to each other to form a ring, and R_{X20} and at least one of R_{X22}, . . . , or R_{X25}, or R_{X21} and at least one of R_{X26}, . . . , or R_{X29} may be bonded to each other to form a ring.

It is preferable that at least two of R_{X22}, . . . , or R_{X29} represent hydrogen atoms, it is more preferable that at least four of R_{X22}, . . . , or R_{X29} represent hydrogen atoms, and it is still more preferable that at least six of R_{X22}, . . . , or R_{X29} represent hydrogen atoms.

The specific cations may be used alone or in combination of two or more kinds thereof.

The compound (X) preferably includes an organic anion.

The organic anion is not particularly limited, and examples thereof include a monovalent or divalent or higher valent organic anion.

The organic anion is preferably an anion having a significantly low ability to cause a nucleophilic reaction, and more preferably a non-nucleophilic anion.

Examples of the non-nucleophilic anion include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, and a tris(alkylsulfonyl)methide anion.

The aliphatic site in the aliphatic sulfonate anion and the aliphatic carboxylate anion may be a linear or branched alkyl group or may be a cycloalkyl group, and has a linear or branched alkyl group having 1 to 30 carbon atoms, or is preferably a cycloalkyl group having 3 to 30 carbon atoms.

The alkyl group may be, for example, a fluoroalkyl group (which may have a substituent other than the fluorine atom, and may be a perfluoroalkyl group).

The aryl group in the aromatic sulfonate anion and the aromatic carboxylate anion is preferably an aryl group having 6 to 14 carbon atoms, and examples thereof include a phenyl group, a tolyl group, and a naphthyl group.

The alkyl group, the cycloalkyl group, and the aryl group exemplified above may have a substituent. The substituent is not particularly limited, but specific examples of the substituent include a nitro group, a halogen atom such as fluorine atom or a chlorine atom, a carboxyl group, a hydroxyl group, an amino group, a cyano group, an alkoxy group (preferably having 1 to 15 carbon atoms), an alkyl group (preferably having 1 to 10 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), and an aryloxysulfonyl group (preferably having 6 to 20 carbon atoms).

As the aralkyl group in the aralkylcarboxylate anion, an aralkyl group having 7 to 14 carbon atoms is preferable.

Examples of the aralkyl group having 7 to 14 carbon atoms include a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Examples of the substituent of such an alkyl group include a halogen atom, an alkyl group substituted with a halogen atom, an alkoxy group, an alkylthio group, an alkyloxysulfonyl group, an aryloxysulfonyl group, and a cycloalkylaryloxysulfonyl group, and a fluorine atom or an alkyl group substituted with the fluorine atom is preferable.

In addition, the alkyl groups in the bis(alkylsulfonyl)imide anion may be bonded to each other to form a ring structure. Thus, the acid strength increases.

Examples of the other non-nucleophilic anions include fluorinated phosphorus (for example, PF₆⁻), fluorinated boron (for example, BF₄⁻), and fluorinated antimony (for example, SbF₆⁻).

As the non-nucleophilic anion, an aliphatic sulfonate anion in which at least α-position of sulfonic acid is substituted with a fluorine atom, an aromatic sulfonate anion substituted with a fluorine atom or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom is preferable. Among these, a perfluoroaliphatic sulfonate anion (preferably having 4 to 8 carbon atoms) or a fluorine atom-containing benzenesulfonate anion is more preferable, and a nonafluorobutanesulfonate anion, a perfluorooctanesulfonate anion, a pentafluorobenzenesulfonate anion, or a 3,5-bis(trifluoromethyl)benzenesulfonate anion is still more preferable.

As the non-nucleophilic anion, an anion represented by Formula (AN1) is also preferable.

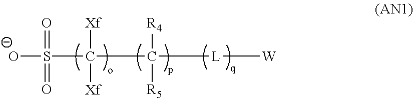

In Expression (AN1), o represents an integer of 1 to 3. p represents an integer of 0 to 10. q represents an integer of 0 to 10.

Xf represents a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf is preferably the fluorine atom or a perfluoroalkyl group having 1 to 4 carbon atoms, and more preferably the fluorine atom or CF₃, and it is still more preferable that both of Xf's are fluorine atoms.

R₄ and R₅ each independently represent a hydrogen atom, a fluorine atom, an alkyl group, or an alkyl group substituted with at least one fluorine atom. In a case where R₄'s and R₅'s are each present in plurality, R₄'s and R₅'s may each be the same as or different from each other.

The alkyl group represented by each of R₄ and R₅ preferably has 1 to 4 carbon atoms. The alkyl group may have a substituent. As each of R₄ and R₅, the hydrogen atom is preferable.

Specific examples and suitable aspects of the alkyl group substituted with at least one fluorine atom are the same ones as the specific examples and the suitable aspects of Xf in Formula (AN1), respectively.

L represents a divalent linking group.

In a case where L's are present in plurality, they may be the same as or different from each other.

Examples of the divalent linking group include —O—CO—O—, —COO—, —CONH—, —CO—, —O—, —S—, —SO—, —SO₂—, an alkylene group (preferably having 1 to 6 carbon atoms), a cycloalkylene group (preferably having 3 to 15 carbon atoms), an alkenylene group (preferably having 2 to 6 carbon atoms), and a divalent linking group formed by combination of a plurality of these groups. As the divalent linking group, among these, —O—CO—O—, —COO—, —CONH—, —CO—, —O—, —SO₂—, and —O—CO—O-alkylene group-, —COO-alkylene group-, or —CONH-alkylene group- is preferable, and —O—CO—O—, —O—CO—O-alkylene group-, —COO—, —CONH—, —SO₂—, or —COO-alkylene group-is more preferable.

W represents an organic group including a cyclic structure. Among those, W is preferably a cyclic organic group.

Examples of the cyclic organic group include an alicyclic group, an aryl group, and a heterocyclic group.

The alicyclic group may be a monocycle or a polycycle. Examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, and an adamantyl group, is preferable.

The aryl group may be a monocycle or a polycycle. Examples of the aryl group include a phenyl group, a naphthyl group, a phenanthryl group, and an anthryl group.

The heterocyclic group may be a monocycle or a polycycle. Among those, in a case of a polycyclic heterocyclic group, diffusion of an acid can be further suppressed. Furthermore, the heterocyclic group may have aromaticity or may not have aromaticity. Examples of the heterocyclic ring having aromaticity include a furan ring, a thiophene ring, a benzofuran ring, a benzothiophene ring, a dibenzofuran ring, a dibenzothiophene ring, and a pyridine ring. Examples of the heterocyclic ring not having aromaticity include a tetrahydropyran ring, a lactone ring, a sultone ring, and a decahydroisoquinoline ring. As the heterocyclic ring in the heterocyclic group, the furan ring, the thiophene ring, the pyridine ring, or the decahydroisoquinoline ring is preferable.

The cyclic organic group may have a substituent. Examples of the substituent include an alkyl group (which may be either linear or branched, preferably having 1 to 12 carbon atoms), a cycloalkyl group (which may be any one of a monocycle, a polycycle, and a spirocycle, and preferably has 3 to 20 carbon atoms), an aryl group (preferably having 6 to 14 carbon atoms), a hydroxyl group, an alkoxy group, an ester group, an amide group, a urethane group, a ureide group, a thioether group, a sulfonamide group, and a sulfonic acid ester group. Incidentally, the carbon constituting the cyclic organic group (carbon contributing to ring formation) may be carbonyl carbon.

As the anion represented by Formula (AN1), SO₃⁻—CF₂—CH₂—OCO-(L)_{q′}-W, SO₃⁻—CF₂—CHF—CH₂—OCO-(L)_{q′}-W, SO₃⁻—CF₂—COO-(L)_{q′}-W, SO₃⁻—CF₂—CF₂—CH₂—CH₂-(L)_{q}-W, or SO₃⁻—CF₂—CH(CF₃)—OCO-(L)_{q′}-W is preferable. Here, L, q, and W are each the same as in Formula (AN1). q′ represents an integer of 0 to 10.

As the non-nucleophilic anion, an anion represented by Formula (AN2) is also preferable.

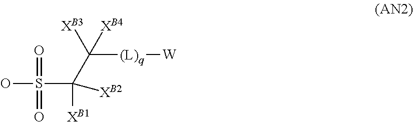

In Formula (AN2), X^{B1} and X^{B2} each independently represent a hydrogen atom or a monovalent organic group having no fluorine atom.

It is preferable that X^{B1} and X^{B2} are each the hydrogen atom.

X^{B3} and X^{B4} each independently represent a hydrogen atom or a monovalent organic group. It is preferable that at least one of X^{B3} or X^{B4} is a fluorine atom or a monovalent organic group having a fluorine atom, and it is more preferable that both of X^{B3} and X^{B4} are fluorine atoms or monovalent organic groups having a fluorine atom. It is still more preferable that both X^{B3} and X^{B4} are alkyl groups substituted with fluorine.

L, q, and W are the same as in Formula (AN1).

As the non-nucleophilic anion, an anion represented by Formula (AN3) is preferable.

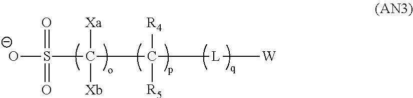

In Formula (AN3), Xa's each independently represent a fluorine atom or an alkyl group substituted with at least one fluorine atom. Xb's each independently represent a hydrogen atom or an organic group having no fluorine atom. The definitions and preferred aspects of o, p, q, R₄, R₅, L, and W are each the same as those in Formula (AN1).

As the non-nucleophilic anion, an anion represented by Formula (AN4) is also preferable.

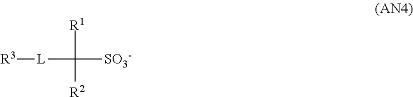

In Formula (AN4), R¹ and R² each independently represent a substituent that is not an electron withdrawing group, or a hydrogen atom.

Examples of the substituent that is not the electron withdrawing group include a hydrocarbon group, a hydroxyl group, an oxyhydrocarbon group, an oxycarbonyl hydrocarbon group, an amino group, a hydrocarbon-substituted amino group, and a hydrocarbon-substituted amide group.

In addition, it is preferable that the substituents which are not electron withdrawing groups are each independently —R′, —OH, —OR′, —OCOR′, —NH₂, —NR′₂, —NHR′, or —NHCOR. R′ is a monovalent hydrocarbon group.

Examples of the monovalent hydrocarbon group represented by R′ include monovalent linear or branched hydrocarbon groups such as alkyl groups such as a methyl group, an ethyl group, a propyl group, and a butyl group; alkenyl groups such as an ethenyl group, a propenyl group, and a butenyl group; and alkynyl groups such as an ethynyl group, a propynyl group, and a butynyl group; monovalent alicyclic hydrocarbon groups such as cycloalkyl groups such as a cyclopropyl group, a cyclobutyl group, a cyclopentyl group, a cyclohexyl group, a norbornyl group, and an adamantyl group; cycloalkenyl groups such as a cyclopropenyl group, a cyclobutenyl group, a cyclopentenyl group, and a norbornenyl group; and monovalent aromatic hydrocarbon groups such as aryl groups such as a phenyl group, a tolyl group, a xylyl group, a mesityl group, a naphthyl group, a methylnaphthyl group, an anthryl group, and a methyl anthryl group; and aralkyl groups such as a benzyl group, a phenethyl group, a phenylpropyl group, a naphthylmethyl group, and an anthrylmethyl group.

Among those, R¹ and R² are each independently preferably the hydrocarbon group (preferably a cycloalkyl group) or the hydrogen atom.

In Formula (AN4), L represents a divalent linking group consisting of a combination of one or more linking groups S and one or more alkylene groups which may have a substituent, or a divalent linking group consisting of one or more linking groups S.

The linking group S is a group selected from the group consisting of *^{A}—O—CO—O—*^{B}, *^{A}—CO—*^{B}, *^{A}—CO—O—*^{B}, *^{A}—O—CO—*^{B}, *^{A}—O—*^{B}, *^{A}—S—*^{B}, and *^{A}—SO₂—*^{B}.

It should be noted that in a case where L is a “divalent linking group consisting of a combination of one or more linking groups S and one or more alkylene groups which have no substituent, which is one form of a “divalent linking group consisting of a combination of one or more linking groups S and one or more alkylene groups which may have a substituent”, it is preferable that the linking group S is a group selected from the group consisting of *^{A}—O—CO—O—*^{B}, *^{A}—CO—*^{B}, *^{A}—O—CO—*^{B}, *^{A}—O—*^{B}, *^{A}—S—*^{B}, and *^{A}—SO₂—*^{B}. In other words, in a case where the alkylene groups in the “divalent linking group consisting of a combination of one or more linking groups S and one or more alkylene groups which may have a substituent” are all unsubstituted alkylene groups, it is preferable that the linking group S is a group selected from the group consisting of *^{A}—O—CO—O—*^{B}, *^{A}—CO—*^{B}, *^{A}—O—CO—*^{B}, *^{A}—O—*^{B}*^{A}—S—*^{B}, and *^{A}—SO₂—*^{B}.

*^{A} represents a bonding position on the R³ side in Formula (AN4) and *^{B} represents a bonding position on the —SO₃⁻ side in Formula (AN4).

In the divalent linking group consisting of a combination of one or more linking groups S and one or more alkylene groups which may have a substituent, only one linking group S may be present, or two or more linking groups S may be present. Similarly, with regard to the alkylene group which may have a substituent, only one alkylene group which may have a substituent may be present, or two or more alkylene groups which may have a substituent may be present. In a case where the linking groups S are present in plurality, the linking groups S that are present in plurality may be the same as or different from each other. In a case where the alkylene groups are present in plurality, the alkylene groups that are present in plurality may be the same as or different from each other.

Furthermore, the linking groups S may be successively bonded to each other. It should be noted that it is preferable that groups selected from the group consisting of *^{A}—CO—*^{B}, *^{A}—O—CO—*^{B}, and *^{A}—O—*^{B} are successively bonded not to form “*^{A}—O—COO—*^{B}”. In addition, it is preferable that groups selected from the group consisting of *^{A}—CO—*^{B}, and *^{A}—O—*^{B} are successively bonded not to form any of “*^{A}—O—CO—*^{B}” and “*^{A}—COO—*^{B}”.

Also in the divalent linking group consisting of one or more linking groups S, only one linking group S may be present, or two or more linking groups S may be present. In a case where the linking groups S are present in plurality, the linking groups S that are present in plurality may be the same as or different from each other.

Also in this case, it is preferable that “*^{A}—O—CO—O—*^{B}” is not formed by the successive bonding of groups selected from the group consisting of *^{A}—CO—*^{B}, *^{A}—O—CO—*^{B} and *^{A}—O—*^{B}. In addition, it is preferable that groups selected from the group consisting of *^{A}—CO—*^{B}, and *^{A}—O—*^{B} are successively bonded not to form any of “*^{A}O—CO*^{B}” and n*^{A}—CO—O—*^{B}”.

It should be noted that in any case, in L, an atom at the β-position with respect to —SO₃— is not a carbon atom having a fluorine atom as a substituent.

Furthermore, in a case where the atom at the β-position is a carbon atom, the carbon atom only needs to be not directly substituted with a fluorine atom, and the carbon atom may have a substituent having a fluorine atom (for example, a fluoroalkyl group such as a trifluoromethyl group).

In addition, the atom at the β-position is, in other words, the atom in L directly bonded to —C(R¹)(R²)— in Formula (AN4).

Above all, it is preferable that L has only one linking group S.

That is, it is preferable that L represents a divalent linking group consisting of a combination of one linking group S and one or more alkylene groups which may have a substituent, or a divalent linking group consisting of one linking group S.

L is preferably, for example, a group represented by Formula (AN4-2).

*^{a}—(CR^{2a}₂)_{X}-Q-(CR^{2b}₂)_{Y}—*^{b} (AN4-2)

In Formula (AN4-2), *^{a} represents a bonding position to R³ in Formula (AN4).

*^{b} represents a bonding position to —C(R¹)(R²)— in Formula (AN4).

X and Y each independently represent an integer of 0 to 10, and is preferably an integer of 0 to 3.

R^{2a} and R^{2b} each independently represent a hydrogen atom or a substituent.

In a case where R^{2a}'s and R^{2b}'s are each present in plurality, R^{2a}'s which are present in plurality and R^{2b}'s which are present in plurality may each be the same as or different from each other.

It should be noted that in a case where Y is 1 or more, R^{2b} in CR^{2b}₂ which is directly bonded to —C(R¹)(R²)— in Formula (AN4) is other than a fluorine atom.

Q represents *^{A}—O—CO—O—*^{B}, *^{A}—CO—*^{B}, *^{A}—CO—O—*^{B}, *^{A}—O—CO—*^{B}, *^{A}—O—*^{B}, *^{A}—S—*^{B}, or *^{A}—SO₂—*^{B}.

It should be noted that in a case where X+Y in Formula (AN4-2) is 1 or more and both of R^{2a} and R^{2b} in Formula (AN4-2) are all hydrogen atoms, Q represents *^{A}—O—CO—O—*^{B}, *^{A}—CO—*^{B}, *^{A}—O—CO—*^{B}, *^{A}—O—*^{B}, *^{A}—S—*^{B}, or *^{A}—SO₂—*^{B}.

*^{A} represents a bonding position on the R³ side in Formula (AN4) and *^{B} represents a bonding position on the —SO₃— side in Formula (AN4).

In Formula (AN4), R³ represents an organic group.

The organic group is not limited as long as it has one or more carbon atoms, may be a linear group (for example, a linear alkyl group) or a branched group (for example, a branched alkyl group such as a t-butyl group), and may be a cyclic group. The organic group may or may not have a substituent. The organic group may or may not have a heteroatom (an oxygen atom, a sulfur atom, a nitrogen atom, and/or the like).

Among those, R³ is preferably an organic group having a cyclic structure. The cyclic structure may be a monocycle or a polycycle, and may have a substituent. The ring in the organic group including a cyclic structure is preferably directly bonded to L in Formula (AN4).

The organic group having a cyclic structure may or may not have, for example, a heteroatom (an oxygen atom, a sulfur atom, a nitrogen atom, and/or the like). The heteroatom may be substituted with one or more of carbon atoms forming the cyclic structure.

The organic group having a cyclic structure is preferably, for example, a hydrocarbon group with a cyclic structure, a lactone ring group, or a sultone ring group. Among those, the organic group having a cyclic structure is preferably a hydrocarbon group with a cyclic structure.

The hydrocarbon group with a cyclic structure is preferably a monocyclic or polycyclic cycloalkyl group. Such a group may have a substituent.

The cycloalkyl group may be a monocycle (a cyclohexyl group or the like) or a polycycle (an adamantyl group or the like), and preferably has 5 to 12 carbon atoms.

As the lactone group and the sultone group, for example, a group formed by extracting one hydrogen atom from a ring member atom constituting the lactone structure or the sultone structure in any of the structures represented by Formulae (LC1-1) to (LC1-21) which will be described later and the structures represented by Formulae (SL1-1) to (SL1-3) as described above is preferable.

The non-nucleophilic anion may be a benzenesulfonate anion, and is preferably a benzenesulfonate anion substituted with a branched alkyl group or a cycloalkyl group.

As the non-nucleophilic anion, an aromatic sulfonate anion represented by Formula (AN5) is also preferable.

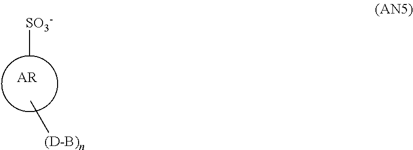

In Formula (AN5), Ar represents an aryl group (a phenyl group and the like), and may further have a substituent other than a sulfonate anion and a -(D-B) group. Examples of the substituent which may be further contained include a fluorine atom and a hydroxyl group.

n represents an integer of 0 or more. n is preferably 1 to 4, more preferably 2 or 3, and still more preferably 3.

D represents a single bond or a divalent linking group. Examples of the divalent linking group include an ether group, a thioether group, a carbonyl group, a sulfoxide group, a sulfone group, a sulfonic acid ester group, an ester group, and a group consisting of a combination of two or more of these.

B represents a hydrocarbon group.

It is preferable that B is an aliphatic hydrocarbon structure. B is more preferably an isopropyl group, a cyclohexyl group, or an aryl group (a tricyclohexylphenyl group and the like) which may further have a substituent.

A disulfonamide anion is also preferable as the non-nucleophilic anion.

The disulfonamide anion is, for example, an anion represented by N—(SO₂—R^{q})₂.

Here, R^{q} represents an alkyl group which may have a substituent, and is preferably a fluoroalkyl group, and more preferably a perfluoroalkyl group. Two of R^{q}'s may be bonded to each other to form a ring. A group formed by the mutual bonding of two of R^{q}'s is preferably an alkylene group which may have a substituent, preferably a fluoroalkylene group, and more preferably a perfluoroalkylene group. The alkylene group preferably has 2 to 4 carbon atoms.

In addition, examples of the non-nucleophilic anion include anions represented by Formulae (d1-1) to (d1-4).

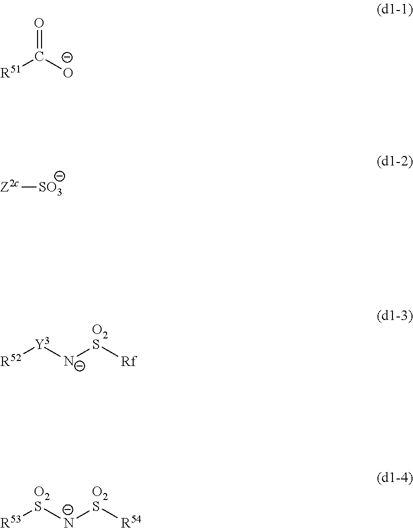

In Formula (d1-1), R⁵¹ represents a hydrocarbon group (for example, an aryl group such as a phenyl group) which may have a substituent (for example, a hydroxyl group).

In Formula (d1-2), Z^{2c} represents a hydrocarbon group having 1 to 30 carbon atoms, which may have a substituent (provided that a carbon atom adjacent to S is not substituted with a fluorine atom).

The hydrocarbon group for Z^{2c} may be linear or branched, and may have a cyclic structure. In addition, a carbon atom in the hydrocarbon group (preferably a carbon atom that is a ring member atom in a case where the hydrocarbon group has the cyclic structure) may be carbonyl carbon (—CO—). Examples of the hydrocarbon group include a group having a norbornyl group which may have a substituent. The carbon atom forming the norbornyl group may be carbonyl carbon.

In addition, it is preferable that “Z-2S—₃-” in Formula (d1-2) is different from the above-described anions represented by Formulae (AN1) to (AN5). For example, Z^{2c} is preferably a group other than an aryl group. In addition, for example, the atoms at the α-position and the β-position with respect to —SO₃— in Z^{2c} are preferably atoms other than the carbon atom having a fluorine atom as a substituent. For example, in Z^{2c}, it is preferable that the atom at the α-position and/or the atom at the β-position with respect to —SO₃— is a ring member atom in the cyclic group.

In Formula (d1-3), R⁵² represents an organic group (preferably a hydrocarbon group having a fluorine atom), Y³ represents a linear, branched, or cyclic alkylene group, an arylene group, or a carbonyl group, and Rf represents a hydrocarbon group.

In Formula (d1-4), R⁵³ and R⁵⁴ each represent an organic group (preferably a hydrocarbon group having a fluorine atom). R⁵³ and R⁵⁴ may be bonded to each other to form a ring.

The organic anions may be used alone or in combination of two or more kinds thereof.

It is also preferable that the compound (X) is at least one selected from the group consisting of compounds (I) to (II).

(Compound (I))

The compound (I) is a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation.

Structural site X: a structural site which consists of an anionic site A₁⁻ and a cationic site M₁⁺, and forms a first acidic site represented by HA₁ upon irradiation with actinic rays or radiation.

Structural site Y: a structural site which consists of an anionic site A₂⁻ and a cationic site M₂⁺, and forms a second acidic site represented by HA₂ upon irradiation with actinic rays or radiation,

It should be noted that at least one of the cationic site M₁⁺ in one or more structural sites X or the cationic site M₂⁺ in one or more structural sites Y represents the cation represented by Formula (X).

In addition, the compound (I) satisfies the following condition I.

Condition I: A compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1.

Hereinafter, the condition I will be described more specifically.

In a case where the compound (I) is, for example, a compound that generates an acid having one site of the first acidic site derived from the structural site X and one site of the second acidic site derived from the structural site Y, the compound PI corresponds to a “compound having HA₁ and HA₂”.

More specifically, with regard to the acid dissociation constant a1 and the acid dissociation constant a2 of such a compound PI, in a case where the acid dissociation constant of the compound PI is determined, the pKa with which the compound PI serves as a “compound having A₁⁻ and HA₂” is the acid dissociation constant a1, and the pKa with which the “compound having A₁⁻ and HA₂” serves as a “compound having A₁⁻ and A₂⁻” is the acid dissociation constant a2.

In addition, in a case where the compound (I) is, for example, a compound that generates an acid having two sites of the first acidic site derived from the structural site X and one site of the second acidic site derived from the structural site Y, the compound PI corresponds to a “compound having two HA₁'s and one HA₂”.

In a case where the acid dissociation constant of such a compound PI is determined, an acid dissociation constant in a case where the compound PI serves as a “compound having one A₁⁻, one HA₁, and one HA₂” and an acid dissociation constant in a case where the “compound having one A₁⁻, one HA₁, and one HA₂” serves as a “compound having two A₁⁻'s and one HA₂” correspond to the acid dissociation constant a1. In addition, the acid dissociation constant in a case where the “compound having two A₁⁻ and one HA₂” serves as a “compound having two A₁⁻'s and A₂⁻” corresponds to the acid dissociation constant a2. That is, in a case of such the compound PI, a value of the acid dissociation constant a2 is larger than the largest value of the plurality of acid dissociation constants a1 in a case where the compound has a plurality of acid dissociation constants derived from the acidic site represented by HA₁, formed by substituting the cationic site M₁⁺ in the structural site X with H⁺. Furthermore, the acid dissociation constant in a case where the compound PI serves as a “compound having one A₁⁻, one HA₁ and one HA₂” is taken as aa and the acid dissociation constant in a case where the “compound having one A₁⁻, one HA₁, and one HA₂” serves as a “compound having two A₁⁻'s and one HA₂” is taken as ab, a relationship between aa and ab satisfies aa<ab.

The acid dissociation constant a1 and the acid dissociation constant a2 can be determined by the above-mentioned method for measuring an acid dissociation constant. The compound PI corresponds to an acid generated upon irradiating the compound (I) with actinic rays or radiation.

In a case where the compound (I) has two or more structural sites X, the structural sites X may be the same as or different from each other. In addition, two or more A₁⁻'s and two or more M₁⁺'s may be the same as or different from each other.

Moreover, in the compound (I), A₁⁻'s and A₂⁻', and M₁⁺'s and M₂⁺'s may be the same as or different from each other, but it is preferable that A₁⁻'s and A₂⁻', are each different from each other.

In the compound PI, a difference (absolute value) between the acid dissociation constant a1 (the maximum value in a case where a plurality of acid dissociation constants a1 are present) and the acid dissociation constant a2 is preferably 0.1 or more, more preferably 0.5 or more, and still more preferably 1.0 or more. Furthermore, the upper limit value of the difference (absolute value) between the acid dissociation constant a1 (the maximum value in a case where a plurality of acid dissociation constants a1 are present) and the acid dissociation constant a2 is not particularly limited, but is, for example, 16 or less.

In the compound PI, the acid dissociation constant a2 is, for example, 20 or less, and preferably 15 or less. Furthermore, a lower limit value of the acid dissociation constant a2 is preferably −4.0 or more.

In addition, in the compound PI, the acid dissociation constant a1 is preferably 2.0 or less, and more preferably 0 or less. Furthermore, a lower limit value of the acid dissociation constant a1 is preferably −20.0 or more.

The anionic site A₁⁻ and the anionic site A₂ are structural sites including negatively charged atoms or atomic groups, and examples thereof include structural sites selected from the group consisting of Formulae (AA-1) to (AA-3) and Formulae (BB-1) to (BB-6) shown below.

As the anionic site A₁⁻, those capable of forming an acidic site having a small acid dissociation constant are preferable, and among those, any one of Formula (AA-1), (AA-2), or (AA-3) is preferable, and Formula (AA-1) or (AA-3) is more preferable.

In addition, the anionic site A₂⁻ is preferably capable of forming an acidic site having a larger acid dissociation constant than the anionic site A₁⁻, any of Formulae (BB-1) to (BB-6) is preferable, and any of Formulae (BB-1) to (BB-4) is more preferable.

Furthermore, in Formulae (AA-1) to (AA-3) and Formulae (BB-1) to (BB-6), * represents a bonding position.

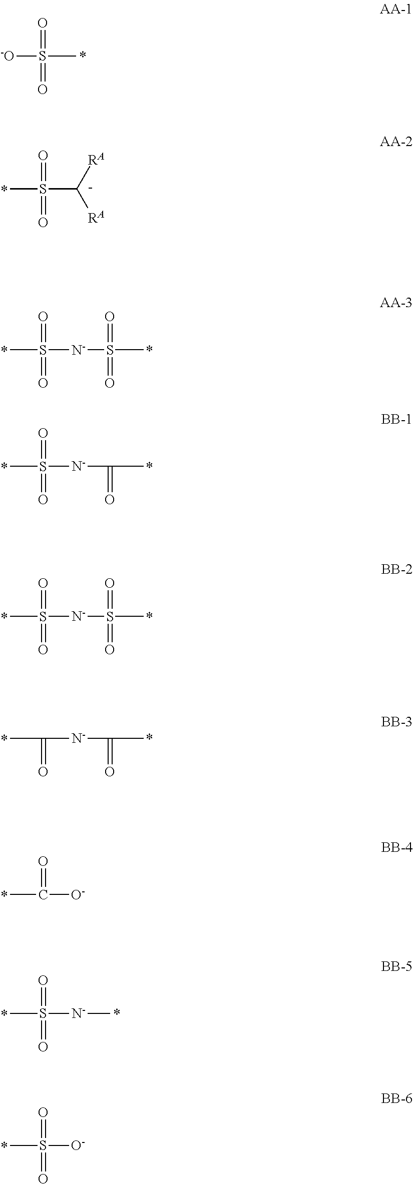

As mentioned above, it should be noted that at least one of the cationic site M₁⁺ in one or more structural sites X or the cationic site M₂⁺ in one or more structural sites Y represents the cation represented by Formula (X).

Among those, it is preferable that both of the cationic site M₁⁺ and the cationic site M₂⁺ are cations represented by Formula (X).

Moreover, in addition to the cation represented by Formula (X), the cation that can be taken by the cationic site M₁⁺ and the cationic site M₂⁺ is not particularly limited, and examples thereof include an organic cation represented by M⁺ which will be described later.

The specific structure of the compound (I) is not particularly limited, but examples thereof include compounds represented by Formulae (Ia-1) to (Ia-5) which will be described later.

—Compound Represented by Formula (Ia-1)—

Hereinbelow, first, the compound represented by Formula (Ia-1) will be described.

M₁₁⁺A₁₁⁻-L₁-A₁₂⁻M₁₂⁺ (Ia-1)

The compound represented by Formula (Ia-1) generates an acid represented by HA₁₁-L₁-A₁₂H upon irradiation with actinic rays or radiation.

In Formula (Ia-1), M₁₁⁺ and M₁₂⁺ each independently represent an organic cation.

A₁₁⁻ and A₁₂⁻ each independently represent a monovalent anionic functional group.

L₁ represents a divalent linking group.

M₁₁⁺ and M₁₂⁺ may be the same as or different from each other.

A₁₁⁻ and A₁₂⁻ may be the same as or different from each other, but are preferably different from each other.

It should be noted that in the compound PIa (HA₁₁-L₁-A₁₂H) formed by substituting cations represented by M₁₁⁺ and M₁₂⁺ with H⁺ in Formula (Ia-1), the acid dissociation constant a2 derived from the acidic site represented by A₁₂H is larger than an acid dissociation constant a1 derived from an acidic site represented by HA₁₁. Furthermore, suitable values of the acid dissociation constant a1 and the acid dissociation constant a2 are as described above. In addition, the acids generated from the compound PIa and the compound represented by Formula (Ia-1) upon irradiation with actinic rays or radiation are the same.

In addition, at least one of M₁₁⁺, M₁₂⁺, A₁₁⁻, A₁₂⁻, or L₁ may have an acid-decomposable group as a substituent.

The organic cations represented by M₁₁⁺ and M₁₂⁺ in Formula (Ia-1) are as mentioned above.

The monovalent anionic functional group represented by A₁₁⁻ is intended to be a monovalent group including the above-mentioned anionic site A₁⁻. In addition, the monovalent anionic functional group represented by A₁₁⁻ is intended to be a monovalent group including the above-mentioned anionic site A₂⁻.

The monovalent anionic functional group represented by each of A₁₁⁻ and A₁₁⁻ is preferably a monovalent anionic functional group including an anionic site of any one of Formula (AA-1), (AA-2), or (AA-3), and Formulae (BB-1) to (BB-6) mentioned above, and more preferably a monovalent anionic functional group selected from the group consisting of Formulae (AX-1) to (AX-3), and Formulae (BX-1) to (BX-7). The monovalent anionic functional group represented by A₁₁⁻ is preferably, among those, the monovalent anionic functional group represented by any one of Formula (AX-1), (AX-1), or (AX-3). In addition, the monovalent anionic functional group represented by A₁₁⁻ is preferably, among those, the monovalent anionic functional group represented by any one of Formula (BX-1), . . . , or (BX-7), and more preferably the monovalent anionic functional group represented by any one of Formula (BX-1), . . . , or to (BX-6).

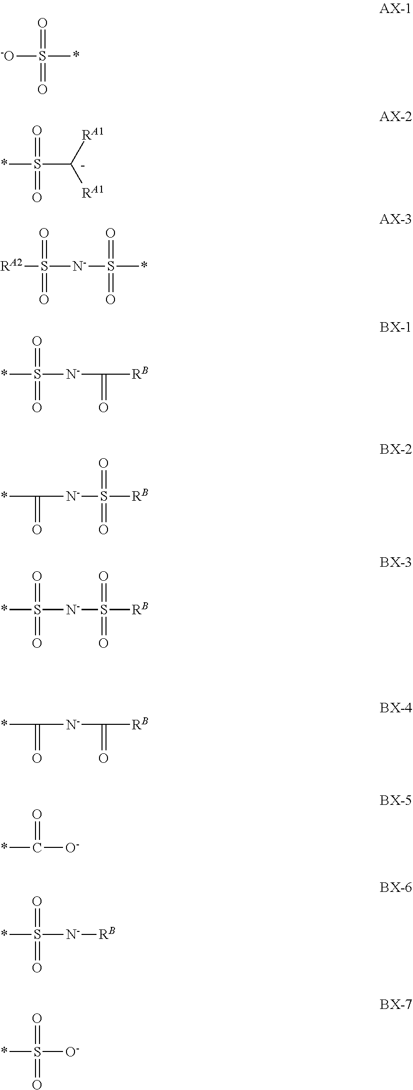

In Formulae (AX-1) to (AX-3), R^{A1} and R^{A2} each independently represent a monovalent organic group. * represents a bonding position.

Examples of the monovalent organic group represented by R^{A1} include a cyano group, a trifluoromethyl group, and a methanesulfonyl group.

As the monovalent organic group represented by R^{A2}, a linear, branched, or cyclic alkyl group, or an aryl group is preferable.

The alkyl group preferably has 1 to 15 carbon atoms, more preferably has 1 to 10 carbon atoms, and still more preferably has 1 to 6 carbon atoms.

The alkyl group may have a substituent. As the substituent, a fluorine atom or a cyano group is preferable, and the fluorine atom is more preferable. In a case where the alkyl group has a fluorine atom as the substituent, it may be a perfluoroalkyl group.

As the aryl group, a phenyl group or a naphthyl group is preferable, and the phenyl group is more preferable.

The aryl group may have a substituent. As the substituent, a fluorine atom, an iodine atom, a perfluoroalkyl group (for example, preferably a perfluoroalkyl group having 1 to 10 carbon atoms, and more preferably a perfluoroalkyl group having 1 to 6 carbon atoms), or a cyano group is preferable, and the fluorine atom, the iodine atom, or the perfluoroalkyl group is more preferable.

In Formulae (BX-1) to (BX-4) and Formula (BX-6), R^{B} represents a monovalent organic group. * represents a bonding position.

As the monovalent organic group represented by R^{B}, a linear, branched, or cyclic alkyl group, or an aryl group is preferable.

The alkyl group preferably has 1 to 15 carbon atoms, more preferably has 1 to 10 carbon atoms, and still more preferably has 1 to 6 carbon atoms.

The alkyl group may have a substituent. The substituent is not particularly limited, but as the substituent, a fluorine atom or a cyano group is preferable, and the fluorine atom is more preferable. In a case where the alkyl group has a fluorine atom as the substituent, it may be a perfluoroalkyl group.

Moreover, in a case where the carbon atom that serves as a bonding position in the alkyl group (for example, in a case of Formulae (BX-1) and (BX-4), the carbon atom corresponds to a carbon atom that directly bonds to —CO— specified in the formula in the alkyl group, and in a case of Formulae (BX-2) and (BX-3), the carbon atom corresponds to a carbon atom that directly bonded to —SO₂— specified in the formula in the alkyl group, and in a case of Formula (BX-6), the carbon atom corresponds to a carbon atom that directly bonded to N-specified in the formula in the alkyl group) has a substituent, it is also preferable that the carbon atom has a substituent other than a fluorine atom or a cyano group.

In addition, the alkyl group may have a carbon atom substituted with a carbonyl carbon.

As the aryl group, a phenyl group or a naphthyl group is preferable, and the phenyl group is more preferable.

The aryl group may have a substituent. As the substituent, a fluorine atom, an iodine atom, a perfluoroalkyl group (for example, preferably a perfluoroalkyl group having 1 to 10 carbon atoms, and more preferably a perfluoroalkyl group having 1 to 6 carbon atoms), a cyano group, an alkyl group (for example, preferably an alkyl group having 1 to 10 carbon atoms, and more preferably an alkyl group having 1 to 6 carbon atoms), an alkoxy group (for example, preferably an alkoxy group having 1 to 10 carbon atoms, and more preferably an alkoxy group having 1 to 6 carbon atoms), or an alkoxycarbonyl group (for example, preferably an alkoxycarbonyl group having 2 to 10 carbon atoms, and more preferably an alkoxycarbonyl group having 2 to 6 carbon atoms) is preferable, and the fluorine atom, the iodine atom, the perfluoroalkyl group, the alkyl group, the alkoxy group, or the alkoxycarbonyl group is more preferable.

In Formula (Ia-1), the divalent linking group represented by L₁ is not particularly limited, but examples thereof include —CO—, —NR—, —CO—, —O—, —S—, —SO—, —SO₂—, an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent linking group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may each have a substituent. Examples of the substituent include a halogen atom (preferably a fluorine atom).

Among those, the divalent linking group represented by Formula (L1) is preferable as the divalent linking group by L₁.

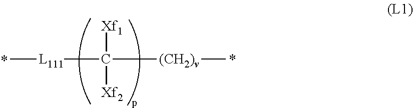

In Formula (L1), L₁₁₁ represents a single bond or a divalent linking group.

The divalent linking group represented by L₁₁₁ is not particularly limited, but examples thereof include —CO—, —NH—, —O—, —SO—, —SO₂—, an alkylene group (which preferably has 1 to 6 carbon atoms, and may be linear or branched), which may have a substituent, a cycloalkylene group (preferably having 3 to 15 carbon atoms), which may have a substituent, an aryl group (preferably having 6 to 10 carbon atoms) which may have a substituent, and a divalent linking group formed by combination of these groups. The substituent is not particularly limited, but examples thereof include a halogen atom.

p represents an integer of 0 to 3, and preferably represents an integer of 1 to 3.

v represents an integer of 0 or 1.

Xf₁'s each independently represent a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf₂'s each independently represent a hydrogen atom, an alkyl group which may have a fluorine atom as a substituent, or a fluorine atom. The alkyl group preferably has 1 to 10 carbon atoms, and more preferably has 1 to 4 carbon atoms. Among those, Xf₂ preferably represents the fluorine atom or the alkyl group substituted with at least one fluorine atom, and is more preferably the fluorine atom or a perfluoroalkyl group.

Among those, Xf₁ and Xf₂ are each independently preferably the fluorine atom or a perfluoroalkyl group having 1 to 4 carbon atoms, and more preferably the fluorine atom or CF₃. In particular, it is still more preferable that both Xf₁ and Xf₂ are fluorine atoms.

* represents a bonding position.

In a case where L₁₁ in Formula (Ia-1) represents a divalent linking group represented by Formula (L1), it is preferable that a bonding site (*) on the L₁₁₁ side in Formula (L1) is bonded to A₁₂⁻ in Formula (Ia-1).

—Compounds Represented by Formulae (Ia-2) to (Ia-4)—

Next, the compounds represented by Formulae (Ia-2) to (Ia-4) will be described.

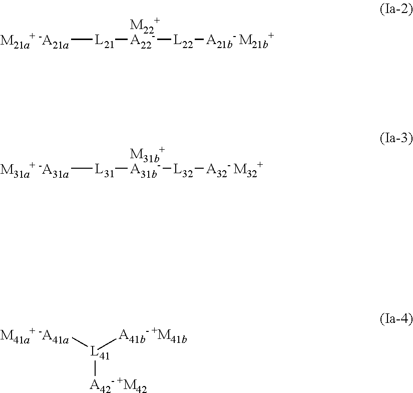

In Formula (Ia-2), A₂₁ₐ⁻ and A_{21b}⁻ each independently represent a monovalent anionic functional group. Here, the monovalent anionic functional group represented by each of A₂₁ₐ⁻ and A_{21b}⁻ is intended to be a monovalent group including the above-mentioned anionic site A₁⁻. The monovalent anionic functional group represented by each of A₂₁ₐ⁻ and A_{21b}⁻ is not particularly limited, but examples thereof include a monovalent anionic functional group selected from the group consisting of Formulae (AX-1) to (AX-3) mentioned above.

A₂₂⁻ represents a divalent anionic functional group. Here, the divalent anionic functional group represented by A₂₂⁻ is intended to be a divalent group including the above-mentioned anionic site A₂⁻. Examples of the divalent anionic functional group represented by A₂₂⁻ include divalent anionic functional groups represented by Formulae (BX-8) to (BX-11).

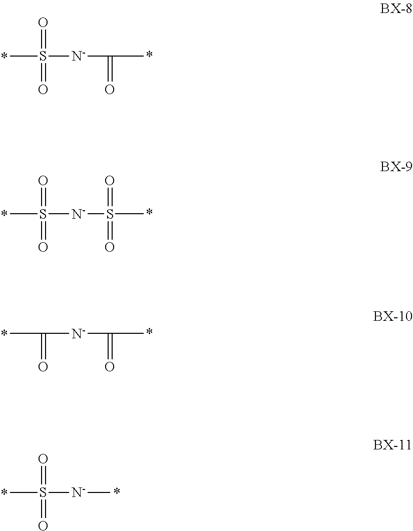

M₂₁ₐ⁺, M_{21b}⁺, and M₂₂⁺ each independently represent an organic cation. The organic cations represented by M₂₁ₐ⁺, M_{21b}⁺, and M₂₂⁺ each have the same definition as the above-mentioned M₁⁺, and suitable aspects thereof are also the same.

L₂₁ and L₂₂ each independently represent a divalent organic group.

In addition, in the compound PIa-2 formed by substituting an organic cation represented by M₂₁ₐ⁺, M_{21b}⁺, and M₂₂⁺ with H⁺ in Formula (Ia-2), the acid dissociation constant a2 derived from the acidic site represented by A₂₂H is larger than the acid dissociation constant a1-1 derived from the acidic site represented by A₂₁ₐH and the acid dissociation constant a1-2 derived from the acidic site represented by A_{21b}H. Incidentally, the acid dissociation constant a1-1 and the acid dissociation constant a1-2 correspond to the above-mentioned acid dissociation constant a1.

Furthermore, A₂₁ₐ⁻ and A_{21b}⁻ may be the same as or different from each other. In addition, M₂₁ₐ⁺, M_{21b}⁺, and M₂₂⁺ may be the same as or different from each other.

Moreover, at least one of M₂₁ₐ⁺, M_{21b}⁺, M₂₂⁺, A₂₁ₐ⁻, A_{21b}⁻, L₂₁, or L₂₂ may have an acid-decomposable group as a substituent.

In Formula (Ia-3), A₃₁ₐ⁻ and A₃₂⁻ each independently represent a monovalent anionic functional group. Furthermore, the monovalent anionic functional group represented by A₃₁ₐ⁻ has the same definition as A₂₁ₐ⁻ and A_{21b}⁻ in Formula (Ia-2) mentioned above, and suitable aspects thereof are also the same.

The monovalent anionic functional group represented by A₃₂⁻ is intended to be a monovalent group including the above-mentioned anionic site A₂⁻. The monovalent anionic functional group represented by A₃₂⁻ is not particularly limited, but examples thereof include a monovalent anionic functional group selected from the group consisting of Formulae (BX-1) to (BX-7) mentioned above.

A_{31b}⁻ represents a divalent anionic functional group. Here, the divalent anionic functional group represented by A_{31b}⁻ is intended to be a divalent group including the above-mentioned anionic site A₁⁻. Examples of the divalent anionic functional group represented by A_{31b}⁻ include a divalent anionic functional group represented by Formula (AX-4).

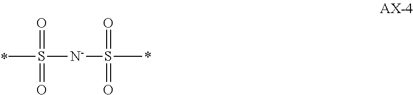

M₃₁ₐ⁺, M_{31b}⁺, and M₃₂⁺ each independently represent a monovalent organic cation. The organic cations represented by M₃₁ₐ⁺, M_{31b}⁺, and M₃₂⁺ each have the same definition as the above-mentioned M₁⁺, and suitable aspects thereof are also the same.

L₃₁ and L₃₂ each independently represent a divalent organic group.

In addition, in the compound PIa-3 formed by substituting an organic cation represented by M₃₁ₐ⁺, M_{31b}⁺, and M₃₂⁺ with H⁺ in Formula (Ia-3), the acid dissociation constant a2 derived from the acidic site represented by A₃₂H is larger than the acid dissociation constant a1-3 derived from the acidic site represented by A₃₁ₐH and the acid dissociation constant a1-4 derived from the acidic site represented by A_{31b}H. Incidentally, the acid dissociation constant a1-3 and the acid dissociation constant a1-4 correspond to the above-mentioned acid dissociation constant a1.

Furthermore, A₃₁ₐ⁻ and A₃₂⁻ may be the same as or different from each other. In addition, M₃₁ₐ⁺, M_{31b}⁺, and M₃₂⁺ may be the same as or different from each other.

Moreover, at least one of M₃₁ₐ⁺, M_{31b}⁺, M₃₂⁺, A₃₁ₐ⁻, A₃₂⁻, L₃₁, or L₃₂ may have an acid-decomposable group as a substituent.

In Formula (Ia-4), A₄₁ₐ⁻, A_{41b}⁻, and A₄₂⁻ each independently represent a monovalent anionic functional group. Furthermore, the monovalent anionic functional groups represented by A₄₁ₐ⁻ and A_{41b}⁻ have the same definitions as A₂₁ₐ⁻ and A_{21b}⁻ in Formula (Ia-2) mentioned above. In addition, the monovalent anionic functional group represented by A₄₂⁻ has the same definition as A₃₂⁻ in Formula (Ia-3) mentioned above, and suitable aspects thereof are also the same.

M₄₁ₐ⁺, M_{41b}⁺, and M₄₂⁺ each independently represent an organic cation.

L₄₁ represents a trivalent organic group.

In addition, in the compound PIa-4 formed by substituting an organic cation represented by M₄₁ₐ⁺, M_{41b}⁺, and M₄₂⁺ with H⁺ in Formula (Ia-4), the acid dissociation constant a2 derived from the acidic site represented by A₄₂H is larger than the acid dissociation constant a1-5 derived from the acidic site represented by A₄₁ₐH and the acid dissociation constant a1-6 derived from the acidic site represented by A_{41b}H. Incidentally, the acid dissociation constant a1-5 and the acid dissociation constant a1-6 correspond to the above-mentioned acid dissociation constant a1.

Furthermore, A₄₁ₐ⁻, A_{41b}⁻, and A₄₂⁻ may be the same as or different from each other. In addition, M₄₁ₐ⁺, M_{41b}⁺, and M₄₂⁺ may be the same as or different from each other.

Moreover, at least one of M₄₁ₐ⁺, M_{41b}⁺, M₄₂⁺, A₄₁ₐ⁻, A_{41b}⁻, A₄₂⁻, or L₄₁ may have an acid-decomposable group as a substituent.

The divalent organic group represented by each of L₂₁ and L₂₂ in Formula (Ia-2) and L₃₁ and L₃₂ in Formula (Ia-3) is not particularly limited, but examples thereof include —CO—, —NR—, —O—, —S—, —SO—, —SO₂—, an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent organic group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may each have a substituent. Examples of the substituent include a halogen atom (preferably a fluorine atom).

As the divalent organic group represented by each of L₂₁ and L₂₂ in Formula (Ia-2) and L₃₁ and L₃₂ in Formula (Ia-3), for example, a divalent organic group represented by Formula (L2) is preferable.

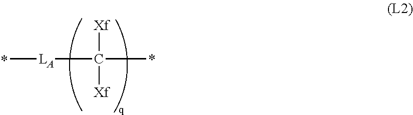

In Formula (L2), q represents an integer of 1 to 3. * represents a bonding position.

Xf's each independently represent a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf is preferably the fluorine atom or a perfluoroalkyl group having 1 to 4 carbon atoms, and more preferably the fluorine atom or CF₃. In particular, it is still more preferable that both Xf's are fluorine atoms.

L_{A} represents a single bond or a divalent linking group.

The divalent linking group represented by L_{A} is not particularly limited, but examples thereof include —CO—, —O—, —SO—, —SO₂—, an alkylene group (which preferably has 1 to 6 carbon atoms and may be linear or branched), a cycloalkylene group (preferably having 3 to 15 carbon atoms), a divalent aromatic hydrocarbon ring group (preferably having a 6 to 10-membered ring, and more preferably having a 6-membered ring), and a divalent linking group formed by combination of a plurality of these groups.

In addition, the alkylene group, the cycloalkylene group, and the divalent aromatic hydrocarbon ring group may have a substituent. Examples of the substituent include a halogen atom (preferably a fluorine atom).

Examples of the divalent organic group represented by Formula (L2) include *—CF₂—*, *—CF₂—CF₂—*, *—CF₂—CF₂—CF₂—*, *-Ph-O—SO₂—CF₂—*, *-Ph-O—SO₂—CF₂—CF₂—*, *-Ph-O—SO₂—CF₂—CF₂—CF₂—*, and d*-Ph-OCO—CF₂—*. Furthermore, Ph is a phenylene group which may have a substituent, and is preferably a 1,4-phenylene group. The substituent is not particularly limited, but is preferably an alkyl group (for example, preferably an alkyl group having 1 to 10 carbon atoms, and more preferably an alkyl group having 1 to 6 carbon atoms), an alkoxy group (for example, preferably an alkoxy group having 1 to 10 carbon atoms, and more preferably an alkoxy group having 1 to 6 carbon atoms), or an alkoxycarbonyl group (for example, preferably an alkoxycarbonyl group having 2 to 10 carbon atoms, and more preferably an alkoxycarbonyl group having 2 to 6 carbon atoms).

In a case where L₂₁ and L₂₂ in Formula (Ia-2) represent a divalent organic group represented by Formula (L2), it is preferable that a bonding site (*) on the LA side in Formula (L2) is bonded to A₂₁ₐ⁻ and A_{21b}⁻ in Formula (Ia-2).

In addition, in a case where L₃₁ and L₃₂ in Formula (Ia-3) represent a divalent organic group represented by Formula (L2), it is preferable that a bonding site (*) on the LA side in Formula (L2) is combined with A₃₁a and A₃₂- in Formula (Ia-3).

The trivalent organic group represented by L₄₁ in Formula (Ia-4) is not particularly limited, but examples thereof include a trivalent organic group represented by Formula (L3).

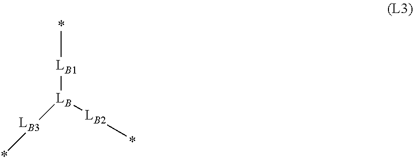

In Formula (L3), L_{B} represents a trivalent hydrocarbon ring group or a trivalent heterocyclic group. * represents a bonding position.

The hydrocarbon ring group may be an aromatic hydrocarbon ring group or an aliphatic hydrocarbon ring group. The number of carbon atoms included in the hydrocarbon ring group is preferably 6 to 18, and more preferably 6 to 14. The heterocyclic group may be either an aromatic heterocyclic group or an aliphatic heterocyclic group. The heterocyclic group is preferably a 5- to 10-membered ring, more preferably a 5- to 7-membered ring, and still more preferably a 5- or 6-membered ring, each of which has at least one N atom, O atom, S atom, or Se atom in the ring structure.

As L_{B}, above all, the trivalent hydrocarbon ring group is preferable, and a benzene ring group or an adamantane ring group is more preferable. The benzene ring group or the adamantane ring group may have a substituent. The substituent is not particularly limited, but examples thereof include a halogen atom (preferably a fluorine atom).

In addition, in Formula (L3), L_{B1} to L_{B3} each independently represent a single bond or a divalent linking group. The divalent linking group represented by each of L_{B1} to L_{B3} is not particularly limited, and for example, —CO—, —NR—, —O—, —S—, —SO—, —SO₂—, or an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent linking group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may each have a substituent. Examples of the substituent include a halogen atom (preferably a fluorine atom).

As the divalent linking group represented by each of L_{B1} to L_{B3}, among those, —CO—, —NR—, —O—, —S—, —SO—, —SO₂—, the alkylene group which may have a substituent, and the divalent linking group formed by combination of these groups are preferable.

As the divalent linking group represented by each of L_{B1} to L_{B3}, the divalent linking group represented by Formula (L3-1) is more preferable.

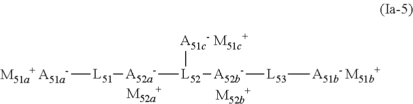

In Formula (L3-1), L_{B11} represents a single bond or a divalent linking group.

The divalent linking group represented by L_{B11} is not particularly limited, but examples thereof include —CO—, —O—, —SO—, —SO₂—, an alkylene group (which preferably has 1 to 6 carbon atoms, and may be linear or branched) which may have a substituent, and a divalent linking group formed by combination of a plurality of these groups. The substituent is not particularly limited, but examples thereof include a halogen atom.

r represents an integer of 1 to 3.

Xf has the same definition as Xf in Formula (L2) mentioned above, and suitable aspects thereof are also the same.

* represents a bonding position.

Examples of the divalent linking groups represented by each of L_{B1} to L_{B3} include *—O—*, *—O—SO₂—CF₂—*, *—O—SO₂—CF₂—CF₂—*, *—O—SO₂—CF₂—CF₂—CF₂—*, and *—COO—CH₂—CH₂—*.

In a case where L₄₁ in Formula (Ia-4) includes a divalent organic group represented by Formula (L3-1), and the divalent organic group represented by Formula (L3-1) and A₄₂⁻ are bonded to each other, it is preferable that the bonding site (*) on the carbon atom side specified in Formula (L3-1) is bonded to A₄₂⁻ in Formula (Ia-4).

—Compound Represented by Formula (Ia-5)—

Next, Formula (Ia-5) will be described.

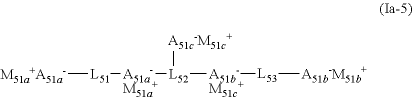

In Formula (Ia-5), A₅₁ₐ⁻, A_{51b}⁻, and A_{51c}⁻ each independently represent a monovalent anionic functional group. Here, the monovalent anionic functional group represented by each of A₅₁ₐ⁻, A_{51b}⁻, and A_{51c}⁻ is intended to be a monovalent group including the above-mentioned anionic site A₁⁻. The monovalent anionic functional group represented by each of A₅₁ₐ⁻, A_{51b}⁻, and A₅₁⁻ is not particularly limited, but examples thereof include a monovalent anionic functional group selected from the group consisting of Formulae (AX-1) to (AX-3) mentioned above.

A₅₂ₐ⁻ and A_{52b}⁻ each represent a divalent anionic functional group. Here, the divalent anionic functional group represented by each of A₅₂ₐ⁻ and A_{52b}⁻ is intended to be a divalent group including the above-mentioned anionic site A₂⁻. Examples of the divalent anionic functional group represented by A₂₂⁻ include a divalent anionic functional group selected from the group consisting of Formulae (BX-8) to (BX-11) mentioned above.

M₅₁ₐ⁺, M_{51b}⁺, M_{51c}⁺, M₅₂ₐ⁺, and M_{52b}⁺ each independently represent an organic cation. The organic cation represented by each of M₅₁ₐ⁺, M_{51b}⁺, M_{51c}⁺, M₅₂ₐ⁺, and M_{52b}⁺ has the same definition as the above-mentioned M₁⁺, and suitable aspects thereof are also the same.

L₅₁ and L₅₃ each independently represent a divalent organic group. The divalent organic group represented by each of L₅₁ and L₅₃ has the same definition as L₂₁ and L₂₂ in Formula (Ia-2) mentioned above, and suitable aspects thereof are also the same.

L₅₂ represents a trivalent organic group. The trivalent organic group represented by L₅₂ has the same definition as L₄₁ in Formula (Ia-4) mentioned above, and suitable aspects thereof are also the same.

In addition, in the compound PIa-5 formed by substituting an organic cation represented by each of M₅₁ₐ⁺, M_{51b}⁺, M_{51c}⁺, M₅₂ₐ⁺, and M_{52b}⁺ with H⁺ in Formula (Ia-5), the acid dissociation constant a2-1 derived from the acidic site represented by A₅₂ₐH and the acid dissociation constant a2-2 derived from the acidic site represented by A_{52b}H are larger than the acid dissociation constant a1-1 derived from the acidic site represented by A₅₁ₐH, the acid dissociation constant a1-2 derived from the acidic site represented by A_{51b}H, and the acid dissociation constant a1-3 derived from the acidic site represented by A_{51c}H. Incidentally, the acid dissociation constants a1-1 to a1-3 correspond to the above-mentioned acid dissociation constant a1, and the acid dissociation constants a2-1 and a2-2 correspond to the above-mentioned acid dissociation constant a2.

Furthermore, A₅₁ₐ⁻, A_{51b}⁻, and A_{51c}⁻ may be the same as or different from each other. Moreover, A₅₂ₐ⁻ and A_{52b}⁻ may be the same as or different from each other. In addition, M₅₁ₐ⁺, M_{51b}⁺, M_{51c}⁺, M₅₂ₐ⁺, and M_{52b}⁺ may be the same as or different from each other.

Moreover, at least one of M_{51b}⁻, M_{51c}⁺, M₅₂ₐ⁺, M_{52b}⁺, A₅₁ₐ⁻, A_{51b}⁻, A_{51c}⁻, L₅₁, L₅₂, or L₅₃ may have an acid-decomposable group as a substituent.

(Compound (II))

The compound (II) is an acid generating compound, including a compound having two or more of the structural sites X and one or more of the following structural sites Z, in which the compound generates an acid including a compound that generates an acid including the two or more first acidic sites derived from the structural site X and the structural sites Z upon irradiation with actinic rays or radiation.

structural site Z: a nonionic site capable of neutralizing an acid,

In the compound (II), the definition of the structural site X and the definitions of A₁- and M₁⁺ are the same as the definition of the structural site X in the compound (I), and the definitions of A₁⁻ and M₁⁺, each mentioned above, and suitable aspects thereof are also the same.

In the compound PII formed by substituting the cationic site M₁⁺ in the structural site X with H⁺ in the compound (II), a suitable range of the acid dissociation constant a1 derived from the acidic site represented by HA₁, formed by substituting the cationic site M₁⁺ in the structural site X with H⁺, is the same as the acid dissociation constant a1 in the compound PI.

Furthermore, in a case where the compound (II) is, for example, a compound that generates an acid having two sites of the first acidic site derived from the structural site X and the structural site Z, the compound PII corresponds to a “compound having two HA₁'s”. In a case where the acid dissociation constant of the compound PII was determined, the acid dissociation constant in a case where the compound PII serves as a “compound having one A₁- and one HA₁” and the acid dissociation constant in a case where the “compound having one A₁⁻ and one HA₁” serves as a “compound having two A₁⁻¹s” correspond to the acid dissociation constant a1.

The acid dissociation constant a1 is determined by the above-mentioned method for measuring an acid dissociation constant.

The compound PII corresponds to an acid generated upon irradiating the compound (II) with actinic rays or radiation.

Furthermore, two or more sites of the structural site X may be the same as or different from each other. In addition, two or more A₁-'s and two or more M₁⁺'s may be the same as or different from each other.

The nonionic site capable of neutralizing an acid in the structural site Z is not particularly limited, and is preferably, for example, a site including a functional group having a group or electron which is capable of electrostatically interacting with a proton.

Examples of the functional group having a group or electron capable of electrostatically interacting with a proton include a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by the following formula.

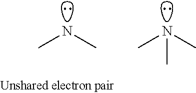

Examples of the partial structure of the functional group having a group or electron capable of electrostatically interacting with a proton include a crown ether structure, an azacrown ether structure, primary to tertiary amine structures, a pyridine structure, an imidazole structure, and a pyrazine structure, and among these, the primary to tertiary amine structures are preferable.

The compound (II) is not particularly limited, but examples thereof include compounds represented by Formula (IIa-1) and Formula (IIa-2).

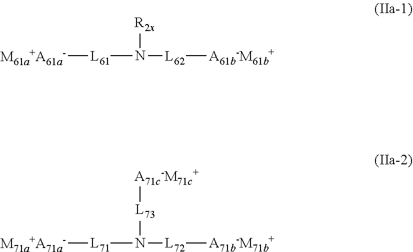

In Formula (IIa-1), A₆₁ₐ⁻ and A_{61b}⁻ each have the same definition as A₁₁⁻ in Formula (Ia-1) mentioned above, and suitable aspects thereof are also the same. In addition, M₆₁ₐ⁺ and M_{61b}⁺ each have the same definition as M₁₁⁺ in Formula (Ia-1) mentioned above, and suitable aspects thereof are also the same.

In Formula (IIa-1), L₆₁ and L₆₂ each have the same definition as L₁ in Formula (Ia-1) mentioned above, and suitable aspects thereof are also the same.

In Formula (IIa-1), R_{2X} represents a monovalent organic group. The monovalent organic group represented by R_{2X} is not particularly limited, but examples thereof include an alkyl group (which preferably has 1 to 10 carbon atoms, and may be linear or branched), a cycloalkyl group (preferably having 3 to 15 carbon atoms), and an alkenyl group (preferably having 2 to 6 carbon atoms), in which —CH₂— may be substituted with one or a combination of two or more selected from the group consisting of —CO—, —NH—, —O—, —S—, —SO—, and —SO₂—.

In addition, the alkylene group, the cycloalkylene group, and the alkenylene group may have a substituent. The substituent is not particularly limited, but examples thereof include a halogen atom (preferably a fluorine atom).

In addition, in the compound PIIa-1 formed by substituting an organic cation represented by M₆₁ₐ⁺ and M_{61b}⁺ with H⁺ in Formula (IIa-1), the acid dissociation constant a1-7 derived from the acidic site represented by A₆₁ₐH and the acid dissociation constant a1-8 derived from the acidic site represented by A_{61b}H correspond to the above-mentioned acid dissociation constant a1.

Furthermore, the compound PIIa-1 formed by substituting the cationic sites M₆₁ₐ⁺ and M_{61b}⁺ in the structural site X with H⁺ in the compound (IIa-1) corresponds to HA₆₁ₐ-L₆₁-N(R_{2X})-L₆₂-A_{61b}H. In addition, the acids generated from the compound PIIa-1 and the compound represented by Formula (IIa-1) upon irradiation with actinic rays or radiation are the same.

Moreover, at least one of M₆₁ₐ⁺, M_{61b}⁺, A₆₁ₐ⁻, A_{61b}⁻, L₆₁, L₆₂, or R₂ₓ may have an acid-decomposable group as a substituent.

In Formula (IIa-2), A₇₁ₐ⁻, A_{71b}⁻, and A_{71c}⁻ each have the same definition as A₁₁⁻ in Formula (Ia-1) mentioned above, and suitable aspects thereof are also the same. In addition, M₇₁ₐ⁺, M_{71b}⁺, and M_{71c}⁺ each have the same definition as Mn* in Formula (Ia-1) mentioned above, and suitable aspects thereof are the same.

In Formula (IIa-2), L₇₁, L₇₂, and L₇₃ each have the same definition as L₁ in Formula (Ia-1) mentioned above, and suitable aspects thereof are also the same.

In addition, in the compound PIIa-2 formed by substituting an organic cation represented by M₇₁ₐ⁺, M_{71b}⁺, and M_{71c}⁺ with H⁺ in Formula (IIa-2), the acid dissociation constant a1-9 derived from the acidic site represented by A₇₁ₐH, the acid dissociation constant a1-10 derived from the acidic site represented by A_{71b}H, and the acid dissociation constant a1-11 derived from the acidic site represented by A_{71c}H correspond to the above-mentioned acid dissociation constant a1.

Furthermore, the compound PIIa-2 formed by substituting the cationic sites M₇₁ₐ⁺, M_{71b}⁺, and M_{71c}⁺ in the structural site X with H⁺ in the compound (IIa-1) corresponds to HA₇₁ₐ-L₇₁-N(L₇₃-A_{71c}H)-L₇₂-A_{71b}H. In addition, the acids generated from the compound PIIa-2 and the compound represented by Formula (IIa-2) upon irradiation with actinic rays or radiation are the same.

Moreover, at least one of M₇₁ₐ⁺, M_{71b}⁺, M₇₁⁺, A₇₁ₐ⁻, A_{71b}⁻, A_{71c}⁻, L₇₁, L₇₂, or L₇₃ may have an acid-decomposable group as a substituent.

The specific cation and the other sites, which can be contained in the compound (X), are exemplified below.

The specific cation can be used as, for example, M₁₁⁺, M₁₂⁺, M₂₁ₐ⁺, M_{21b}⁺, M₂₂⁺, M₃₁ₐ⁺, M_{31b}⁺, M₃₂⁺, M₄₁ₐ⁺, M_{41b}⁺, M₄₂⁺, M₅₁ₐ⁺, M_{51b}⁺, M_{51c}⁺, M₅₂ₐ⁺, or M_{52b}⁺ in the compounds represented by Formulae (Ia-1) to (Ia-5).

The other sites can be used as, for example, moieties other than M₁₁⁺, M₁₂⁺, M₂₁ₐ⁺, M_{21b}⁺, M₂₂⁺, M₃₁ₐ⁺, M_{31b}⁺, M₃₂⁺, M₄₁ₐ⁺, M_{41b}⁺, M₄₂⁺, M₅₁ₐ⁺, M_{51b}⁺, M_{51c}⁺, M₅₂ₐ⁺, or M_{52b}⁺ in the compounds represented by Formulae (Ia-1) to (Ia-5).

A site other than the specific cation which can be contained in the compound (X) will be exemplified.

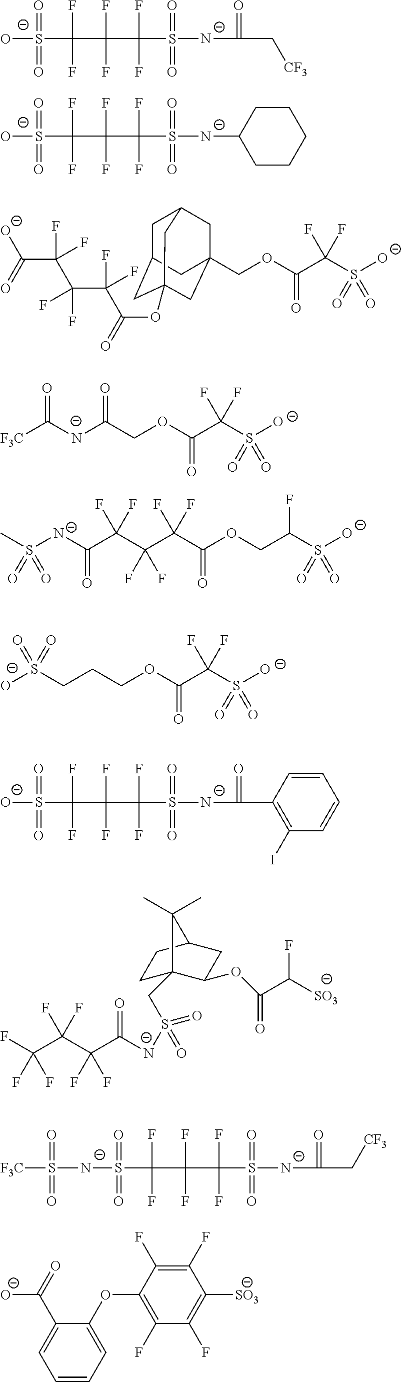

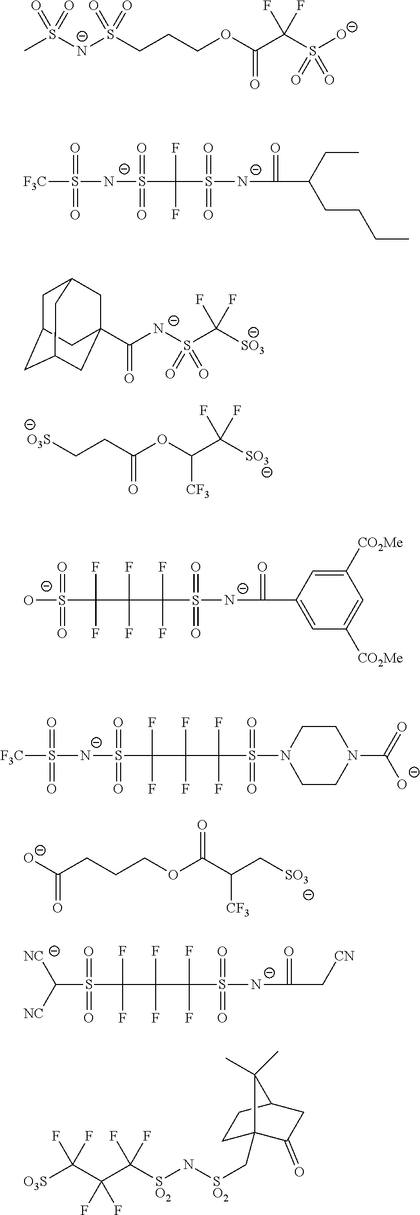

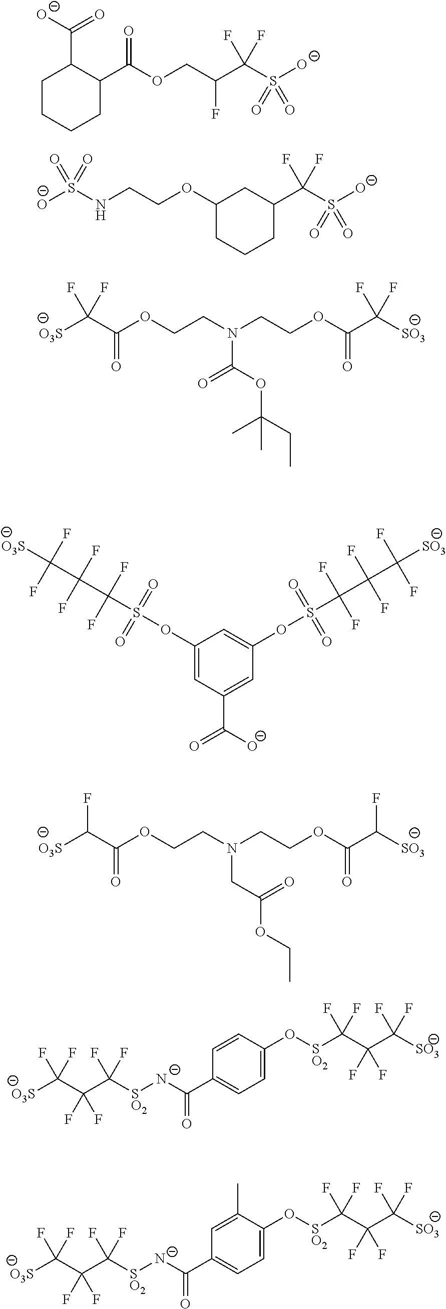

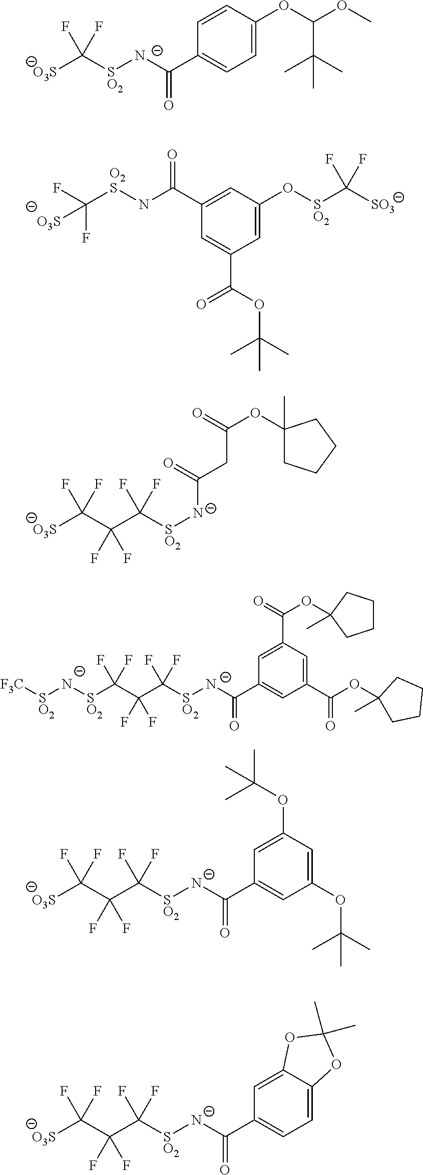

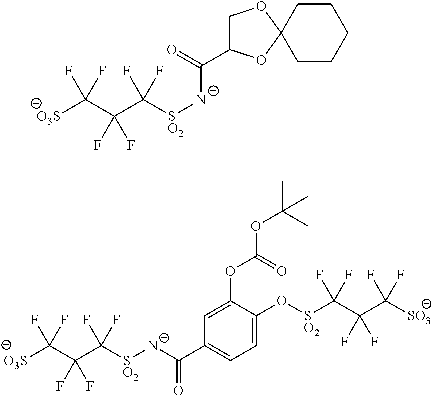

Specific examples of the compound (X) are shown below, but the present invention is not limited thereto.

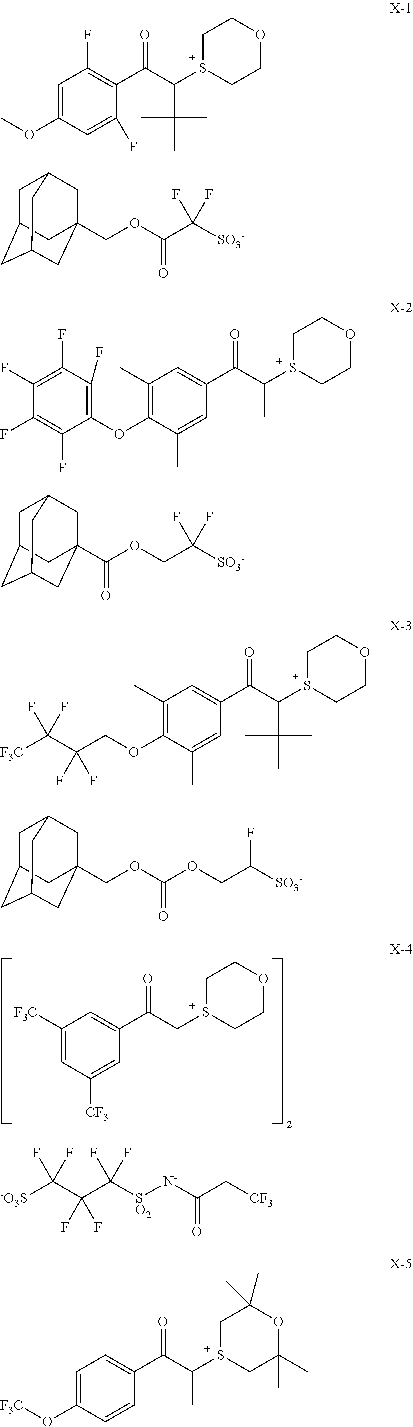

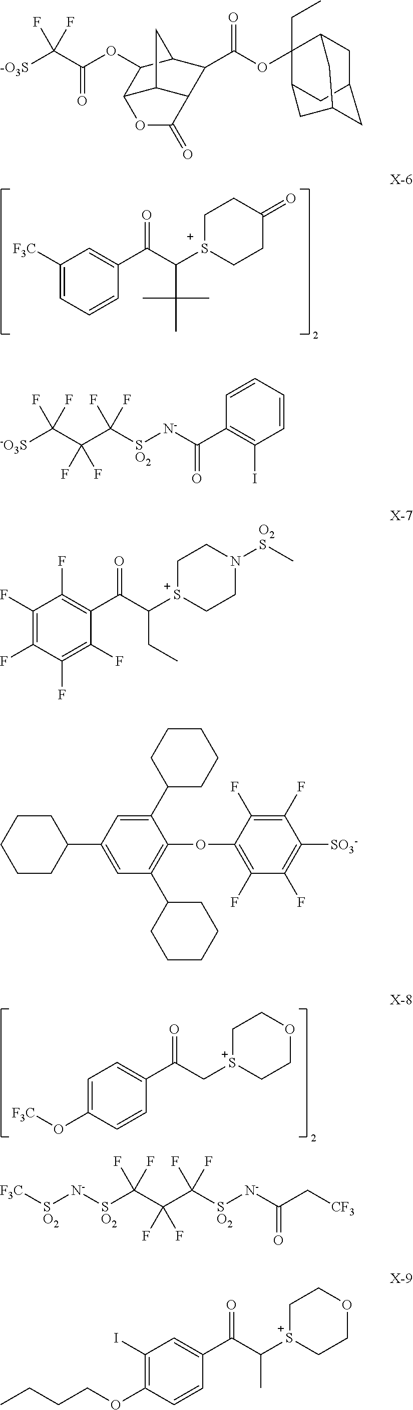

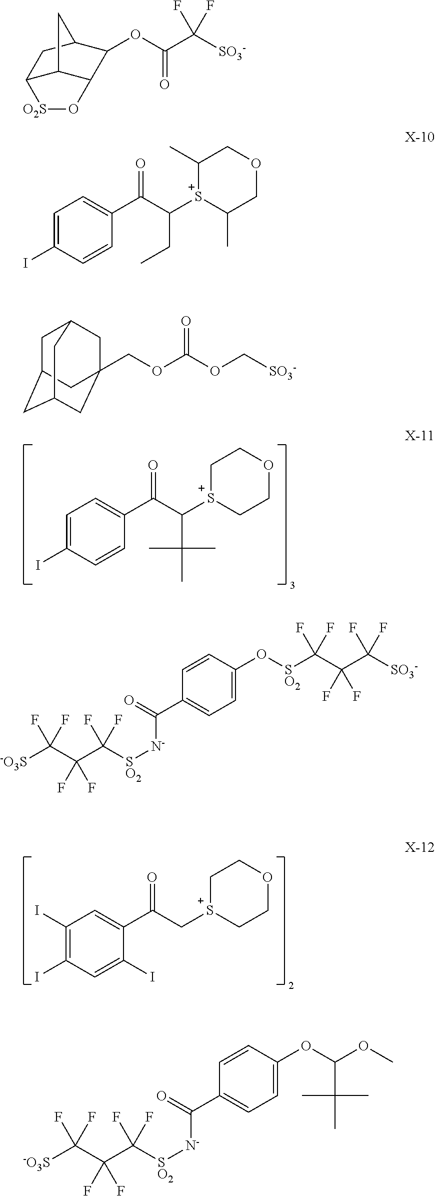

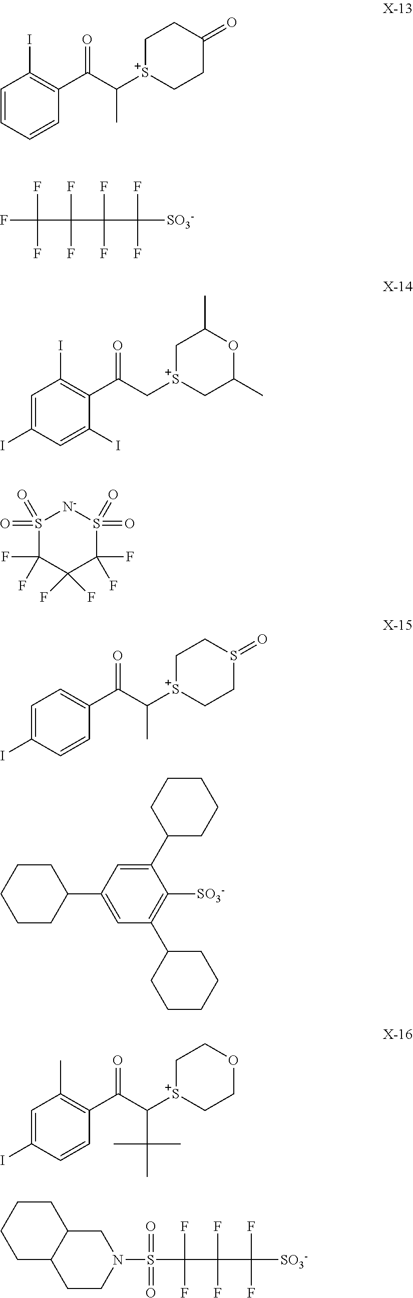

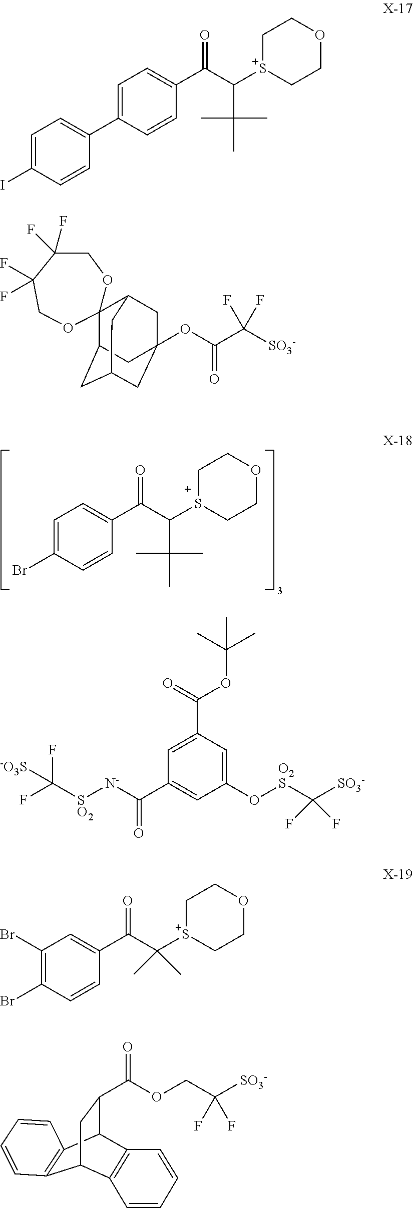

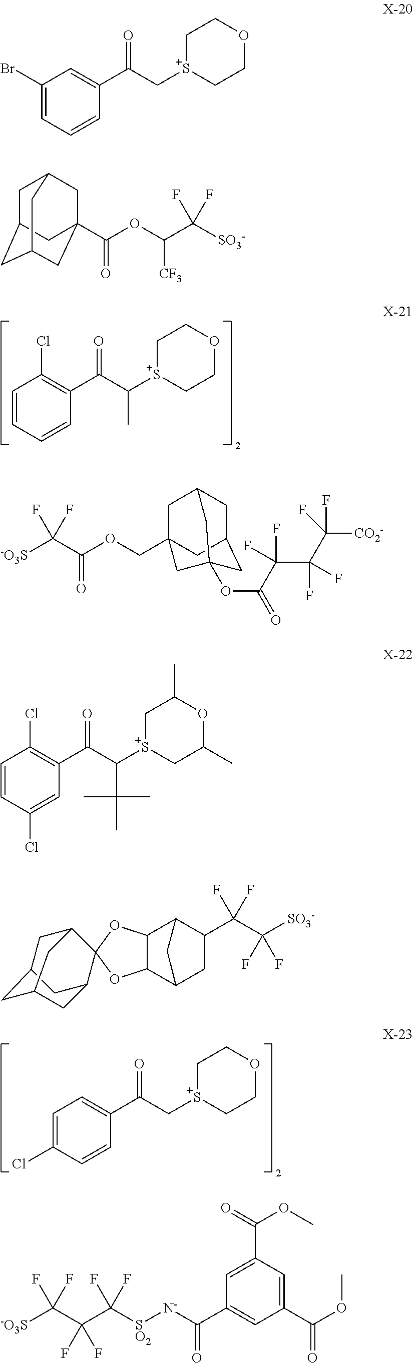

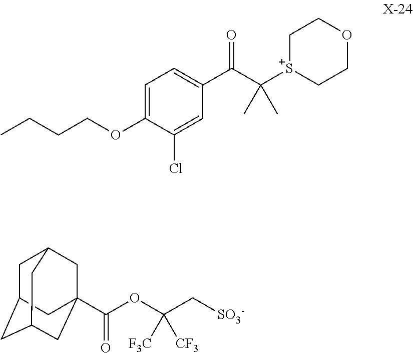

The molecular weight of the compound (X) is preferably 100 to 10,000, more preferably 100 to 2,500, and still more preferably 100 to 1,500.

The content of the compound (X) is preferably 1.0% by mass or more, more preferably 5.0% by mass or more, and still more preferably 10.0% by mass or more with respect to the total solid content of the resist composition. In addition, the upper limit value thereof is preferably 90.0% by mass or less, more preferably 80.0% by mass or less, and still more preferably 70.0% by mass or less with respect to the total solid content of the resist composition.

The compound (X) may be used alone or in combination of two or more kinds thereof. In a case where two or more kinds of such other photoacid generators are used, a total content thereof is preferably within the suitable content range.

<Photoacid Generator (B)>

The resist composition may include a photoacid generator (B).

The photoacid generator (B) corresponds to a photoacid generator other than the above-mentioned compound (X).

The photoacid generator (B) may be in a form of a low-molecular-weight compound or a form incorporated into a part of a polymer (for example, a resin (A) which will be described later). In addition, a combination of the form of a low-molecular-weight compound and the form incorporated into a part of a polymer (for example, a resin (A) which will be described later) may also be used.

In a case where the photoacid generator (B) is in the form of a low-molecular-weight compound, the molecular weight of the photoacid generator is preferably 3,000 or less, more preferably 2,000 or less, and still more preferably 1,000 or less. The lower limit is not particularly limited, but is preferably 100 or more.

In a case where the photoacid generator (B) is in the form incorporated into a part of a polymer, it may be incorporated into the part of the resin (A) or into a resin that is different from the resin (A).

In the present invention, the photoacid generator (B) is preferably in the form of a low-molecular-weight compound.

Examples of the photoacid generator (B) include a compound (onium salt) represented by “M⁺X⁻”, and a compound that generates an organic acid by exposure is preferable. Examples of the organic acid include sulfonic acids (an aliphatic sulfonic acid, an aromatic sulfonic acid, and a camphor sulfonic acid), carboxylic acids (an aliphatic carboxylic acid, an aromatic carboxylic acid, and an aralkylcarboxylic acid), a carbonylsulfonylimide acid, a bis(alkylsulfonyl)imide acid, and a tris(alkylsulfonyl)methide acid.

In the compound represented by “M⁺X⁻”, M⁺ represents an organic cation.

The organic cation represented by M⁺ is a cation different from the specific cation.

The organic cation is not particularly limited as long as it is an organic cation. In addition, the valence of the organic cation may be 1 or 2 or more.

Among those, as the organic cation, a cation represented by Formula (ZaI) (hereinafter also referred to as a “cation (ZaI)”) or a cation represented by Formula (ZaII) (hereinafter also referred to as a “cation (ZaII)”) is preferable.

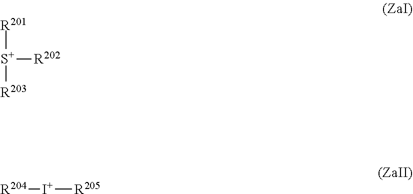

In Formula (ZaI),

R²⁰¹, R²⁰², and R²⁰³ each independently represent an organic group.

The organic group as each of R²⁰¹, R²⁰², and R²⁰³ usually has 1 to 30 carbon atoms, and preferably has 1 to 20 carbon atoms. In addition, two of R²⁰¹ to R²⁰³ may be bonded to each other to form a ring structure, and the ring may include an oxygen atom, a sulfur atom, an ester group, an amide group, or a carbonyl group. Examples of the group formed by the bonding of two of R²⁰¹ to R²⁰³ include an alkylene group (for example, a butylene group and a pentylene group), and —CH₂—CH₂—O—CH₂—CH₂—.

Suitable aspects of the organic cation as Formula (ZaI) include a cation (ZaI-1), a cation (ZaI-2), an organic cation represented by Formula (ZaI-3b) (cation (ZaI-3b)), and an organic cation represented by Formula (ZaI-4b) (cation (ZaI-4b)), each of which will be described later.

First, the cation (ZaI-1) will be described.

The cation (ZaI-1) is an arylsulfonium cation in which at least one of R²⁰¹, R²⁰², or R²⁰³ of Formula (ZaI) is an aryl group.

In the arylsulfonium cation, all of R²⁰¹ to R²⁰³ may be aryl groups, or some of R²⁰¹ to R²⁰³ may be an aryl group, and the rest may be an alkyl group or a cycloalkyl group.

In addition, one of R²⁰¹ to R²⁰³ is an aryl group, two of R²⁰¹ to R²⁰³ may be bonded to each other to form a ring structure, and an oxygen atom, a sulfur atom, an ester group, an amide group, or a carbonyl group may be included in the ring. Examples of the group formed by the bonding of two of R²⁰¹ to R²⁰³ include an alkylene group (for example, a butylene group, a pentylene group, and —CH₂—CH₂—O—CH₂—CH₂—) in which one or more methylene groups may be substituted with an oxygen atom, a sulfur atom, an ester group, an amide group, and/or a carbonyl group.

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

As the aryl group included in the arylsulfonium cation, a phenyl group or a naphthyl group is preferable, and the phenyl group is more preferable. The aryl group may be an aryl group which has a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium cation has two or more aryl groups, the two or more aryl groups may be the same as or different from each other.

The alkyl group or the cycloalkyl group contained in the arylsulfonium cation, as necessary, is preferably a linear alkyl group having 1 to 15 carbon atoms, a branched alkyl group having 3 to 15 carbon atoms, or a cycloalkyl group having 3 to 15 carbon atoms, and more preferably a methyl group, an ethyl group, a propyl group, an n-butyl group, a sec-butyl group, a t-butyl group, a cyclopropyl group, a cyclobutyl group, or a cyclohexyl group.

The substituents which may be contained in each of the aryl group, the alkyl group, and the cycloalkyl group of each of R²⁰¹ to R²⁰³ are each independently preferably an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom (for example, fluorine and iodine), a hydroxyl group, a carboxyl group, an ester group, a sulfinyl group, a sulfonyl group, an alkylthio group, and a phenylthio group.

The substituent may further have a substituent as possible and is also preferably in the form of an alkyl halide group such as a trifluoromethyl group in which the alkyl group has a halogen atom as a substituent.

In addition, it is also preferable that the substituents form an acid-decomposable group by any combination.

Furthermore, the acid-decomposable group is intended to be a group that decomposes by the action of an acid to produce a polar group, and preferably has a structure in which a polar group is protected by a leaving group that leaves by the action of an acid. The polar group and the leaving group are as mentioned above.

Next, the cation (ZaI-2) will be described.

The cation (ZaI-2) is a cation in which R²⁰¹ to R²⁰³ in Formula (ZaI) are each independently a cation representing an organic group having no aromatic ring. The aromatic ring also includes an aromatic ring including a heteroatom.

The organic group having no aromatic ring as each of R²⁰¹ to R²⁰³ generally has 1 to 30 carbon atoms, and preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably the linear or branched 2-oxoalkyl group.

Examples of the alkyl group and the cycloalkyl group of each of R²⁰¹ to R²⁰³ include a linear alkyl group having 1 to 10 carbon atoms or branched alkyl group having 3 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group).

R²⁰¹ to R²⁰³ may further be substituted with a halogen atom, an alkoxy group (for example, having 1 to 5 carbon atoms), a hydroxyl group, a cyano group, or a nitro group.

In addition, it is also preferable that the substituents of R²⁰¹ to R²⁰³ each independently form an acid-decomposable group by any combination of the substituents.

Next, the cation (ZaI-3b) will be described.

The cation (ZaI-3b) is a cation represented by Formula (ZaI-3b).

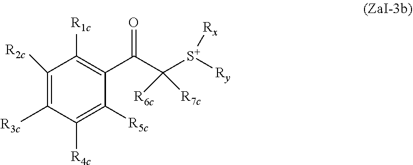

In Formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group (for example, a t-butyl group), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

In addition, it is also preferable that the substituents of R_{1c} to R_{7c}, Rₓ, and R_{y} each independently form an acid-decomposable group by any combination of substituents.

Any two or more of R_{1c}, . . . , or R_{5c}, R_{5c} and R_{6c}, R_{6c} and R_{7c}, R_{5c} and Rₓ, and Rₓ and R_{y} may each be bonded to each other to form a ring, and the ring may each independently include an oxygen atom, a sulfur atom, a ketone group, an ester bond, or an amide bond.

Examples of the ring include an aromatic or non-aromatic hydrocarbon ring, an aromatic or non-aromatic heterocyclic ring, and a polycyclic fused ring formed by combination of two or more kinds of these rings. Examples of the ring include a 3- to 10-membered ring, and the ring is preferably a 4- to 8-membered ring, and more preferably a 5- or 6-membered ring.

Examples of the group formed by the bonding of any two or more of R_{1c}, . . . , or R_{5c}, R_{6c} and R_{7c}, and Rₓ and R_{y} include an alkylene group such as a butylene group and a pentylene group. The methylene group in this alkylene group may be substituted with a heteroatom such as an oxygen atom.

As the group formed by the bonding of R_{5c} and R_{6c}, and R_{5c} and Rₓ, a single bond or an alkylene group is preferable. Examples of the alkylene group include a methylene group and an ethylene group.

A ring formed by the mutual bonding of any two or more of R_{1c} to R_{5c}, R_{6c}, R_{7c}, Rₓ, R_{y}, or R_{1c} to R_{5c}, and a ring formed by the mutual bonding of each pair of R_{5c} and R_{6c}, R_{6c} and R_{7c}, R_{5c} and Rₓ, and Rₓ and R_{y} may have a substituent.

Next, the cation (ZaI-4b) will be described.

The cation (ZaI-4b) is a cation represented by Formula (ZaI-4b).

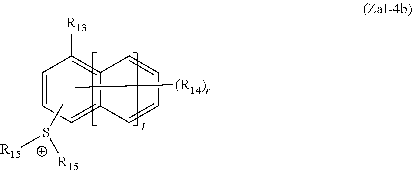

In Formula (ZaI-4b),

l represents an integer of 0 to 2.

r represents an integer of 0 to 8.

R₁₃ represents a hydrogen atom, a halogen atom (for example, a fluorine atom and an iodine atom), a hydroxyl group, an alkyl group, an alkyl halide group, an alkoxy group, a carboxyl group, an alkoxycarbonyl group, or a group including a cycloalkyl group (which may be the cycloalkyl group itself or a group including the cycloalkyl group in a part thereof). These groups may have a substituent.

R₁₄ represents a hydroxyl group, a halogen atom (for example, a fluorine atom and an iodine atom), an alkyl group, an alkyl halide group, an alkoxy group, an alkoxycarbonyl group, an alkylcarbonyl group, an alkylsulfonyl group, a cycloalkylsulfonyl group, or a group including a cycloalkyl group (which may be the cycloalkyl group itself or a group including the cycloalkyl group in a part thereof). These groups may have a substituent. In a case where R₁₄'s are present in plurality, R₁₄'s each independently represent the group such as a hydroxyl group.

R₁₅'s each independently represent an alkyl group, a cycloalkyl group, or a naphthyl group. Two R₁₅'s may be bonded to each other to form a ring. In a case where two R₁₅'s are bonded to each other to form a ring, the ring skeleton may include a heteroatom such as an oxygen atom and a nitrogen atom. In one aspect, it is preferable that two R₁₅'s are alkylene groups and are bonded to each other to form a ring structure. Furthermore, the alkyl group, the cycloalkyl group, the naphthyl group, and the ring formed by the mutual bonding two R₁₅'s may have a substituent.

In Formula (ZaI-4b), the alkyl group of each of R₁₃, R₁₄, and R₁₅ may be linear or branched. The alkyl group preferably has 1 to 10 carbon atoms. The alkyl group is more preferably a methyl group, an ethyl group, an n-butyl group, a t-butyl group, or the like. In addition, it is also preferable that the respective substituents of R₁₃ to R₁₅, Rₓ, and R_{y} each independently form an acid-decomposable group by any combination of substituents.

Next, Formula (ZaII) will be described.

In Formula (ZaII), R²⁰⁴ and R²⁰⁵ each independently represent an aryl group, an alkyl group, or a cycloalkyl group.

The aryl group of each of R²⁰⁴ and R²⁰⁵ is preferably a phenyl group or a naphthyl group, and more preferably the phenyl group. The aryl group of each of R²⁰⁴ and R²⁰⁵ may be an aryl group which has a heterocyclic ring having an oxygen atom, a nitrogen atom, a sulfur atom, or the like. Examples of the skeleton of the aryl group having a heterocyclic ring include pyrrole, furan, thiophene, indole, benzofuran, and benzothiophene.

The alkyl group and the cycloalkyl group of each of R²⁰⁴ and R²⁰⁵ is preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, or a norbornyl group).

The aryl group, the alkyl group, and the cycloalkyl group of each of R²⁰⁴ and R²⁰⁵ may each independently have a substituent. Examples of the substituent which may be contained in each of the aryl group, the alkyl group, and the cycloalkyl group of each of R²⁰⁴ and R²⁰⁵ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group. In addition, it is also preferable that the substituents of R²⁰⁴ and R²⁰⁵ each independently form an acid-decomposable group by any combination of the substituents.

In the compound represented by “M⁺X⁻”, X⁻ represents an organic anion.

The organic anion is not particularly limited, and is preferably a non-nucleophilic anion (anion having a significantly low ability to cause a nucleophilic reaction).

Examples of the non-nucleophilic anion include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, and a tris(alkylsulfonyl)methide anion.

The aliphatic site in the aliphatic sulfonate anion and the aliphatic carboxylate anion may be an alkyl group or a cycloalkyl group, and has a linear or branched alkyl group having 1 to 30 carbon atoms, or is preferably a cycloalkyl group having 3 to 30 carbon atoms.

The alkyl group may be, for example, a fluoroalkyl group (which may or may not have a substituent other than a fluorine atom, and may be a perfluoroalkyl group).

The aryl group in the aromatic sulfonate anion and the aromatic carboxylate anion is preferably an aryl group having 6 to 14 carbon atoms, and examples thereof include a phenyl group, a tolyl group, and a naphthyl group.

The alkyl group, the cycloalkyl group, and the aryl group exemplified above may have a substituent. The substituent is not particularly limited, but specific examples of the substituent include a nitro group, a halogen atom such as fluorine atom or a chlorine atom, a carboxyl group, a hydroxyl group, an amino group, a cyano group, an alkoxy group (preferably having 1 to 15 carbon atoms), an alkyl group (preferably having 1 to 10 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), and an aryloxysulfonyl group (preferably having 6 to 20 carbon atoms).

The aralkyl group in the aralkyl carboxylate anion is preferably an aralkyl group having 7 to 14 carbon atoms, and examples thereof include a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Examples of the substituent of such an alkyl group include a halogen atom, an alkyl group substituted with a halogen atom, an alkoxy group, an alkylthio group, an alkyloxysulfonyl group, an aryloxysulfonyl group, and a cycloalkylaryloxysulfonyl group, and a fluorine atom or an alkyl group substituted with the fluorine atom is preferable.

In addition, the alkyl groups in the bis(alkylsulfonyl)imide anion may be bonded to each other to form a ring. Thus, the acid strength increases.

As the non-nucleophilic anion, an aliphatic sulfonate anion in which at least α-position of sulfonic acid is substituted with a fluorine atom, an aromatic sulfonate anion substituted with a fluorine atom or a group including a fluorine atom, a bis(alkylsulfonyl)imide anion in which an alkyl group is substituted with a fluorine atom, or a tris(alkylsulfonyl)methide anion in which an alkyl group is substituted with a fluorine atom is preferable.

As the photoacid generator (B), the photoacid generators disclosed in paragraphs [0135] to [0171] of WO2018/193954A, paragraphs [0077] to [0116] of WO2020/066824A, and paragraphs [0018] to [0075] and [0334] and [0335] of WO2017/154345A, and the like are preferably used.

In a case where the resist composition includes the photoacid generator (B), the content thereof is not particularly limited, but from the viewpoint that the shape of a pattern thus formed is further rectangularized, the content is preferably 0.5% by mass or more, and more preferably 1.0% by mass or more with respect to a total solid content of the resist composition. In addition, the content is preferably 50.0% by mass or less, more preferably 30.0% by mass or less, and still more preferably 25.0% by mass or less with respect to the total solid content of the resist composition.

The photoacid generator (B) may be used alone or in combination of two or more kinds thereof.

[Acid-Decomposable Resin (Resin (A))]

The resist composition includes the resin (A).

That is, in the pattern forming method of an embodiment of the present invention, typically, in a case where an alkali developer is adopted as the developer, a positive tone pattern is suitably formed, and in a case where an organic developer is adopted as the developer, a negative tone pattern is suitably formed.

The resin (A) usually includes a repeating unit having a group (hereinafter also referred to as an “acid-decomposable group”) of which polarity increases through decomposition by the action of an acid, and preferably includes a repeating unit having an acid-decomposable group.

As the repeating unit having an acid-decomposable group, in addition to a (repeating unit having an acid-decomposable group) which will be described later, a (repeating unit having an acid-decomposable group including an unsaturated bond) is preferable.

<Repeating Unit Having Acid-Decomposable Group>

(Repeating Unit Having Acid-Decomposable Group)

The acid-decomposable group refers to a group that decomposes by the action of an acid to generate a polar group. The acid-decomposable group preferably has a structure in which the polar group is protected by a leaving group that leaves by the action of an acid. That is, the resin (A) has a repeating unit having a group that decomposes by the action of an acid to generate a polar group. A resin having this repeating unit has an increased polarity by the action of an acid, and thus has an increased solubility in an alkali developer, and a decreased solubility in an organic solvent.

As the polar group, an alkali-soluble group is preferable, and examples thereof include an acidic group such as a carboxyl group, a phenolic hydroxyl group, a fluorinated alcohol group, a sulfonic acid group, a phosphoric acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and an alcoholic hydroxyl group.

Among those, as the polar group, the carboxyl group, the phenolic hydroxyl group, the fluorinated alcohol group (preferably a hexafluoroisopropanol group), or the sulfonic acid group is preferable.

Examples of the leaving group that leaves by the action of an acid include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In Formulae (Y1) and (Y2), Rx₁ to RX₃ each independently represent an (linear or branched) alkyl group, a (monocyclic or polycyclic) cycloalkyl group, an (linear or branched) alkenyl group, or an (monocyclic or polycyclic) aryl group. Furthermore, in a case where all of Rx₁ to RX₃ are (linear or branched) alkyl groups, it is preferable that at least two of Rx₁, RX₂, or RX₃ are methyl groups.

Above all, it is preferable that Rx₁ to RX₃ each independently represent a linear or branched alkyl group, and it is more preferable that Rx₁ to RX₃ each independently represent the linear alkyl group.

Two of RX₁ to RX₃ may be bonded to each other to form a monocycle or a polycycle.

As the alkyl group of each of Rx₁ to RX₃, an alkyl group having 1 to 5 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to RX₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group as each of Rx₁ to Rx₃, an aryl group having 6 to 10 carbon atoms is preferable, and examples thereof include a phenyl group, a naphthyl group, and an anthryl group.

As the alkenyl group of each of Rx₁ to Rx₃, a vinyl group is preferable.

As a ring formed by the bonding of two of Rx₁ to Rx₃, a cycloalkyl group is preferable. As the cycloalkyl group formed by the bonding of two of Rx₁ to Rx₃, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of two of Rx₁ to Rx₃, for example, one of the methylene groups constituting the ring may be substituted with a heteroatom such as an oxygen atom, a group including a heteroatom, such as a carbonyl group, or a vinylidene group. In addition, in such the cycloalkyl group, one or more of the ethylene groups constituting the cycloalkane ring may be substituted with a vinylene group.

With regard to the group represented by Formula (Y1) or Formula (Y2), for example, an aspect in which Rx₁ is a methyl group or an ethyl group, and Rx₂ and Rx₃ are bonded to each other to form a cycloalkyl group is preferable.

In a case where the resist composition is, for example, a resist composition for EUV exposure, it is preferable that the alkyl group, the cycloalkyl group, the alkenyl group, or the aryl group represented by each of Rx₁ to Rx₃, and a ring formed by the bonding of two of Rx₁ to Rx₃ further has a fluorine atom or an iodine atom as a substituent.

In Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is the hydrogen atom.

Furthermore, the alkyl group, the cycloalkyl group, the aryl group, and the aralkyl group may include a heteroatom such as an oxygen atom, and/or a group including a heteroatom, such as a carbonyl group. For example, in the alkyl group, the cycloalkyl group, the aryl group, and the aralkyl group, one or more of the methylene groups may be substituted with a heteroatom such as an oxygen atom, and/or a group including a heteroatom, such as a carbonyl group.

In addition, R₃₈ and another substituent contained in the main chain of the repeating unit may be bonded to each other to form a ring. A group formed by the mutual bonding of R₃₈ and another substituent in the main chain of the repeating unit is preferably an alkylene group such as a methylene group.

In a case where the resist composition is, for example, a resist composition for EUV exposure, it is preferable that the monovalent organic group represented by each of R₃₆ to R₃₈ and the ring formed by the mutual bonding of R₃₇ and R₃₈ further have a fluorine atom or an iodine atom as a substituent.

As Formula (Y3), a group represented by Formula (Y3-1) is preferable.

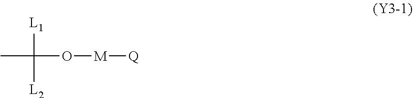

Here, L₁ and L₂ each independently represent a hydrogen atom, an alkyl group, a cycloalkyl group, an aryl group, or a group formed by combination thereof (for example, a group formed by combination of an alkyl group and an aryl group).

M represents a single bond or a divalent linking group.

Q represents an alkyl group which may include a heteroatom, a cycloalkyl group which may include a heteroatom, an aryl group which may include a heteroatom, an amino group, an ammonium group, a mercapto group, a cyano group, an aldehyde group, or a group formed by combination of these groups (for example, a group formed by combination of an alkyl group and a cycloalkyl group).

In the alkyl group and the cycloalkyl group, for example, one of the methylene groups may be substituted with a heteroatom such as an oxygen atom or a group including a heteroatom, such as a carbonyl group.

In addition, it is preferable that one of L₁ or L₂ is a hydrogen atom, and the other is an alkyl group, a cycloalkyl group, an aryl group, or a group formed by combination of an alkylene group and an aryl group.

At least two of Q, M, or L₁ may be bonded to each other to form a ring (preferably a 5- or 6-membered ring).

From the viewpoint of pattern miniaturization, L₂ is preferably a secondary or tertiary alkyl group, and more preferably the tertiary alkyl group. Examples of the secondary alkyl group include an isopropyl group, a cyclohexyl group, and a norbornyl group, and examples of the tertiary alkyl group include a tert-butyl group and an adamantane group. In these aspects, since the glass transition temperature (Tg) and the activation energy are increased, it is possible to suppress fogging in addition to ensuring film hardness.

In a case where the resist composition is, for example, a resist composition for EUV exposure, it is also preferable that the alkyl group, the cycloalkyl group, an aryl group, or the group formed by combination of these groups, represented by each of L₁ and L₂, further has a fluorine atom or an iodine atom as a substituent. In addition, it is also preferable that the alkyl group, the cycloalkyl group, the aryl group, and the aralkyl group include a heteroatom such as an oxygen atom, in addition to the fluorine atom and the iodine atom (that is, in the alkyl group, the cycloalkyl group, the aryl group, and the aralkyl group, for example, one of the methylene groups is substituted with a heteroatom such as an oxygen atom or a group including a heteroatom, such as a carbonyl group).

In addition, in a case where the resist composition is, for example, a resist composition for EUV exposure, it is also preferable that in an alkyl group which may include a heteroatom, a cycloalkyl group which may include a heteroatom, an aryl group which may include a heteroatom, an amino group, an ammonium group, a mercapto group, a cyano group, an aldehyde group, or a group formed by combination of these groups, represented by Q, the heteroatom is a heteroatom selected from the group consisting of a fluorine atom, an iodine atom, and an oxygen atom.

In Formula (Y4), Ar represents an aromatic ring group. Rn represents an alkyl group, a cycloalkyl group, or an aryl group. Rn and Ar may be bonded to each other to form a non-aromatic ring. An aryl group is preferable as Ar.

In a case where the resist composition is, for example, a resist composition for EUV exposure, it is also preferable that the aromatic ring group represented by Ar, and the alkyl group, the cycloalkyl group, and the aryl group, represented by Rn, have a fluorine atom and an iodine atom as a substituent.

From the viewpoint that the acid decomposability of the repeating unit is excellent, in a case where a non-aromatic ring is directly bonded to a polar group (or a residue thereof) in a leaving group that protects the polar group, it is also preferable that a ring member atom adjacent to the ring member atom directly bonded to the polar group (or a residue thereof) in the non-aromatic ring has no halogen atom such as a fluorine atom as a substituent.

In addition, the leaving group that leaves by the action of an acid may be a 2-cyclopentenyl group having a substituent (an alkyl group and the like), such as a 3-methyl-2-cyclopentenyl group, and a cyclohexyl group having a substituent (an alkyl group and the like), such as a 1,1,4,4-tetramethylcyclohexyl group.

As the repeating unit having an acid-decomposable group, a repeating unit represented by Formula (A) is also preferable.

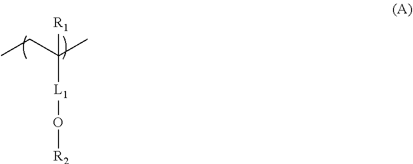

L₁ represents a divalent linking group which may have a fluorine atom or an iodine atom, R₁ represents a hydrogen atom, a fluorine atom, an iodine atom, a fluorine atom, an alkyl group which may have an iodine atom, or an aryl group which may have a fluorine atom or an iodine atom, and R₂ represents a leaving group that leaves by the action of an acid and may have a fluorine atom or an iodine atom. It should be noted that at least one of L₁, R₁, or R₂ has a fluorine atom or an iodine atom.

L₁ represents a divalent linking group which may have a fluorine atom or an iodine atom. Examples of the divalent linking group which may have a fluorine atom or an iodine atom include —CO—, —O—, —S—, —SO—, —SO₂—, a hydrocarbon group which may have a fluorine atom or an iodine atom (for example, an alkylene group, a cycloalkylene group, an alkenylene group, and an arylene group), and a linking group formed by the linking of a plurality of these groups. Among those, as L₁, —CO—, an arylene group, or -arylene group-alkylene group having a fluorine atom or an iodine atom- is preferable, and —CO— or -arylene group-alkylene group having a fluorine atom or an iodine atom- is more preferable.

As the arylene group, a phenylene group is preferable.

The alkylene group may be linear or branched. The number of carbon atoms of the alkylene group is not particularly limited, but is preferably 1 to 10, and more preferably 1 to 3.

The total number of fluorine atoms and iodine atoms included in the alkylene group having a fluorine atom or an iodine atom is not particularly limited, but is preferably 2 or more, more preferably 2 to 10, and still more preferably 3 to 6.

R₁ represents a hydrogen atom, a fluorine atom, an iodine atom, an alkyl group which may have a fluorine atom or an iodine atom, or an aryl group which may have a fluorine atom or an iodine atom.

The alkyl group may be linear or branched. The number of carbon atoms of the alkyl group is not particularly limited, but is preferably 1 to 10, and more preferably 1 to 3.

The total number of fluorine atoms and iodine atoms included in the alkyl group having a fluorine atom or an iodine atom is not particularly limited, but is preferably 1 or more, more preferably 1 to 5, and still more preferably 1 to 3.

The alkyl group may include a heteroatom such as an oxygen atom, other than a halogen atom.

R₂ represents a leaving group that leaves by the action of an acid and may have a fluorine atom or an iodine atom. Examples of the leaving group which may have a fluorine atom or an iodine atom include a leaving group represented by any one of Formula (Y1), . . . , or (Y4), having a fluorine atom or an iodine atom.

As the repeating unit having an acid-decomposable group, a repeating unit represented by Formula (AI) is also preferable.

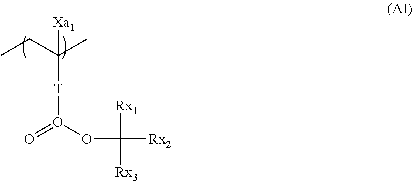

In Formula (AI),

Xa₁ represents a hydrogen atom, or an alkyl group which may have a substituent.

T represents a single bond or a divalent linking group.

Rx₁ to Rx₃ each independently represent an (linear or branched) alkyl group, a (monocyclic or polycyclic) cycloalkyl group, an (linear or branched) alkenyl group, or an (monocyclic or polycyclic) aryl group. It should be noted that in a case where all of Rx₁ to Rx₃ are (linear or branched) alkyl groups, it is preferable that at least two of Rx₁, Rx₂, or Rx₃ are methyl groups.

Two of Rx₁ to Rx₃ may be bonded to each other to form a monocycle or polycycle (a monocyclic or polycyclic cycloalkyl group and the like).

Examples of the alkyl group which may have a substituent, represented by Xa₁, include a methyl group and a group represented by —CH₂—R₁₁. R₁₁ represents a halogen atom (a fluorine atom or the like), a hydroxyl group, or a monovalent organic group, examples thereof include an alkyl group having 5 or less carbon atoms, which may be substituted with a halogen atom, an acyl group having 5 or less carbon atoms, which may be substituted with a halogen atom, and an alkoxy group having 5 or less carbon atoms, which may be substituted with a halogen atom; and an alkyl group having 3 or less carbon atoms is preferable, and a methyl group is more preferable. Xa₁ is preferably a hydrogen atom, a methyl group, a trifluoromethyl group, or a hydroxymethyl group.

Examples of the divalent linking group of T include an alkylene group, an aromatic ring group, a —COO-Rt- group, and an —O-Rt- group. In the formulae, Rt represents an alkylene group or a cycloalkylene group.

T is preferably the single bond or the —COO-Rt- group. In a case where T represents the —COO-Rt-group, Rt is preferably an alkylene group having 1 to 5 carbon atoms, and more preferably a —CH₂— group, a —(CH₂)₂— group, or a —(CH₂)₃— group.

As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group as each of Rx₁ to Rx₃, an aryl group having 6 to 10 carbon atoms is preferable, and examples thereof include a phenyl group, a naphthyl group, and an anthryl group.

As the alkenyl group of each of Rx₁ to Rx₃, a vinyl group is preferable.

As the cycloalkyl group formed by the bonding of two of Rx₁ to Rx₃, a monocyclic cycloalkyl group such as a cyclopentyl group and a cyclohexyl group is preferable. In addition, a polycyclic cycloalkyl group such as a norbornyl group, a tetracyclodecanyl group, a tetracyclododecanyl group, and an adamantyl group is preferable. Among those, a monocyclic cycloalkyl group having 5 or 6 carbon atoms is preferable.

In the cycloalkyl group formed by the bonding of two of Rx₁ to Rx₃, for example, one of the methylene groups constituting the ring may be substituted with a heteroatom such as an oxygen atom, a group including a heteroatom, such as a carbonyl group, or a vinylidene group. In addition, in such the cycloalkyl group, one or more of the ethylene groups constituting the cycloalkane ring may be substituted with a vinylene group.

With regard to the repeating unit represented by Formula (AI), for example, an aspect in which Rx₁ is a methyl group or an ethyl group, and Rx₂ and Rx₃ are bonded to each other to form the above-mentioned cycloalkyl group is preferable.

In a case where each of the groups has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

The repeating unit represented by Formula (AI) is preferably an acid-decomposable tertiary alkyl (meth)acrylate ester-based repeating unit (the repeating unit in which Xa₁ represents a hydrogen atom or a methyl group, and T represents a single bond).

The content of the repeating unit having an acid-decomposable group is preferably 15% by mole or more, more preferably 20% by mole or more, and still more preferably 30% by mole or more with respect to all the repeating units in the resin (A). In addition, the upper limit value is preferably 90% by mole or less, more preferably 80% by mole or less, still more preferably 70% by mole or less, and particularly preferably 60% by mole or less with respect to all the repeating units in the resin (A).

Specific examples of the repeating unit having an acid-decomposable group are shown below, but the present invention is not limited thereto. Furthermore, in the formula, Xa₁ represents H, CH₃, CF₃, or CH₂OH. Rxa and Rxb each independently represent a linear or branched alkyl group having 1 to 5 carbon atoms.

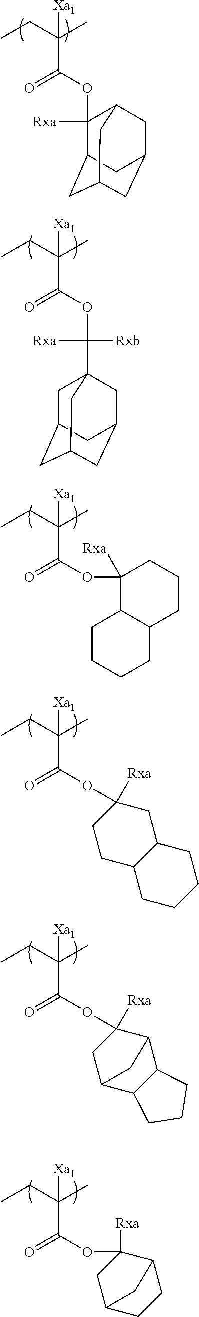

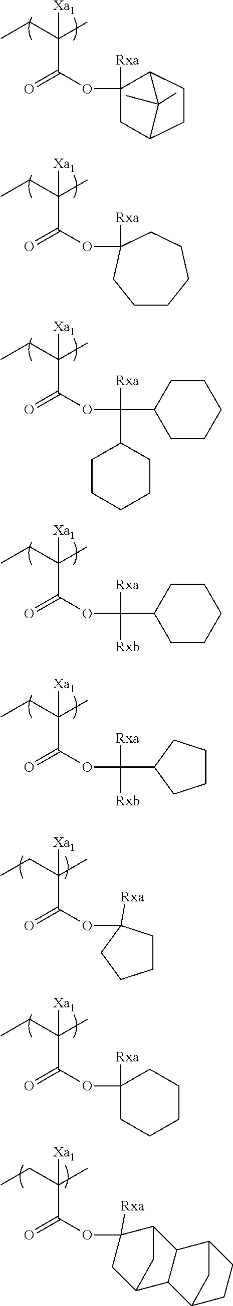

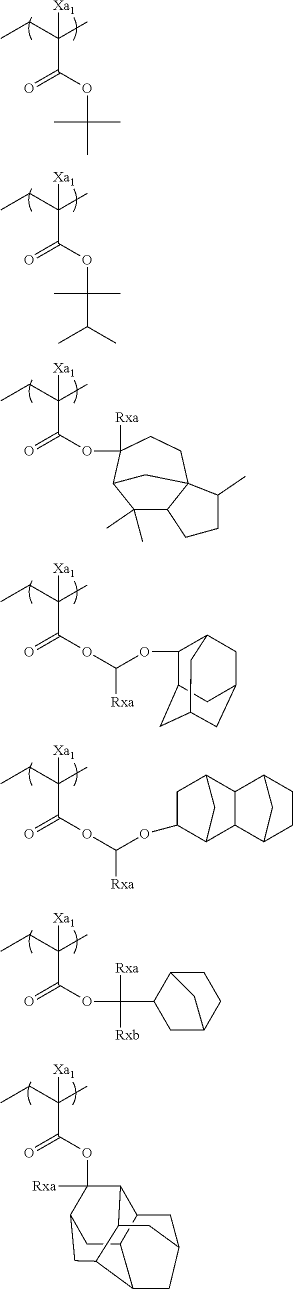

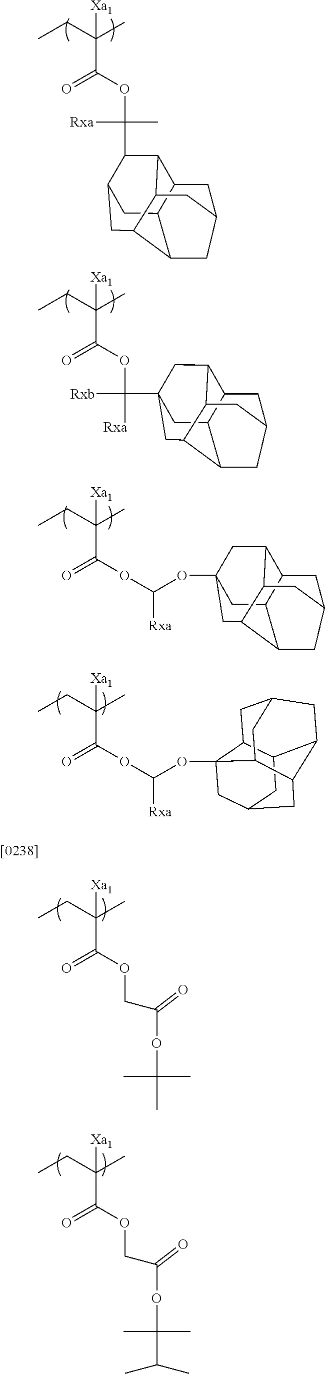

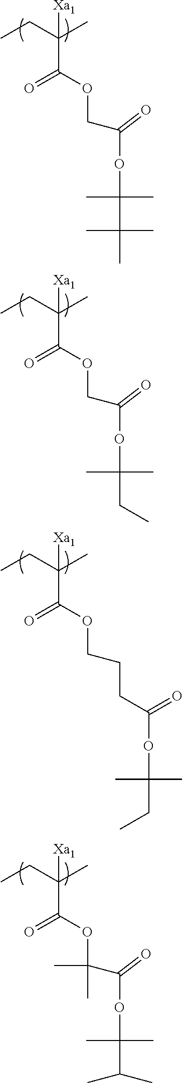

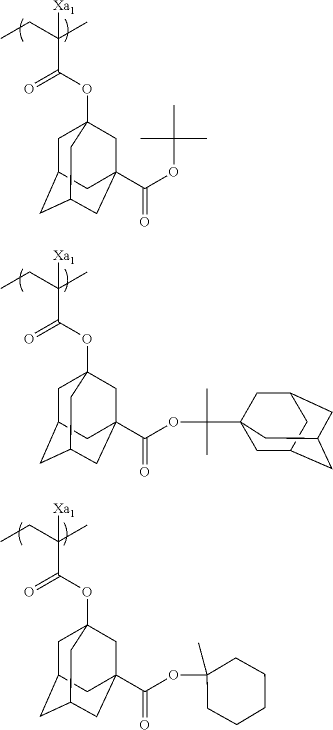

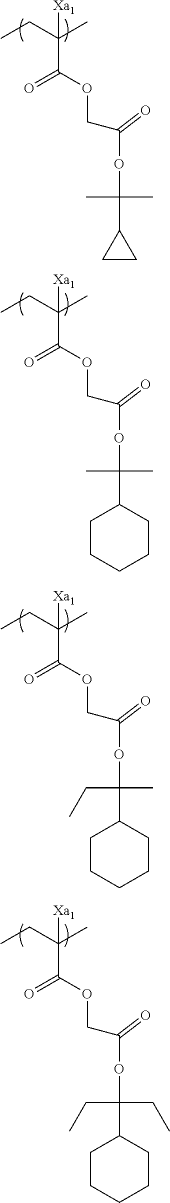

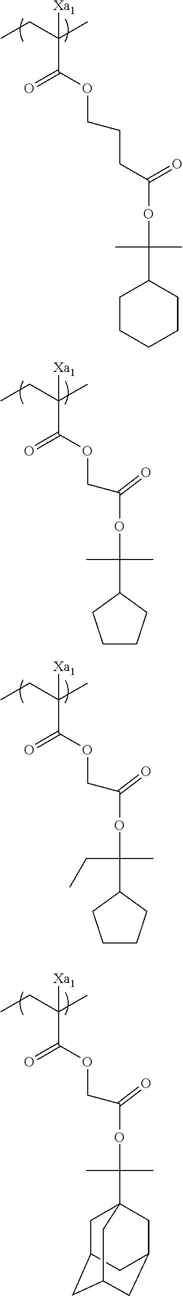

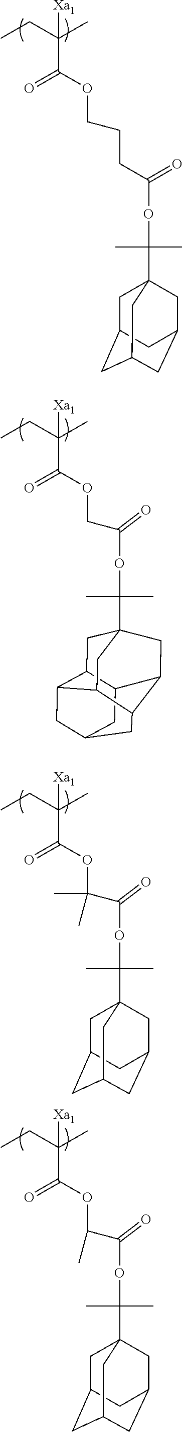

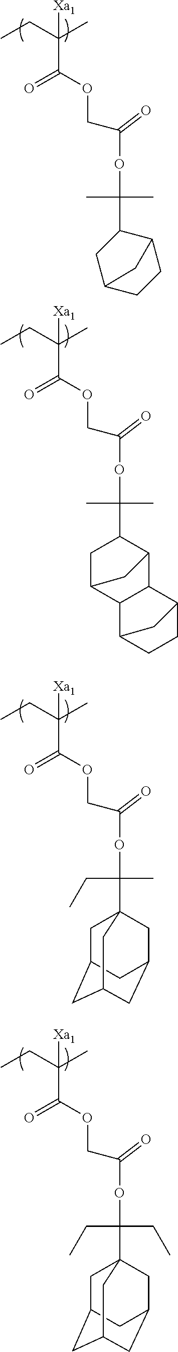

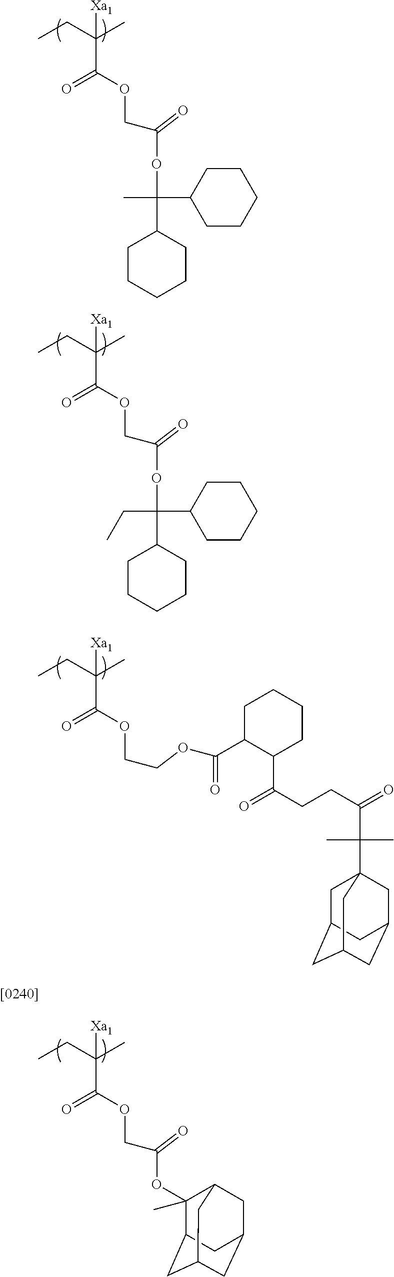

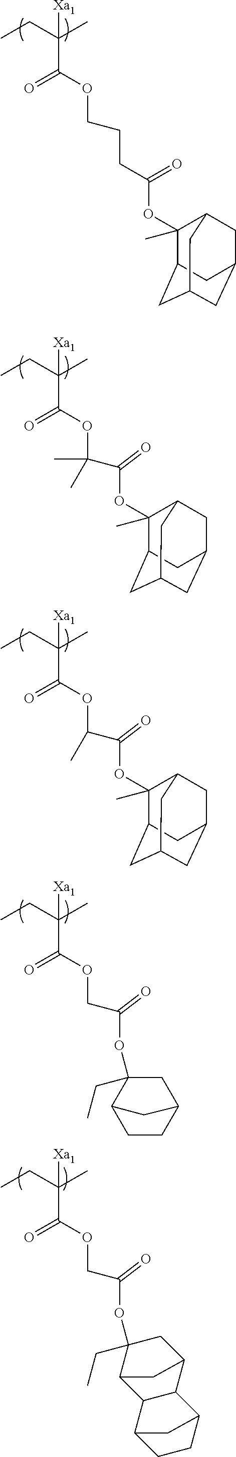

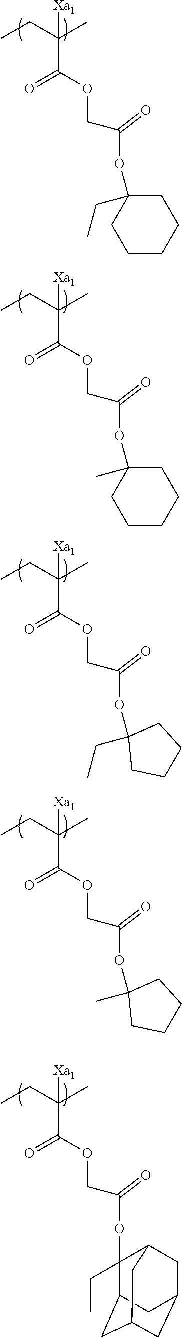

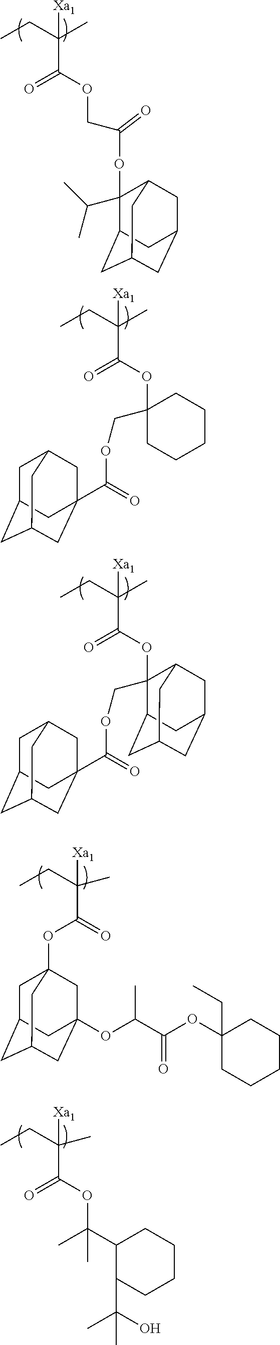

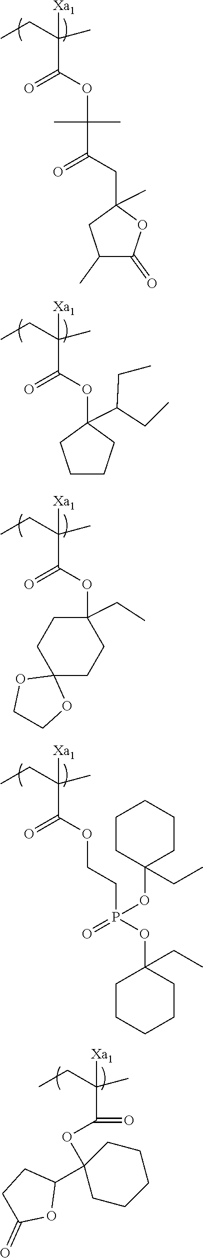

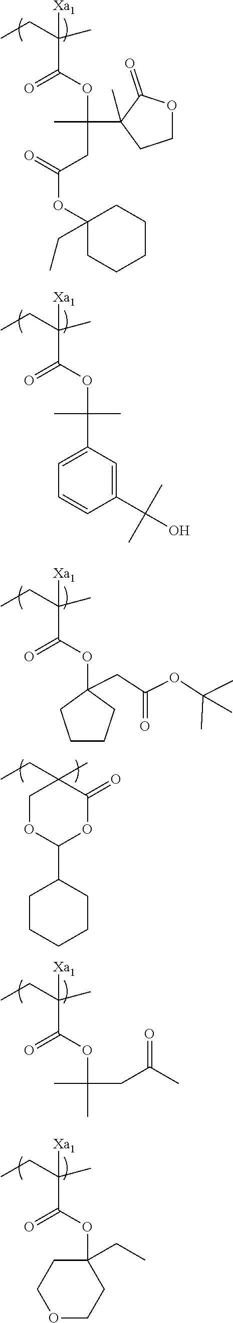

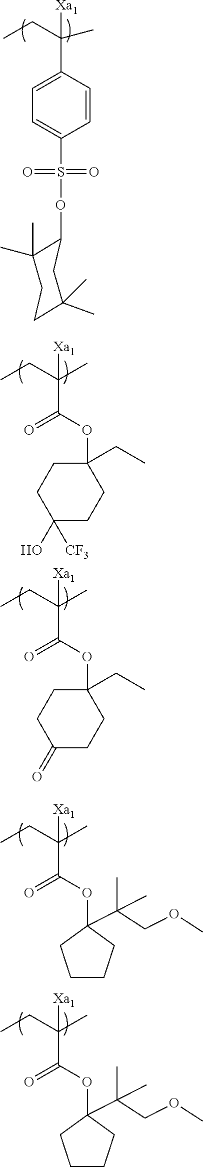

<Repeating Unit Having Acid-Decomposable Group Including Unsaturated Bond>

The resin (A) may have a repeating unit having an acid-decomposable group including an unsaturated bond.

The repeating unit having an acid-decomposable group including an unsaturated bond is preferably a repeating unit represented by Formula (B).

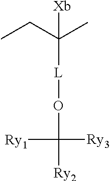

In Formula (B),

Xb represents a hydrogen atom, a halogen atom, or an alkyl group which may have a substituent.

L represents a single bond, or a divalent linking group which may have a substituent.

Ry₁ to Ry₃ each independently represent a linear and branched alkyl group, a monocyclic or polycyclic cycloalkyl group, an alkenyl group, an alkynyl group, or a monocyclic or polycyclic aryl group. It should be noted that at least one of Ry₁ to Ry₃ represents an alkenyl group, an alkynyl group, a monocyclic or polycyclic cycloalkenyl group, or a monocyclic or polycyclic aryl group.

Two of Ry₁ to Ry₃ may be bonded to each other to form a monocycle or polycycle (a monocyclic or polycyclic cycloalkyl group, a cycloalkenyl group, or the like).

Examples of the alkyl group which may have a substituent, represented by Xb, include a methyl group and a group represented by —CH₂—R₁₁. R₁₁ represents a halogen atom (a fluorine atom or the like), a hydroxyl group, or a monovalent organic group, examples thereof include an alkyl group having 5 or less carbon atoms, which may be substituted with a halogen atom, an acyl group having 5 or less carbon atoms, which may be substituted with a halogen atom, and an alkoxy group having 5 or less carbon atoms, which may be substituted with a halogen atom; and an alkyl group having 3 or less carbon atoms is preferable, and a methyl group is more preferable. As Xb, a hydrogen atom, a fluorine atom, a methyl group, a trifluoromethyl group, or a hydroxymethyl group is preferable.

Examples of the divalent linking group of L include an -Rt- group, a —CO— group, a —COO-Rt- group, a —COO-Rt-CO— group, an -Rt-CO— group, and an —O-Rt- group. In the formulae, Rt represents an alkylene group, a cycloalkylene group, or an aromatic ring group, and is preferably the aromatic ring group.

As L, the -Rt- group, the —CO— group, the —COO-Rt-CO— group, or the -Rt-CO— group is preferable. Rt may have a substituent such as, for example, a halogen atom, a hydroxyl group, or an alkoxy group. The aromatic group is preferable.

As the alkyl group of each of Ry₁ to Ry₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Ry₁ to Ry₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group of each of Ry₁ to Ry₃, an aryl group having 6 to 10 carbon atoms is preferable, and examples thereof include a phenyl group, a naphthyl group, and an anthryl group.

As the alkenyl group of each of Ry₁ to Ry₃, a vinyl group is preferable.

As the alkynyl group of each of Ry₁ to Ry₃, an ethynyl group is preferable.

As the cycloalkenyl group of each of Ry₁ to Ry₃, a structure including a double bond in a part of a monocyclic cycloalkyl group such as a cyclopentyl group and a cyclohexyl group is preferable.

As the cycloalkyl group formed by the bonding of two of Ry₁ to Ry₃, a monocyclic cycloalkyl group such as a cyclopentyl group and a cyclohexyl group is preferable. In addition, a polycyclic cycloalkyl group such as a norbornyl group, a tetracyclodecanyl group, a tetracyclododecanyl group, and an adamantyl group is preferable. Among those, a monocyclic cycloalkyl group having 5 or 6 carbon atoms is more preferable.

In the cycloalkyl group or cycloalkenyl group formed by the bonding of two of Ry₁ to Ry₃, for example, one of the methylene groups constituting the ring may be substituted with a heteroatom such as an oxygen atom, a group including a heteroatom, such as a carbonyl group, an —SO₂— group, and an —SO₃— group, or a vinylidene group, or a combination thereof. In addition, in the cycloalkyl group or cycloalkenyl group, one or more of the ethylene groups constituting the cycloalkane ring or the cycloalkene ring may be substituted with a vinylene group.

In the repeating unit represented by Formula (B), for example, an aspect in which Ry₁ is a methyl group, an ethyl group, a vinyl group, an allyl group, or an aryl group, and Ry₂ and Rx₃ are bonded to each other to form the above-mentioned cycloalkyl group or cycloalkenyl group is preferable.

In a case where each of the groups has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

As the repeating unit represented by Formula (B), an acid-decomposable (meth)acrylic acid tertiary ester-based repeating unit (a repeating unit in which Xb represents a hydrogen atom or a methyl group, and L represents a —CO— group), an acid-decomposable hydroxystyrene tertiary alkyl ether-based repeating unit (a repeating unit in which Xb represents a hydrogen atom or a methyl group and L represents a phenyl group), or an acid-decomposable styrenecarboxylic acid tertiary ester-based repeating unit (a repeating unit in which Xb represents a hydrogen atom or a methyl group, and L represents a -Rt-CO— group (Rt is an aromatic group)) is preferable.

The content of the repeating unit having an acid-decomposable group including an unsaturated bond is preferably 15% by mole or more, more preferably 20% by mole or more, and still more preferably 30% by mole or more with respect to all the repeating units in the resin (A). In addition, the upper limit value is preferably 80% by mole or less, more preferably 70% by mole or less, and still more preferably 60% by mole or less with respect to all the repeating units in the resin (A).

Specific examples of the repeating unit having an acid-decomposable group including an unsaturated bond are shown below, but the present invention is not limited thereto.

Furthermore, in the formula, Xb has the same definition as Xb in Formula (B). L₁ has the same definition as L in Formula (B). Ar represents an aromatic group. R represents a substituent such as an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (for example, —OCOR^{A} and —COOR^{A}, where R^{A} represents an alkyl group or fluorinated alkyl group having 1 to 20 carbon atoms), and a carboxyl group, and a hydrogen atom. R′ represents a linear or branched alkyl group, a monocyclic or polycyclic cycloalkyl group, an alkenyl group, an alkynyl group, or a monocyclic or polycyclic aryl group. Q represents a heteroatom such as an oxygen atom, a group including a heteroatom, such as a carbonyl group, —SO₂—, and —SO₃—, a vinylidene group, or a combination thereof n, m, and 1 each represent an integer of 0 or more.

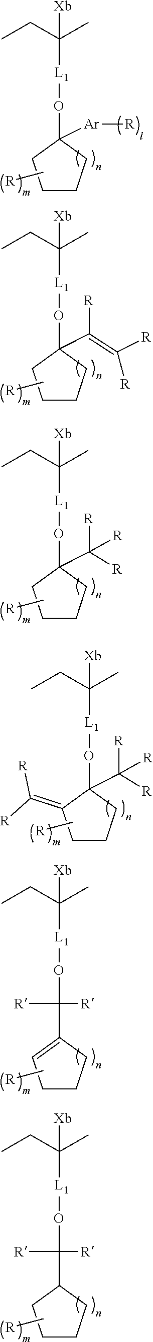

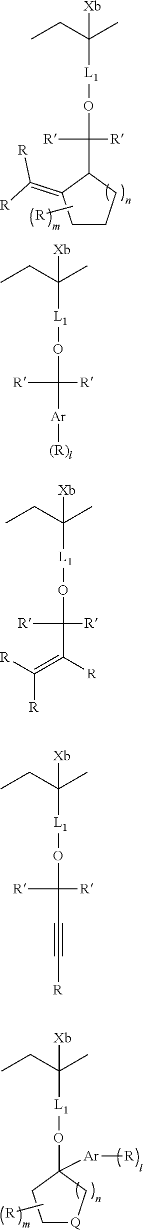

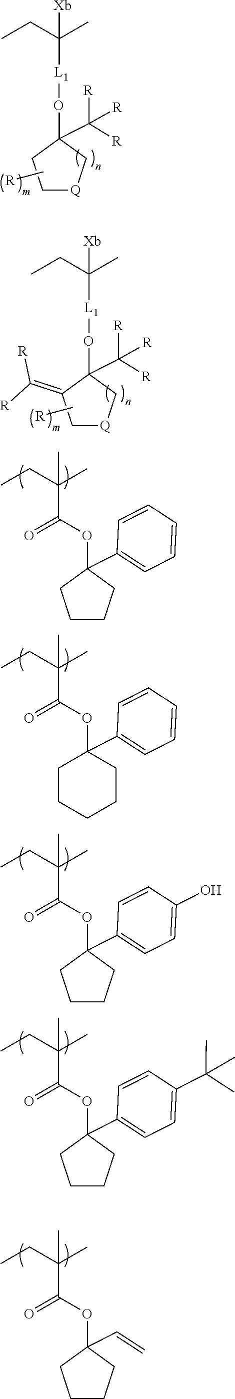

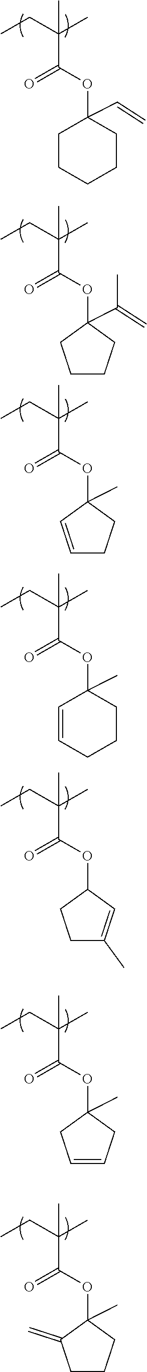

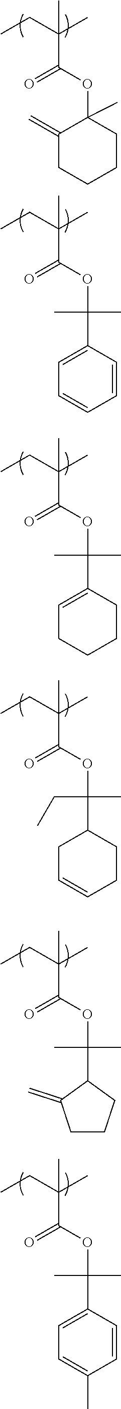

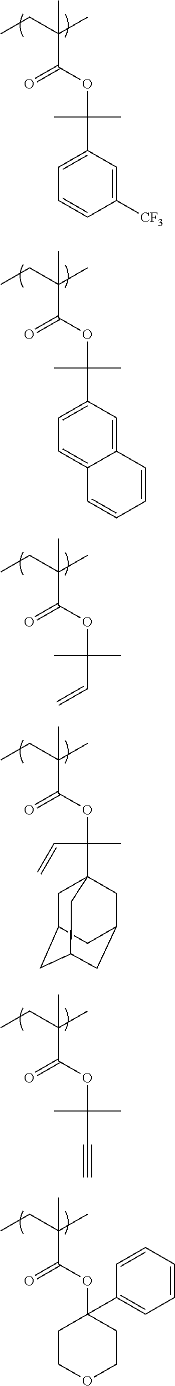

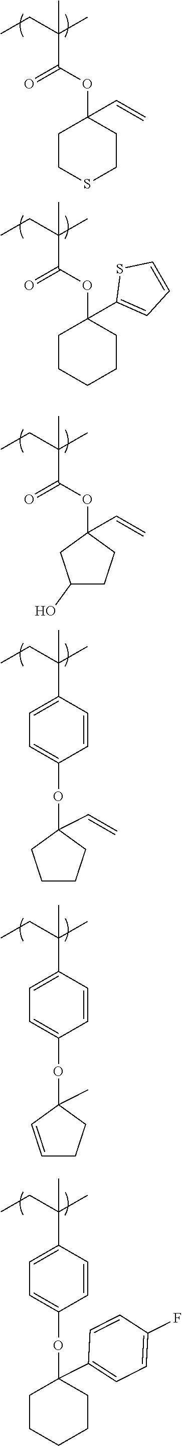

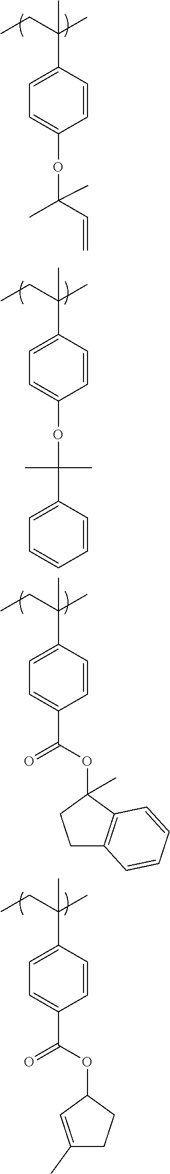

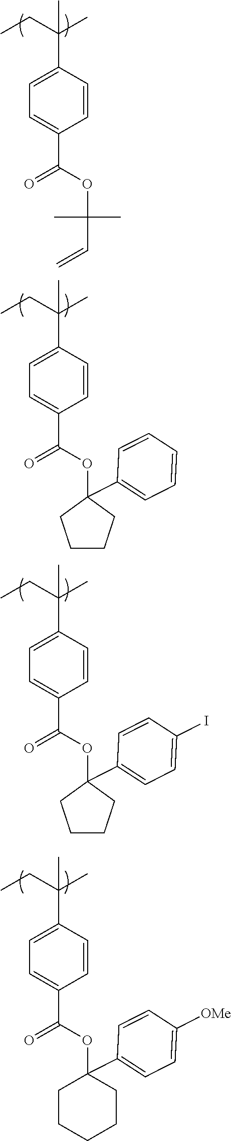

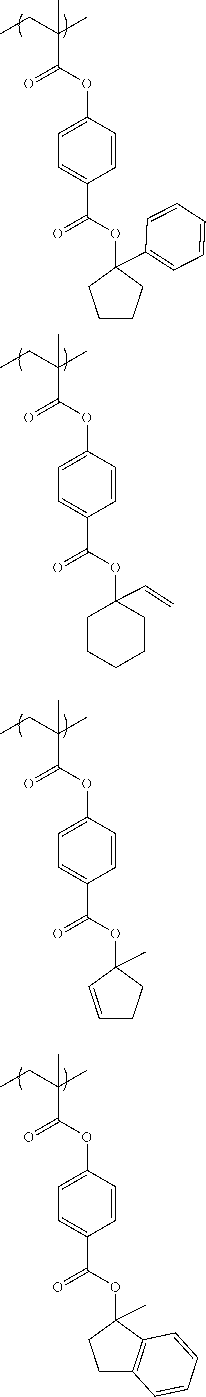

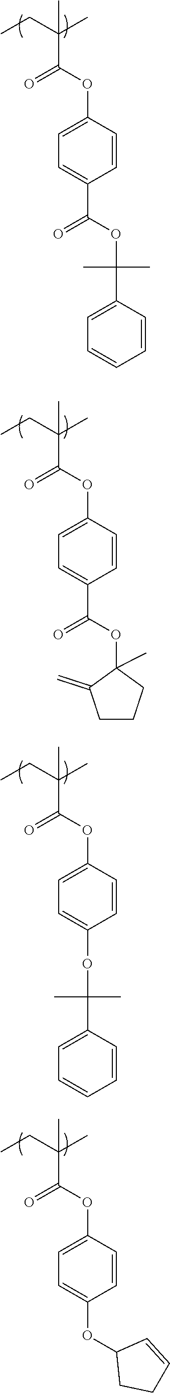

The resin (A) may include a repeating unit other than the above-mentioned repeating units.

For example, the resin (A) may include at least one repeating unit selected from the group consisting of the following group A and/or at least one repeating unit selected from the group consisting of the following group B.

Group A: A group consisting of the following repeating units (20) to (29).

(20) A repeating unit having an acid group, which will be described later

(21) A repeating unit having a fluorine atom or an iodine atom, which will be described later

(22) A repeating unit having a lactone group, a sultone group, or a carbonate group, which will be described later

(23) A repeating unit having a photoacid generating group, which will be described later

(24) A repeating Unit represented by Formula (V-1) or Formula (V-2), which will be described later

(25) A repeating unit represented by Formula (A), which will be described later

(26) A repeating unit represented by Formula (B), which will be described later

(27) A repeating unit represented by Formula (C), which will be described later

(28) A repeating unit represented by Formula (D), which will be described later

(29) A repeating unit represented by Formula (E), which will be described later

Group B: A group consisting of the following repeating units (30) to (32).

(30) A repeating unit having at least one group selected from a lactone group, a sultone group, a carbonate group, a hydroxyl group, a cyano group, or an alkali-soluble group, which will be described later

(31) A repeating unit having an alicyclic hydrocarbon structure and not exhibiting acid decomposability described later

(32) A repeating unit represented by Formula (III) having neither a hydroxyl group nor a cyano group, which will be described later

The resin (A) preferably has an acid group, and preferably includes a repeating unit having an acid group, as will be described later. Incidentally, the definition of the acid group will be described later together with a suitable aspect of the repeating unit having an acid group. In a case where the resin (A) has an acid group, the interaction between the resin (A) and an acid generated from the compound (X) is more excellent. As a result, the diffusion of the acid is further suppressed, and the cross-sectional shape of a pattern thus formed can be further rectangularized.

In a case where the resist composition is used as an actinic ray-sensitive or radiation-sensitive resin composition for EUV, it is preferable that the resin (A) has at least one repeating unit selected from the group consisting of the group A.

In addition, in a case where the resist composition is used as the actinic ray-sensitive or radiation-sensitive resin composition for EUV, it is preferable that the resin (A) includes at least one of a fluorine atom or an iodine atom. In a case where the resin (A) includes both a fluorine atom and an iodine atom, the resin (A) may have one repeating unit including both a fluorine atom and an iodine atom, and the resin (A) may include two kinds of repeating units, that is, a repeating unit having a fluorine atom and a repeating unit having an iodine atom.

In addition, in a case where the resist composition is used as an actinic ray-sensitive or radiation-sensitive resin composition for EUV, it is also preferable that the resin (A) has a repeating unit having an aromatic group.

In a case where the resist composition is used as an actinic ray-sensitive or radiation-sensitive resin composition for ArF, it is preferable that the resin (A) has at least one repeating unit selected from the group consisting of the group B.

Furthermore, in a case where the resist composition is used as the actinic ray-sensitive or radiation-sensitive resin composition for ArF, it is preferable that the resin (A) includes neither a fluorine atom nor a silicon atom.

In addition, in a case where the resist composition is used as the actinic ray-sensitive or radiation-sensitive resin composition for ArF, it is preferable that the resin (A) does not have an aromatic group.

<Repeating Unit Having Acid Group>

The resin (A) preferably has a repeating unit having an acid group.

As the acid group, an acid group having a pKa of 13 or less is preferable. The acid dissociation constant of the acid group is preferably 13 or less, more preferably 3 to 13, and still more preferably 5 to 10, as described above.

In a case where the resin (A) has an acid group having a pKa of 13 or less, the content of the acid group in the resin (A) is not particularly limited, but is 0.2 to 6.0 mmol/g in many cases. Among those, the content of the acid group is preferably 0.8 to 6.0 mmol/g, more preferably 1.2 to 5.0 mmol/g, and still more preferably 1.6 to 4.0 mmol/g. In a case where the content of the acid group is within the range, the progress of development is improved, and thus, the shape of a pattern thus formed is excellent and the resolution is also excellent.

As the acid group, for example, a carboxyl group, a phenolic hydroxyl group, a fluorinated alcohol group (preferably a hexafluoroisopropanol group), a sulfonic acid group, a sulfonamide group, an isopropanol group, or the like is preferable.

In addition, in the hexafluoroisopropanol group, one or more (preferably one or two) fluorine atoms may be substituted with a group (an alkoxycarbonyl group and the like) other than a fluorine atom. —C(CF₃)(OH)—CF₂— formed as above is also preferable as the acid group. In addition, one or more fluorine atoms may be substituted with a group other than a fluorine atom to form a ring including —C(CF₃)(OH)—CF₂—.

The repeating unit having an acid group is preferably a repeating unit different from a repeating unit having the structure in which a polar group is protected by the leaving group that leaves by the action of an acid as described above, and a repeating unit having a lactone group, a sultone group, or a carbonate group which will be described later.

A repeating unit having an acid group may have a fluorine atom or an iodine atom.

As the repeating unit having an acid group, a repeating unit represented by Formula (B) is preferable.

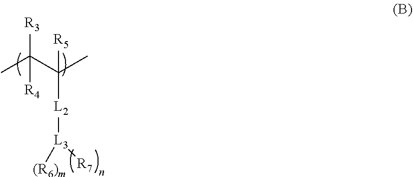

R₃ represents a hydrogen atom or a monovalent organic group which may have a fluorine atom or an iodine atom.

The monovalent organic group which may have a fluorine atom or an iodine atom is preferably a group represented by -L₄-R₈. L₄ represents a single bond or an ester group. R₈ is an alkyl group which may have a fluorine atom or an iodine atom, a cycloalkyl group which may have a fluorine atom or an iodine atom, an aryl group which may have a fluorine atom or an iodine atom, or a group formed by combination thereof.

R₄ and R₅ each independently represent a hydrogen atom, a fluorine atom, an iodine atom, or an alkyl group which may have a fluorine atom or an iodine atom.

L₂ represents a single bond, an ester group, or a divalent group formed by combination of —CO—, —O—, and an alkylene group (which preferably has 1 to 6 carbon atoms, and may be linear or branched; —CH₂— may be substituted with a halogen atom).

L₃ represents an (n+m+1)-valent aromatic hydrocarbon ring group or an (n+m+1)-valent alicyclic hydrocarbon ring group. Examples of the aromatic hydrocarbon ring group include a benzene ring group and a naphthalene ring group. The alicyclic hydrocarbon ring group may be a monocycle or a polycycle, and examples thereof include a cycloalkyl ring group, a norbornene ring group, and an adamantane ring group.

R₆ represents a hydroxyl group or a fluorinated alcohol group. The fluorinated alcohol group is preferably a monovalent group represented by Formula (3L).

*-L_{6X}-R_{6X} (3L)

L_{6X} represents a single bond or a divalent linking group. The divalent linking group is not particularly limited, but examples thereof include-CO—, —O—, —SO—, —SO₂—, —NR^{A}— an alkylene group (which preferably has 1 to 6 carbon atoms, and may be linear or branched) which may have a substituent, and a divalent linking group formed by combination of a plurality of these groups. Examples of R^{A} include a hydrogen atom or an alkyl group having 1 to 6 carbon atoms. In addition, the alkylene group may have a substituent. Examples of the substituent include a halogen atom (preferably a fluorine atom) and a hydroxyl group. R_{6X} represents a hexafluoroisopropanol group. Furthermore, in a case where R₆ is a hydroxyl group, it is also preferable that L₃ is an (n+m+1)-valent aromatic hydrocarbon ring group.

R₇ represents a halogen atom. Examples of the halogen atom include a fluorine atom, a chlorine atom, a bromine atom, or an iodine atom.

m represents an integer of 1 or more. m is preferably an integer of 1 to 3, and more preferably an integer of 1 or 2.

n represents 0 or an integer of 1 or more. n is preferably an integer of 1 to 4.

Furthermore, (n+m+1) is preferably an integer of 1 to 5.

* represents a bonding position.

Examples of the repeating unit having an acid group include the following repeating units.

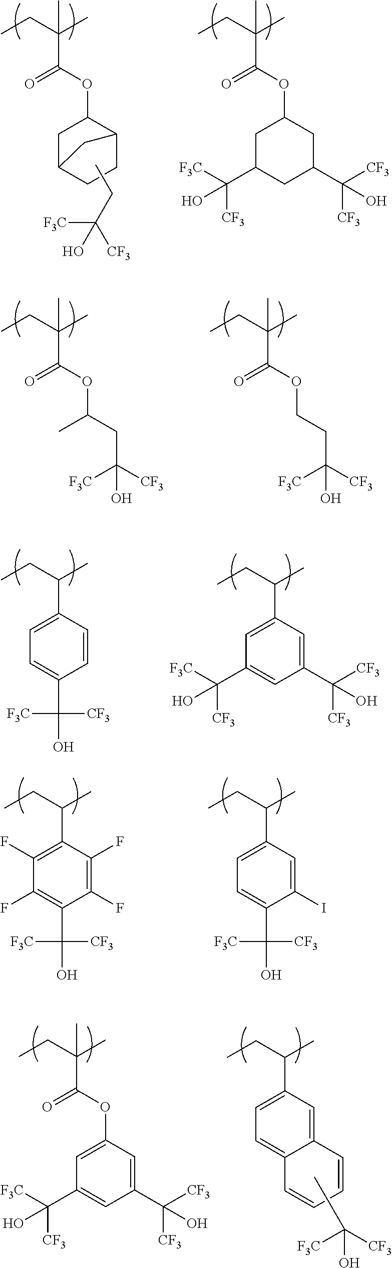

As the repeating unit having an acid group, a repeating unit represented by Formula (I) is also preferable.

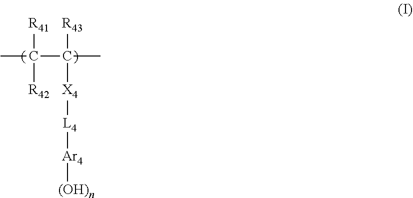

In Formula (I),

R₄₁, R₄₂, and R₄₃ each independently represent a hydrogen atom, an alkyl group, a cycloalkyl group, a halogen atom, a cyano group, or an alkoxycarbonyl group. It should be noted that R₄₂ may be bonded to Ar₄ to form a ring, in which case R₄₂ represents a single bond or an alkylene group.

X₄ represents a single bond, —COO—, or —CONR₆₄—, and R₆₄ represents a hydrogen atom or an alkyl group.

L₄ represents a single bond or an alkylene group.

Ar₄ represents an (n+1)-valent aromatic ring group, and in a case where Ar₄ is bonded to R₄₂ to form a ring, Ar₄ represents an (n+2)-valent aromatic ring group.

n represents an integer of 1 to 5.

As the alkyl group represented by each of R₄₁, R₄₂, and R₄₃ in Formula (I), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group is preferable, an alkyl group having 8 or less carbon atoms is more preferable, and an alkyl group having 3 or less carbon atoms is still more preferable.

The cycloalkyl group of each of R₄₁, R₄₂, and R₄₃ in Formula (I) may be monocyclic or polycyclic. Among those, a monocyclic cycloalkyl group having 3 to 8 carbon atoms, such as a cyclopropyl group, a cyclopentyl group, and a cyclohexyl group, is preferable.

Examples of the halogen atom of each of R₄₁, R₄₂, and R₄₃ in Formula (I) include a fluorine atom, a chlorine atom, a bromine atom, and an iodine atom, and the fluorine atom is preferable.

As the alkyl group included in the alkoxycarbonyl group of each of R₄₁, R₄₂, and R₄₃ in Formula (I), the same ones as the alkyl group in each of R₄₁, R₄₂, and R₄₃ are preferable.

As the substituent in each of the groups, for example, an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, a cyano group, or a nitro group is preferable, and the substituent more preferably has 8 or less carbon atoms.

Ar₄ represents an (n+1)-valent aromatic ring group. The divalent aromatic ring group in a case where n is 1 is preferably for example, an arylene group having 6 to 18 carbon atoms, such as a phenylene group, a tolylene group, a naphthylene group, and an anthracenylene group, or a divalent aromatic ring group including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Furthermore, the aromatic ring group may have a substituent.

Specific examples of the (n+1)-valent aromatic ring group in a case where n is an integer of 2 or more include groups formed by removing any (n - 1) hydrogen atoms from the above-mentioned specific examples of the divalent aromatic ring group.

The (n+1)-valent aromatic ring group may further have a substituent.

Examples of the substituent which can be contained in the alkyl group, the cycloalkyl group, the alkoxycarbonyl group, the alkylene group, and the (n+1)-valent aromatic ring group, each mentioned above, include the alkyl groups; the alkoxy groups such as a methoxy group, an ethoxy group, a hydroxyethoxy group, a propoxy group, a hydroxypropoxy group, and a butoxy group; the aryl groups such as a phenyl group; and the like, as mentioned for each of R₄₁, R₄₂, and R₄₃ in Formula (I).

Examples of the alkyl group of R₆₄ in —CONR₆₄— represented by X₄ (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and an alkyl group having 8 or less carbon atoms, is preferable.

As X₄, a single bond, —COO—, or —CONH— is preferable, and the single bond or —COO— is more preferable.

As the alkylene group in L₄, an alkylene group having 1 to 8 carbon atoms, such as a methylene group, an ethylene group, a propylene group, a butylene group, a hexylene group, and an octylene group, is preferable.

As Ar₄, an aromatic ring group having 6 to 18 carbon atoms is preferable, and a benzene ring group, a naphthalene ring group, and a biphenylene ring group are more preferable.

The repeating unit represented by Formula (I) is preferably equipped with a hydroxystyrene structure. That is, Ar₄ is preferably the benzene ring group.

As the repeating unit represented by Formula (I), a repeating unit represented by Formula (1) is preferable.

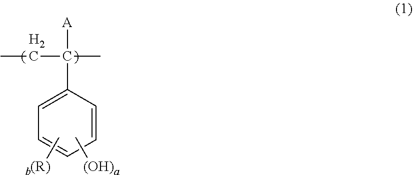

In Formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group, and in a case where a plurality of R's are present, R's may be the same as or different from each other. In a case where there are a plurality of R's, R's may be bonded to each other to form a ring. As R, the hydrogen atom is preferable.

a represents an integer of 1 to 3.

b represents an integer of 0 to (5-a).

The repeating unit having an acid group is exemplified below. In the formulae, a represents 1 or 2.

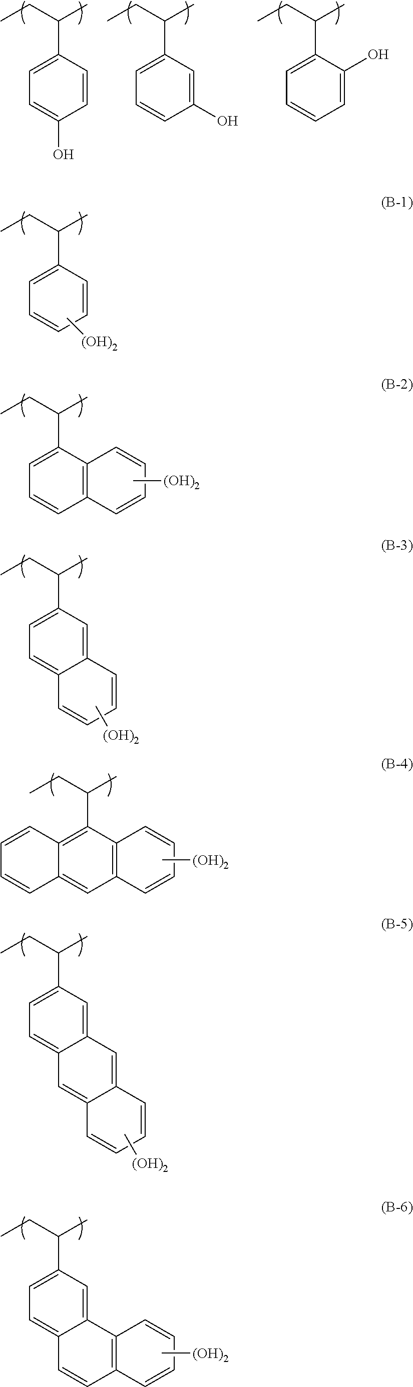

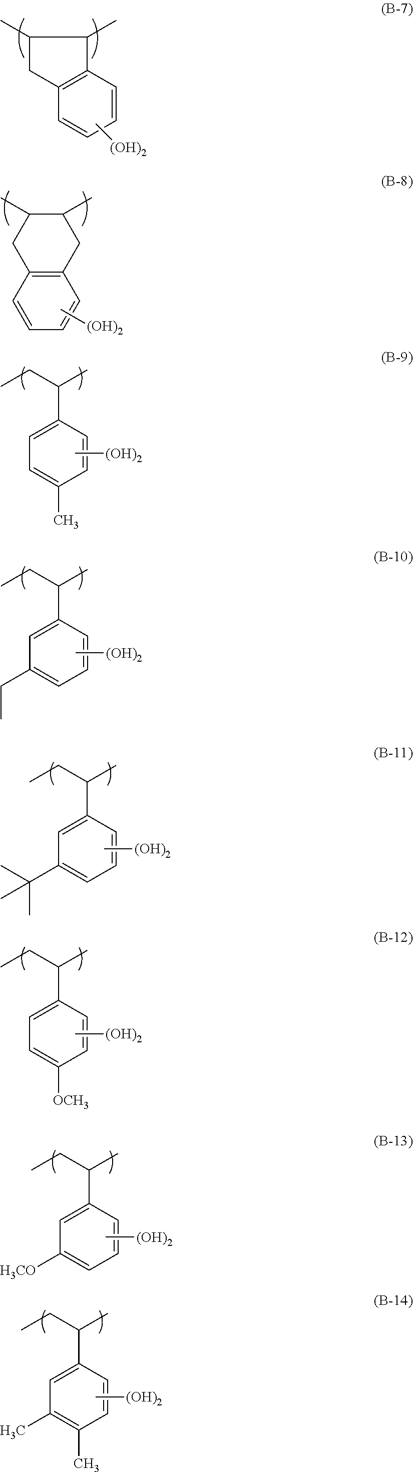

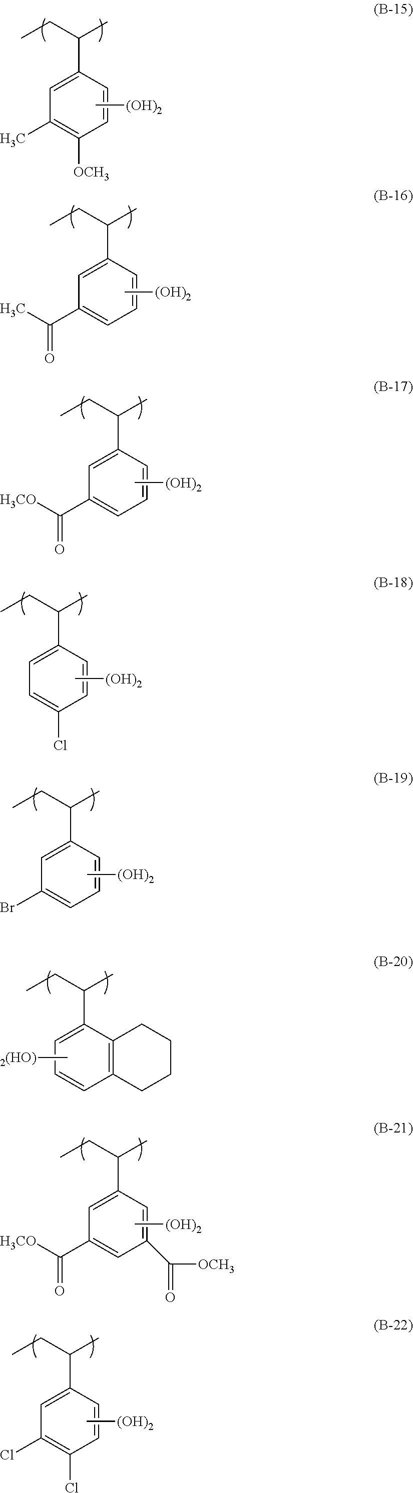

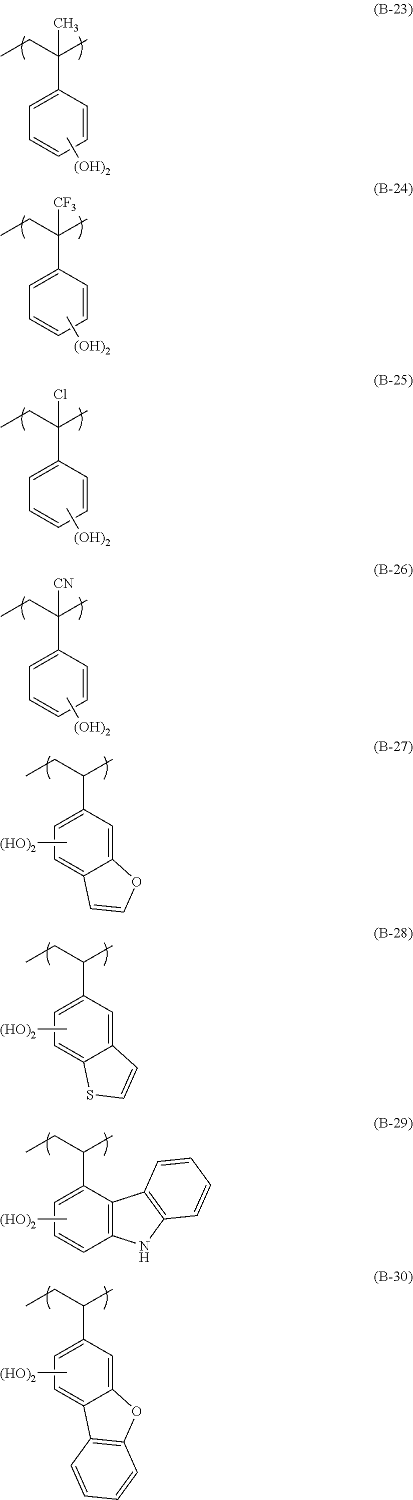

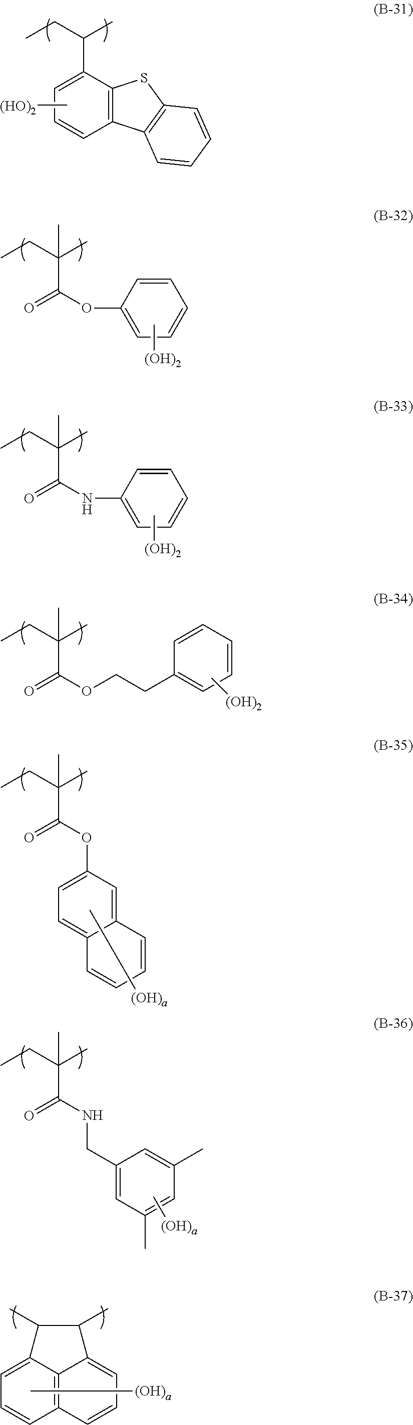

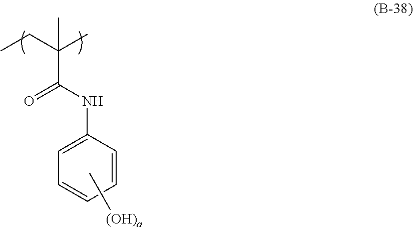

Moreover, among the repeating units, the repeating units specifically described below are preferable. In the formula, R represents a hydrogen atom or a methyl group, and a represents 2 or 3.

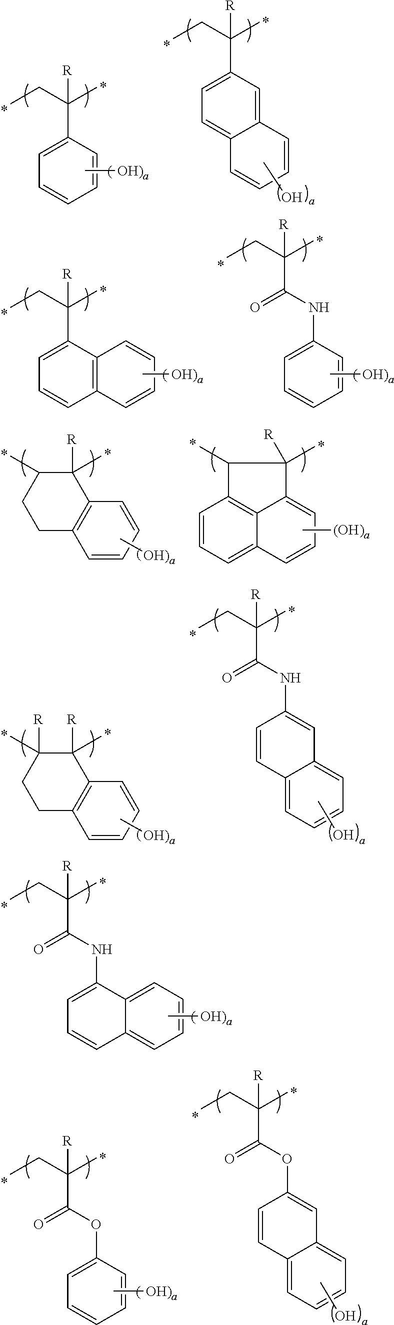

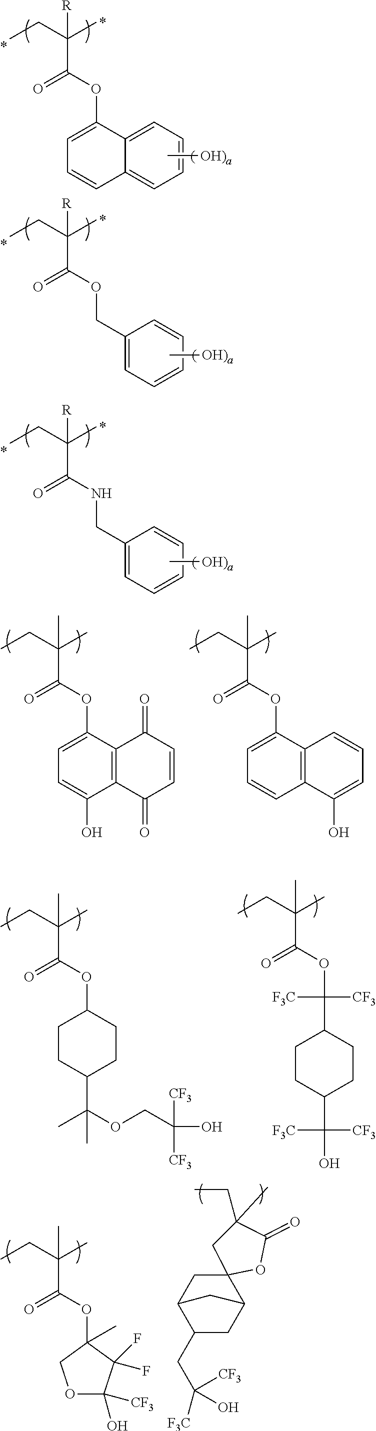

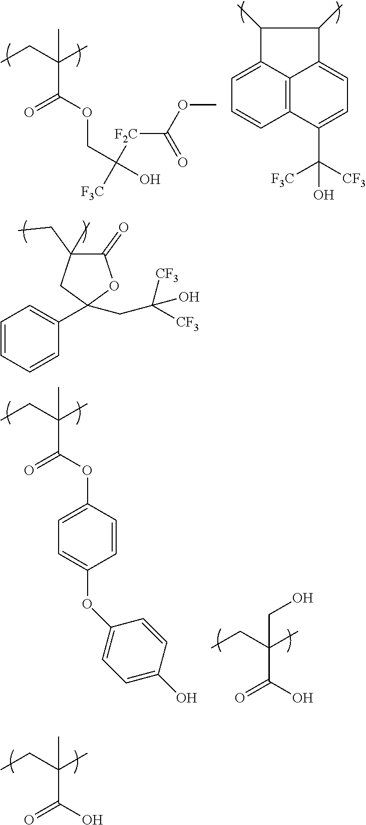

The content of the repeating unit having an acid group is preferably 10% by mole or more, and more preferably 15% by mole or more with respect to all the repeating units in the resin (A). In addition, the upper limit value is preferably 70% by mole or less, more preferably 65% by mole or less, and still more preferably 60% by mole or less with respect to all the repeating units in the resin (A).

<Repeating Unit Having Fluorine Atom or Iodine Atom>

The resin (A) may have a repeating unit having a fluorine atom or an iodine atom in addition to <Repeating Unit Having Acid-Decomposable Group> and <Repeating Unit Having Acid Group> mentioned above. In addition, <Repeating Unit Having Fluorine Atom or Iodine Atom> mentioned herein is preferably different from other kinds of repeating units belonging to the group A, such as <Repeating Unit Having Lactone Group, Sultone Group, or Carbonate Group> and <Repeating Unit Having Photoacid Generating Group>, which will be described later.

As the repeating unit having a fluorine atom or an iodine atom, a repeating unit represented by Formula (C) is preferable.

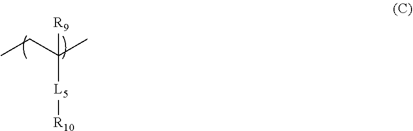

L₅ represents a single bond or an ester group.

R₉ represents a hydrogen atom, or an alkyl group which may have a fluorine atom or an iodine atom.

R₁₀ represents a hydrogen atom, an alkyl group which may have a fluorine atom or an iodine atom, a cycloalkyl group which may have a fluorine atom or an iodine atom, an aryl group which may have a fluorine atom or an iodine atom, or a group formed by combination thereof.

The repeating unit having a fluorine atom or an iodine atom will be exemplified below.

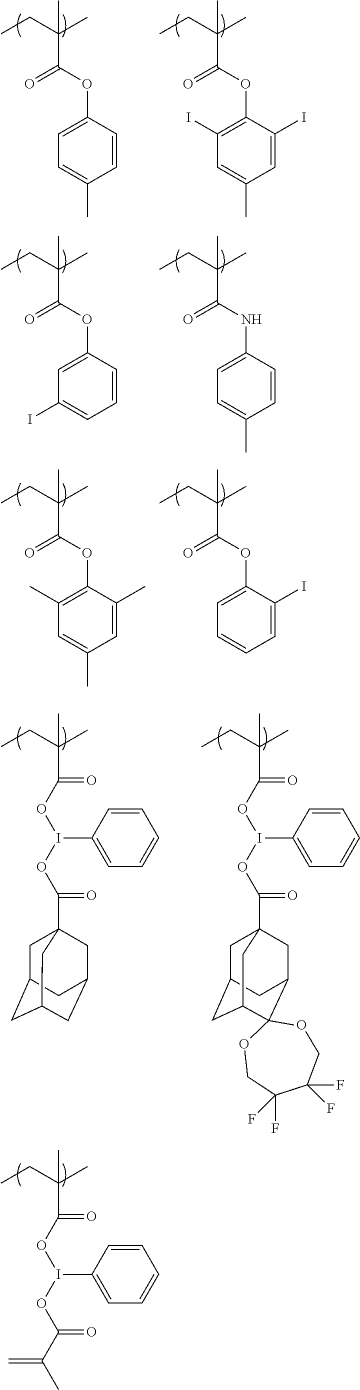

The content of the repeating unit having a fluorine atom or an iodine atom is preferably 0% by mole or more, more preferably 5% by mole or more, and still more preferably 10% by mole or more with respect to all the repeating units in the resin (A). In addition, the upper limit value is preferably 50% by mole or less, more preferably 45% by mole or less, and still more preferably 40% by mole or less with respect to all the repeating units in the resin (A).

Furthermore, since the repeating unit having a fluorine atom or an iodine atom does not include <Repeating Unit Having Acid-Decomposable Group> and <Repeating Unit Having Acid Group> as described above, the content of the repeating unit having a fluorine atom or an iodine atom is also intended to be the content of the repeating unit having a fluorine atom or an iodine atom excluding <Repeating Unit Having Acid-Decomposable Group> and <Repeating Unit Having Acid Group>.

The total content of the repeating units including at least one of a fluorine atom or an iodine atom in the repeating units of the resin (A) is preferably 10% by mole or more, more preferably 20% by mole or more, still more preferably 30% by mole or more, and particularly preferably 40% by mole or more with respect to all the repeating units of the resin (A). The upper limit value is not particularly limited, and is, for example, 100% by mole or less with respect to all the repeating units of the resin (A).

In addition, examples of the repeating unit including at least one of a fluorine atom or an iodine atom include a repeating unit which has a fluorine atom or an iodine atom, and has an acid-decomposable group, a repeating unit which has a fluorine atom or an iodine atom, and has an acid group, and a repeating unit having a fluorine atom or an iodine atom.

<Repeating Unit Having Lactone Group, Sultone Group, or Carbonate Group>

The resin (A) may have a repeating unit having at least one selected from the group consisting of a lactone group, a sultone group, and a carbonate group (hereinafter also collectively referred to as a “repeating unit having a lactone group, a sultone group, or a carbonate group”).

It is also preferable that the repeating unit having a lactone group, a sultone group, or a carbonate group does not have a hydroxyl group and an acid group such as a hexafluoropropanol group.

The lactone group or the sultone group may have a lactone structure or a sultone structure. The lactone structure or the sultone structure is preferably a 5- to 7-membered ring lactone structure or a 5- to 7-membered ring sultone structure. Among those, the structure is more preferably a 5- to 7-membered ring lactone structure with which another ring structure is fused so as to form a bicyclo structure or a spiro structure, or a 5- to 7-membered ring sultone structure with which another ring structure is fused so as to form a bicyclo structure or a spiro structure.

The resin (A) preferably has a repeating unit having a lactone group or a sultone group, formed by extracting one or more hydrogen atoms from a ring member atom of a lactone structure represented by any one of Formula (LC1-1), . . . , or (LC1-21) or a sultone structure represented by any one of Formula (SL1-1), (SL1-2), or (SL1-3).

In addition, the lactone group or the sultone group may be bonded directly to the main chain. For example, a ring member atom of the lactone group or the sultone group may constitute the main chain of the resin (A).

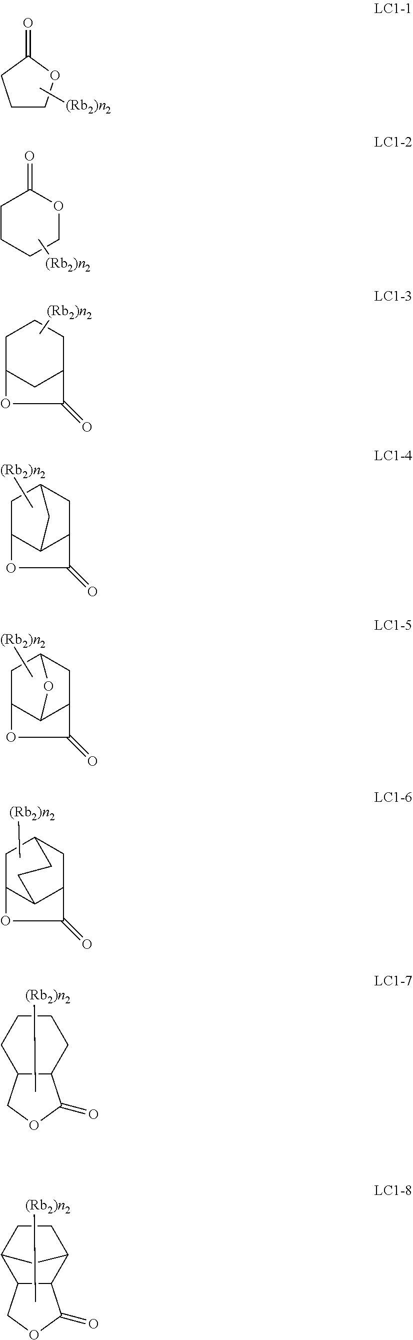

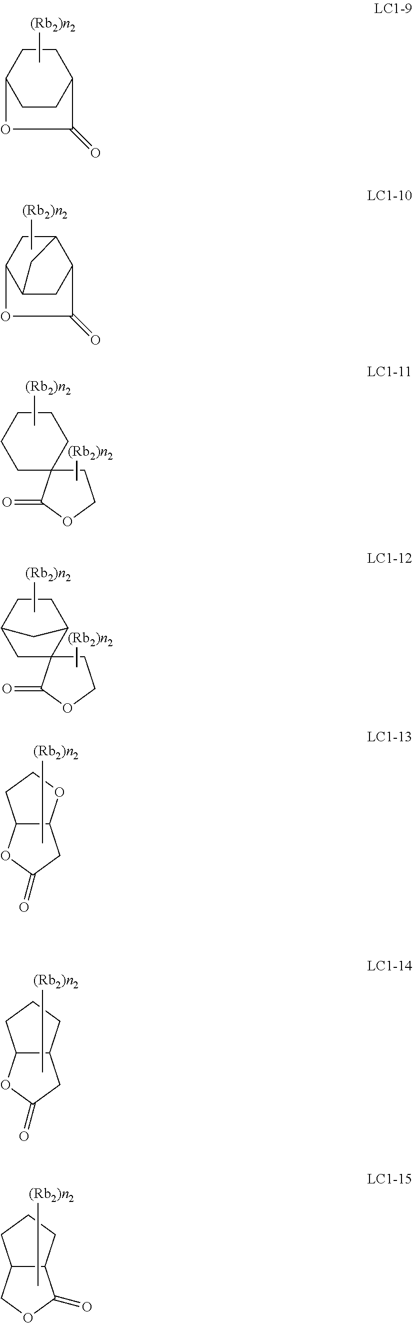

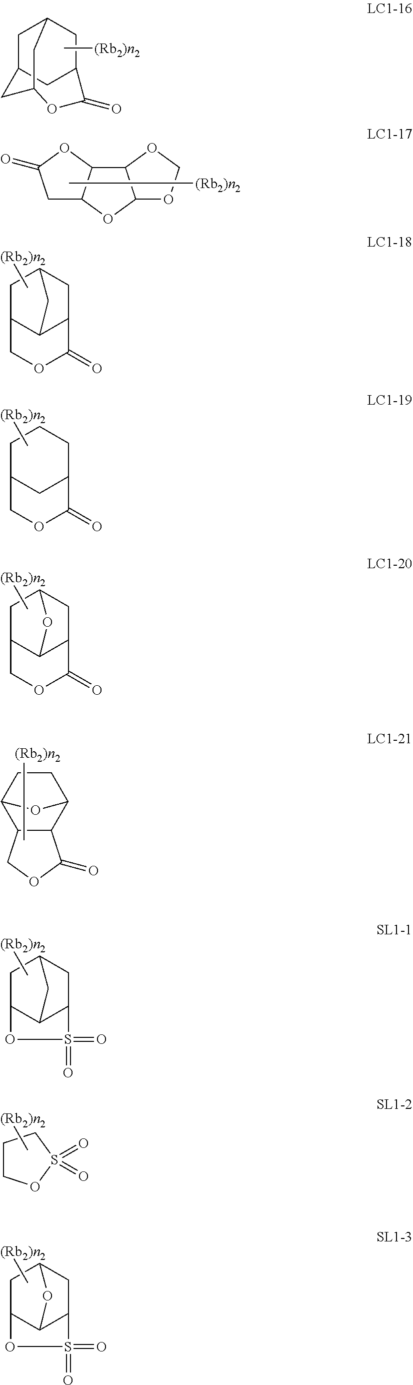

The moiety of the lactone structure or the sultone structure may have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a cyano group, and an acid-decomposable group. n2 represents an integer of 0 to 4. In a case where n2 is 2 or more, Rb₂'s which are present in plurality may be different from each other, and Rb₂'s which are present in plurality may be bonded to each other to form a ring.

Examples of the repeating unit having a group including the lactone structure represented by any one of Formula (LC1-1), . . . , or (LC1-21) or the sultone structure represented by any one of Formula (SL1-1), (SL1-2), or (SL1-3) include a repeating unit represented by Formula (AI).

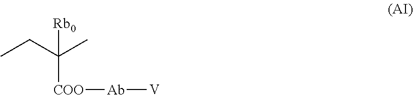

In Formula (AI), Rb₀ represents a hydrogen atom, a halogen atom, or an alkyl group having 1 to 4 carbon atoms.

Preferred examples of the substituent which may be contained in the alkyl group of Rb₀ include a hydroxyl group and a halogen atom.

Examples of the halogen atom of Rb₀ include a fluorine atom, a chlorine atom, a bromine atom, and an iodine atom. Rb₀ is preferably the hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group formed by combination of these groups. Among those, the single bond or a linking group represented by -Ab₁-CO₂— is preferable. Ab₁ is a linear or branched alkylene group, or a monocyclic or polycyclic cycloalkylene group, and is preferably a methylene group, an ethylene group, a cyclohexylene group, an adamantylene group, or a norbornylene group.

V represents a group formed by extracting one hydrogen atom from a ring member atom of the lactone structure represented by any one of Formula (LC1-1), . . . , or (LC1-21) or a group formed by extracting one hydrogen atom from a ring member atom of the sultone structure represented by any one of Formula (SL1-1), (SL1-2), or (SL1-3).

In a case where an optical isomer is present in the repeating unit having a lactone group or a sultone group, any of the optical isomers may be used. In addition, one kind of optical isomers may be used alone or a plurality of kinds of optical isomers may be mixed and used. In a case where one kind of optical isomers is mainly used, an optical purity (ee) thereof is preferably 90 or more, and more preferably 95 or more.

As the carbonate group, a cyclic carbonic acid ester group is preferable. As the repeating unit having a cyclic carbonic acid ester group, a repeating unit represented by Formula (A-1) is preferable.

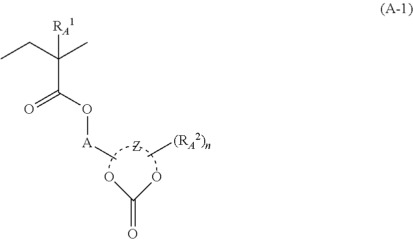

In Formula (A-1), R_{A}¹ represents a hydrogen atom, a halogen atom, or a monovalent organic group (preferably a methyl group).

n represents an integer of 0 or more.

R_{A}² represents a substituent. In a case where n is 2 or more, R_{A}² which are present in plurality may be the same as or different from each other.

A represents a single bond or a divalent linking group. As the divalent linking group, an alkylene group, a divalent linking group having a monocyclic or polycyclic alicyclic hydrocarbon structure, an ether group, an ester group, a carbonyl group, a carboxyl group, or a divalent group formed by combination of these groups is preferable.

Z represents an atomic group that forms a monocycle or polycycle with a group represented by —O—CO—O— in the formula.

The repeating unit having a lactone group, a sultone group, or a carbonate group will be exemplified below.

(in the formulae, Rx represents H, CH₃, CH₂OH, or CF₃)

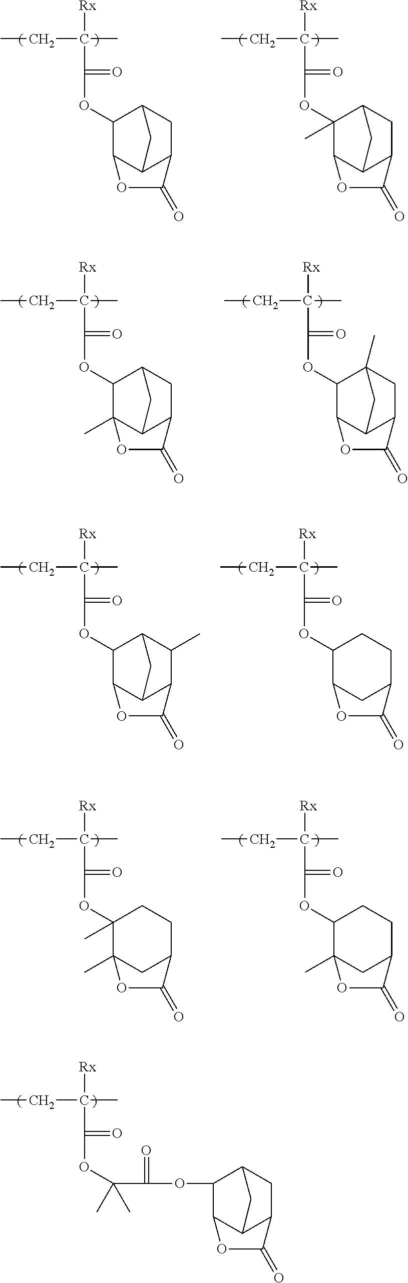

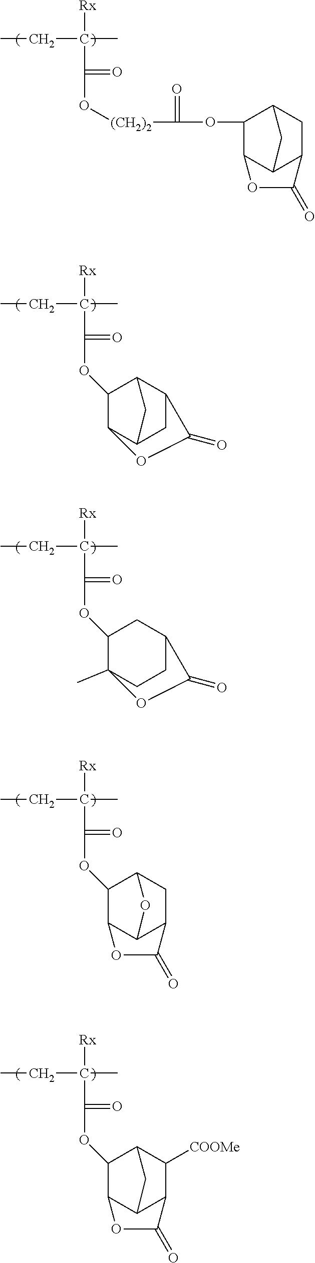

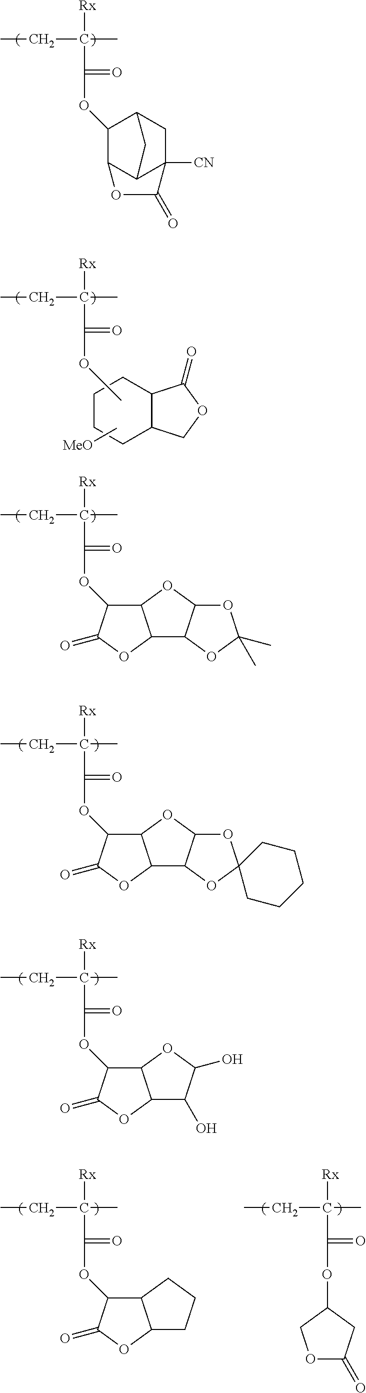

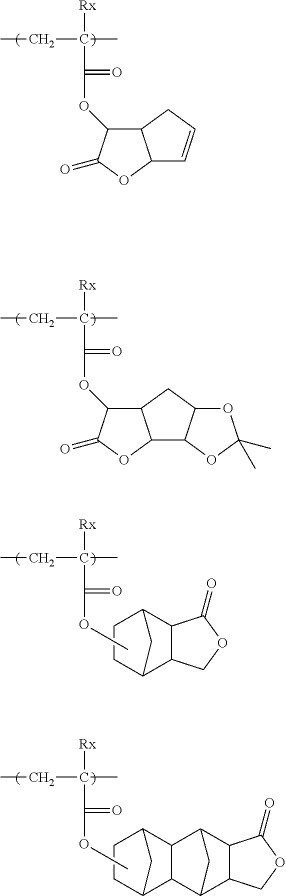

(in the formulae, Rx represents H, CH₃, CH₂OH, or CF₃)

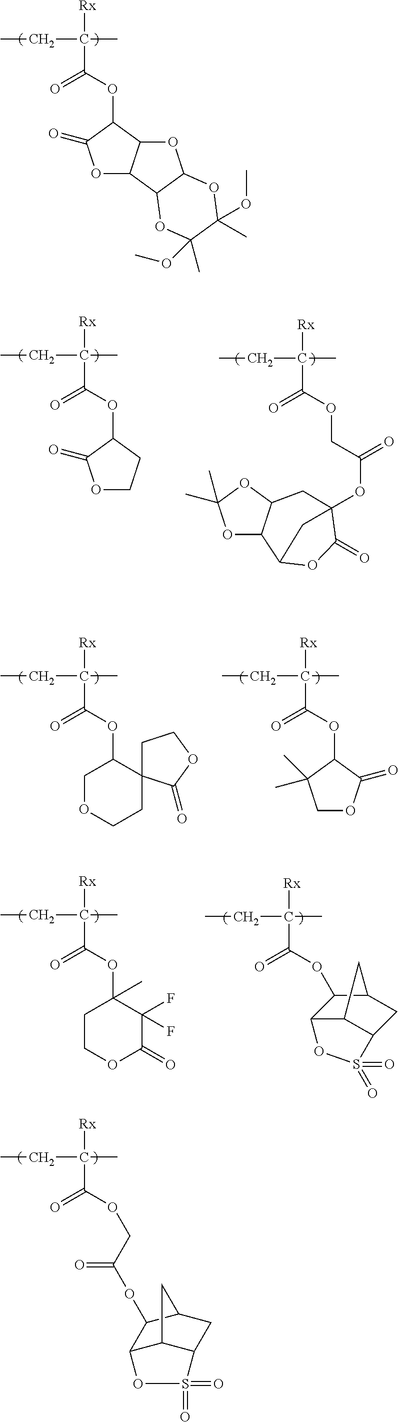

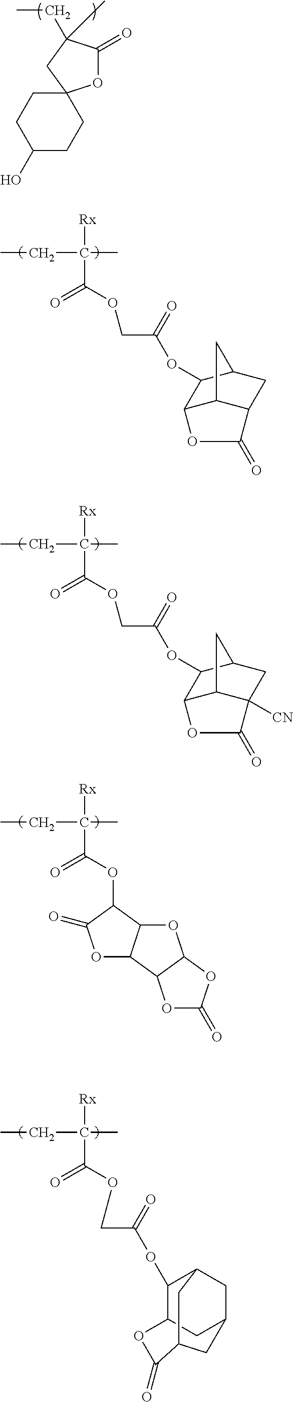

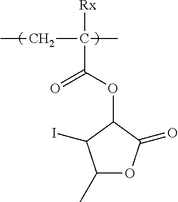

(in the formulae, Rx represents H, CH₃, CH₂OH, or CF₃)

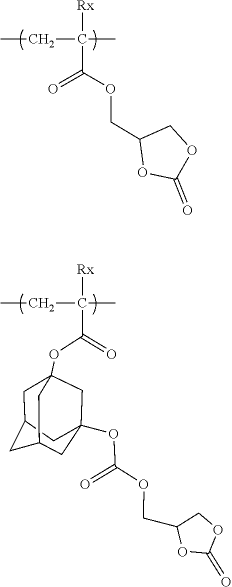

The content of the repeating unit having a lactone group, a sultone group, or a carbonate group is preferably 1% by mole or more, and more preferably 10% by mole or more with respect to all the repeating units in the resin (A). In addition, the upper limit value is preferably 85% by mole or less, more preferably 80% by mole or less, still more preferably 70% by mole or less, and particularly preferably 60% by mole or less with respect to all the repeating units in the resin (A).

<Repeating Unit Having Photoacid Generating Group>

The resin (A) may have, as a repeating unit other than those above, a repeating unit having a group that generates an acid upon irradiation with actinic rays or radiation (hereinafter also referred to as a “photoacid generating group”).

In this case, it can be considered that the repeating unit having the photoacid generating group corresponds to the above-mentioned photoacid generator (B).

Examples of such the repeating unit include a repeating unit represented by Formula (4).

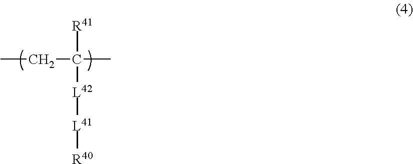

R⁴¹ represents a hydrogen atom or a methyl group. L⁴¹ represents a single bond or a divalent linking group. L⁴² represents a divalent linking group. R⁴⁰ represents a structural site that decomposes upon irradiation with actinic rays or radiation to generate an acid in a side chain.

The repeating unit having a photoacid generating group is exemplified below.

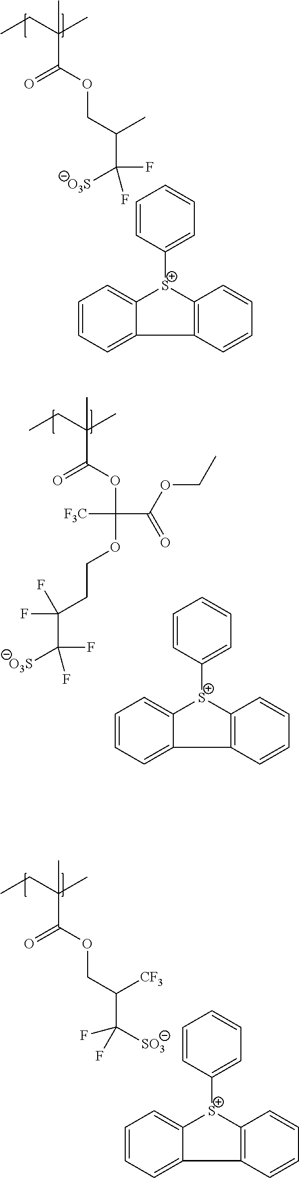

In addition, examples of the repeating unit represented by Formula (4) include the repeating units described in paragraphs [0094] to [0105] of JP2014-041327A and the repeating units described in paragraph [0094] of WO2018/193954A.

The content of the repeating unit having a photoacid generating group is preferably 1% by mole or more, and more preferably 5% by mole or more with respect to all the repeating units in the resin (A). In addition, the upper limit value is preferably 40% by mole or less, more preferably 35% by mole or less, and still more preferably 30% by mole or less with respect to all the repeating units in the resin (A).

<Repeating Unit Represented by Formula (V-1) or Formula (V-2)>

The resin (A) may have a repeating unit represented by Formula (V-1) or Formula (V-2).

The repeating unit represented by Formulae (V-1) and (V-2) is preferably a repeating unit different from the above-mentioned repeating units.

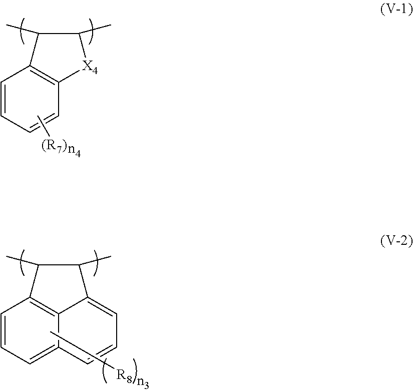

In the formulae,

R₆ and R₇ each independently represent a hydrogen atom, a hydroxyl group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group. As the alkyl group, a linear, branched, or cyclic alkyl group having 1 to 10 carbon atoms is preferable.

n3 represents an integer of 0 to 6.

n4 represents an integer of 0 to 4.

X₄ is a methylene group, an oxygen atom, or a sulfur atom.

The repeating unit represented by Formula (V-1) or (V-2) will be exemplified below.

Examples of the repeating unit represented by Formula (V-1) or (V-2) include the repeating unit described in paragraph [0100] of WO2018/193954A.

<Repeating Unit for Reducing Motility of Main Chain>

The resin (A) preferably has a high glass transition temperature (Tg) from the viewpoint that excessive diffusion of an acid generated or pattern collapse during development can be suppressed. Tg is preferably higher than 90° C., more preferably higher than 100° C., still more preferably higher than 110° C., and particularly preferably higher than 125° C. Furthermore, since an excessive increase in Tg causes a decrease in the dissolution rate in a developer, Tg is preferably 400° C. or lower, and more preferably 350° C. or lower.

Furthermore, in the present specification, the glass transition temperature (Tg) of a polymer such as the resin (A) (hereinafter referred to as “the Tg of the repeating unit”) is calculated by the following method. First, the Tg of a homopolymer consisting only of each repeating unit included in the polymer is calculated by a Bicerano method. Next, the mass proportion (%) of each repeating unit to all the repeating units in the polymer is calculated. Then, the Tg at each mass proportion is calculated using a Fox's equation (described in Materials Letters 62 (2008) 3152, and the like), and these are summed to obtain the Tg (° C.) of the polymer.

The Bicerano method is described in Prediction of polymer properties, Marcel Dekker Inc., New York (1993), and the like. In addition, the calculation of a Tg by the Bicerano method can be carried out using MDL Polymer (MDL Information Systems, Inc.), which is software for estimating physical properties of a polymer.

In order to raise the Tg of the resin (A) (preferably to raise the Tg to higher than 90° C.), it is preferable to reduce the motility of the main chain of the resin (A). Examples of a method for reducing the motility of the main chain of the resin (A) include the following (a) to (e) methods.

(a) Introduction of a bulky substituent into the main chain

(b) Introduction of a plurality of substituents into the main chain

(c) Introduction of a substituent that induces an interaction between the resins (A) near the main chain

(d) Formation of the main chain in a cyclic structure

(e) Linking of a cyclic structure to the main chain

Furthermore, the resin (A) preferably has a repeating unit having a Tg of a homopolymer exhibiting 130° C. or higher.

In addition, the type of the repeating unit having a Tg of the homopolymer exhibiting 130° C. or higher is not particularly limited, and may be any of repeating units having a Tg of a homopolymer of 130° C. or higher calculated by the Bicerano method. Moreover, it corresponds to a repeating unit having a Tg of a homopolymer exhibiting 130° C. or higher, depending on the type of a functional group in the repeating units represented by Formula (A) to Formula (E) which will be described later.

(Repeating Unit Represented by Formula (A))

As an example of a specific unit for accomplishing (a) above, a method of introducing a repeating unit represented by Formula (A) into the resin (A) may be mentioned.

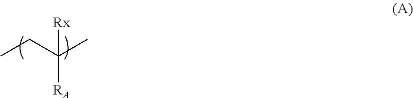

In Formula (A), R_{A} represents a group including a polycyclic structure. Rx represents a hydrogen atom, a methyl group, or an ethyl group. The group including a polycyclic structure is a group including a plurality of ring structures, and the plurality of ring structures may or may not be fused.

Specific examples of the repeating unit represented by Formula (A) include those described in paragraphs [0107] to [0119] of WO2018/193954A.

(Repeating Unit Represented by Formula (B))

As an example of a specific unit for accomplishing (b) above, a method of introducing a repeating unit represented by Formula (B) into the resin (A) may be mentioned.

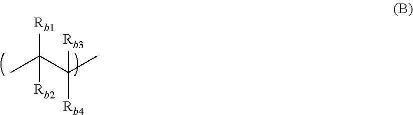

In Formula (B), R_{b1} to R_{b4} each independently represent a hydrogen atom or an organic group, and at least two or more of R_{b1}, . . . , or R_{b4} represent an organic group.

Furthermore, in a case where at least one of the organic groups is a group in which a ring structure is directly linked to the main chain in the repeating unit, the types of the other organic groups are not particularly limited.

In addition, in a case where none of the organic groups is a group in which a ring structure is directly linked to the main chain in the repeating unit, at least two or more of the organic groups are substituents having three or more constituent atoms excluding hydrogen atoms.

Specific examples of the repeating unit represented by Formula (B) include those described in paragraphs [0113] to [0115] of WO2018/193954A.

(Repeating Unit Represented by Formula (C))

As an example of a specific unit for accomplishing (c) above, a method of introducing a repeating unit represented by Formula (C) into the resin (A) may be mentioned.

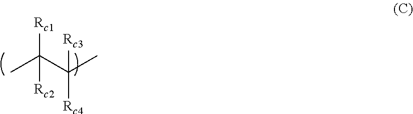

In Formula (C), R_{c1} to R_{c4} each independently represent a hydrogen atom or an organic group, and at least one of R_{c1}, . . . , or R_{c4} is a group including a hydrogen-bonding hydrogen atom with a number of atoms of 3 or less from the main chain carbon. Above all, it is preferable that the group has hydrogen-bonding hydrogen atoms with a number of atoms of 2 or less (on a side closer to the vicinity of the main chain) to induce an interaction between the main chains of the resin (A).

Specific examples of the repeating unit represented by Formula (C) include those described in paragraphs [0119] to [0121] of WO2018/193954A.

(Repeating Unit Represented by Formula (D))

As an example of a specific unit for accomplishing (d) above, a method of introducing a repeating unit represented by Formula (D) into the resin (A) may be mentioned.

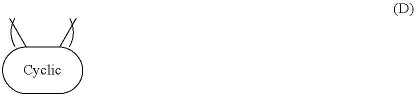

In Formula (D), “Cyclic” is a group that forms a main chain with a cyclic structure. The number of the ring-constituting atoms is not particularly limited.

Specific examples of the repeating unit represented by Formula (D) include those described in paragraphs [0126] and [0127] of WO2018/193954A.

(Repeating Unit Represented by Formula (E))

As an example of a specific unit for accomplishing (e) above, a method of introducing a repeating unit represented by Formula (E) into the resin (A) may be mentioned.

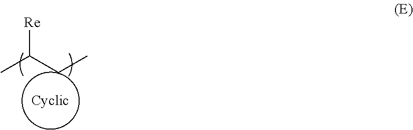

In Formula (E), Re's each independently represent a hydrogen atom or an organic group. Examples of the organic group include an alkyl group, a cycloalkyl group, an aryl group, an aralkyl group, and an alkenyl group, which may have a substituent.

“Cyclic” is a cyclic group including a carbon atom of the main chain. The number of atoms included in the cyclic group is not particularly limited.

Specific examples of the repeating unit represented by Formula (E) include those described in paragraphs [0131] to [0133] of WO2018/193954A.

<Repeating Unit Having at Least One Group selected from Lactone Group, Sultone Group, Carbonate Group, Hydroxyl Group, Cyano Group, or Alkali-Soluble Group>

The resin (A) may have a repeating unit having at least one group selected from a lactone group, a sultone group, a carbonate group, a hydroxyl group, a cyano group, or an alkali-soluble group.

Examples of the repeating unit having a lactone group, a sultone group, or a carbonate group contained in the resin (A) include the repeating units described in <Repeating Unit Having Lactone Group, Sultone Group, or Carbonate Group> mentioned above. A preferred content thereof is also the same as described in <Repeating Unit Having Lactone Group, Sultone Group, or Carbonate Group> mentioned above.

The resin (A) may have a repeating unit having a hydroxyl group or a cyano group. As a result of this, the adhesiveness to a substrate and the affinity for a developer are improved.

The repeating unit having a hydroxyl group or a cyano group is preferably a repeating unit having an alicyclic hydrocarbon structure substituted with a hydroxyl group or a cyano group.

The repeating unit having a hydroxyl group or a cyano group preferably has no acid-decomposable group. Examples of the repeating unit having a hydroxyl group or a cyano group include those described in paragraphs [0081] to [0084] of JP2014-98921A.

The resin (A) may have a repeating unit having an alkali-soluble group.

Examples of the alkali-soluble group include a carboxyl group, a sulfonamide group, a sulfonylimide group, a bissulfonylimide group, or an aliphatic alcohol group (for example, a hexafluoroisopropanol group) in which the α-position is substituted with an electron withdrawing group, and the carboxyl group is preferable. In a case where the resin (A) includes a repeating unit having an alkali-soluble group, the resolution for use in contact holes increases. Examples of the repeating unit having an alkali-soluble group include those described in paragraphs [0085] and [0086] of JP2014-98921A.

<Repeating Unit Having Alicyclic Hydrocarbon Structure and Not Exhibiting Acid Decomposability>

The resin (A) may have a repeating unit having an alicyclic hydrocarbon structure and not exhibiting acid decomposability. This can reduce the elution of low-molecular-weight components from the resist film into an immersion liquid during liquid immersion exposure. Examples of such the repeating unit include repeating units derived from 1-adamantyl (meth)acrylate, diamantyl (meth)acrylate, tricyclodecanyl (meth)acrylate, and cyclohexyl (meth)acrylate.

<Repeating Unit Represented by Formula (III) Having Neither Hydroxyl Group Nor Cyano Group>

The resin (A) may have a repeating unit represented by Formula (III), which has neither a hydroxyl group nor a cyano group.

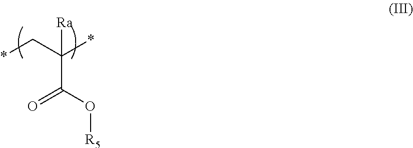

In Formula (III), R₅ represents a hydrocarbon group having at least one cyclic structure and having neither a hydroxyl group nor a cyano group.

Ra represents a hydrogen atom, an alkyl group, or a —CH₂—O—Ra₂ group. In the formula, Ra₂ represents a hydrogen atom, an alkyl group, or an acyl group.

Examples of the repeating unit represented by Formula (III) having neither a hydroxyl group nor a cyano group include those described in paragraphs [0087] to [0094] of JP2014-98921A.

<Other Repeating Units>

Furthermore, the resin (A) may have repeating units other than the repeating units described above.

For example, the resin (A) may have a repeating unit selected from the group consisting of a repeating unit having an oxathiane ring group, a repeating unit having an oxazolone ring group, a repeating unit having a dioxane ring group, and a repeating unit having a hydantoin ring group.

Such repeating units will be exemplified below.

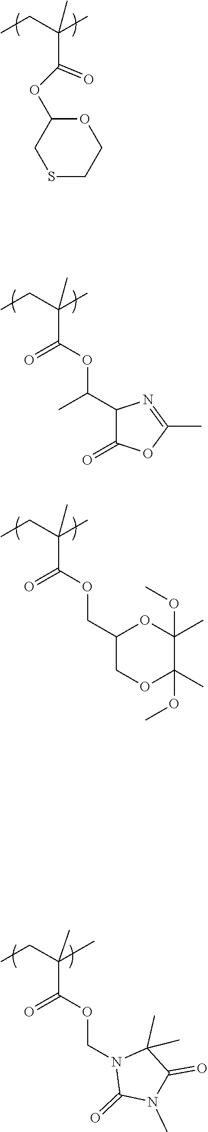

The resin (A) may have a variety of repeating structural units, in addition to the repeating structural units described above, for the purpose of adjusting dry etching resistance, suitability for a standard developer, adhesiveness to a substrate, a resist profile, a resolution, heat resistance, sensitivity, and the like.

For the resin (A), it is preferable that (particularly in a case where the composition is used as an actinic ray-sensitive or radiation-sensitive resin composition for ArF), all of the repeating units are composed of repeating units derived from a compound having an ethylenically unsaturated bond. In particular, it is also preferable that all of the repeating units are composed of the (meth)acrylate-based repeating units. In this case, any of a resin in which all of the repeating units are methacrylate-based repeating units, a resin in which all of the repeating units are acrylate-based repeating units, and a resin in which all of the repeating units are methacrylate-based repeating units and acrylate-based repeating units can be used, and it is preferable that the amount of the acrylate-based repeating units is 50% by mole or less with respect to all the repeating units.

The resin (A) can be synthesized in accordance with an ordinary method (for example, radical polymerization).

The weight-average molecular weight of the resin (A) as a value expressed in terms of polystyrene by a GPC method is preferably 30,000 or less, preferably 1,000 to 30,000, more preferably 3,000 to 30,000, and still more preferably 5,000 to 15,000.

The dispersity (molecular weight distribution) of the resin (A) is usually 1 to 5, preferably 1 to 3, more preferably 1.2 or 3.0, and still more preferably 1.2 to 2.0. The smaller the dispersity, the more excellent the resolution and the resist shape, and the smoother the side wall of the resist pattern, the more excellent the roughness.

The content of the resin (A) in the resist composition is preferably 40.0% to 99.9% by mass, and more preferably 60.0% to 90.0% by mass with respect to the total solid content of the composition.

The resin (A) may be used alone or in combination of a plurality thereof.

[Solvent (F)]

The resist composition preferably includes a solvent.

The solvent preferably includes at least one solvent of (M1) propylene glycol monoalkyl ether carboxylate, or (M2) at least one selected from the group consisting of a propylene glycol monoalkyl ether, a lactic acid ester, an acetic acid ester, an alkoxypropionic acid ester, a chain ketone, a cyclic ketone, a lactone, and an alkylene carbonate as a solvent. Furthermore, this solvent may further include components other than the components (M1) and (M2).

The present inventors have found that by using such a solvent and the above-mentioned resin in combination, a pattern having a small number of development defects can be formed while improving the coating property of the resist composition. A reason thereof is not necessarily clear, but the present inventors have considered that since these solvents have a good balance among the solubility, the boiling point, and the viscosity of the resin, the unevenness of the film thickness of a composition film, the generation of precipitates during spin coating, and the like can be suppressed.

Details of the component (M1) and the component (M2) are described in paragraphs [0218] to [0226] of WO2020/004306A, the contents of which are incorporated herein by reference.

In a case where the solvent further includes a component other than the components (M1) and (M2), the content of the component other than the components (M1) and (M2) is preferably 5% to 30% by mass with respect to the total amount of the solvent.

The content of the solvent in the resist composition is preferably set such that the concentration of solid contents is 0.5% to 30% by mass, and more preferably set such that the concentration of solid contents of the resist composition is 1% to 20% by mass. With this content, the coating property of the resist composition can be further improved.

Furthermore, the solid content means all the components excluding the solvent.

[Acid Diffusion Control Agent (C)]

The resist composition may include an acid diffusion control agent.

The acid diffusion control agent acts as a quencher that suppresses a reaction of an acid-decomposable resin in the unexposed portion by excessive generated acids by trapping the acids generated from a photoacid generator and the like upon exposure. For example, a basic compound (CA), a basic compound (CB) of which basicity is reduced or lost upon irradiation with actinic rays or radiation, a low-molecular-weight compound (CD) having a nitrogen atom and a group that leaves by the action of an acid, and an onium salt compound (CE) having a nitrogen atom in the cationic moiety, can be used as the acid diffusion control agent. In the resist composition of the embodiment of the present invention, a known acid diffusion control agent can be appropriately used. For example, the known compounds disclosed in paragraphs [0627] to [0664] of the specification of US2016/0070167A1, paragraphs [0095] to [0187] of the specification of US2015/0004544A1, paragraphs [0403] to [0423] of the specification of US2016/0237190A1, and paragraphs [0259] to [0328] of the specification of US2016/0274458A1 can be suitably used as the acid diffusion control agent.

In addition, for example, specific examples of the basic compound (CA) include those described in paragraphs [0132] to [0136] of WO2020/066824A, specific examples of the basic compound (CB) of which basicity is reduced or lost upon irradiation with actinic rays or radiation include those described in paragraphs [0137] to [0155] of WO2020/066824A, specific examples of the low-molecular-weight compound (CD) having a nitrogen atom and a group that leaves by the action of an acid include those described in paragraphs [0156] to [0163] of WO2020/066824A, and specific examples of the onium salt compound (CE) having a nitrogen atom in the cationic moiety include those described in paragraph [0164] of WO2020/066824A.

In a case where the resist composition includes an acid diffusion control agent, the content of the acid diffusion control agent (in a case where a plurality of kinds of the acid diffusion control agents are present, a total content thereof) is preferably 0.1% to 15.0% by mass, and more preferably 1.0% to 15.0% by mass with respect to the total solid content of the resist composition.

In the resist composition, the acid diffusion control agents may be used alone or in combination of two or more kinds thereof.

[Hydrophobic Resin (D)]

The resist composition may further include a hydrophobic resin which is different from the resin (A).

Although it is preferable that the hydrophobic resin is designed to be unevenly distributed on a surface of the resist film, it does not necessarily need to have a hydrophilic group in the molecule as different from the surfactant, and does not need to contribute to uniform mixing of polar materials and non-polar materials.

Examples of the effect caused by the addition of the hydrophobic resin include a control of static and dynamic contact angles of a surface of the resist film with respect to water and suppression of out gas.

The hydrophobic resin preferably has any one or more of a fluorine atom, a silicon atom, and a CH₃ partial structure which is contained in a side chain moiety of a resin from the viewpoint of uneven distribution on the film surface layer, and more preferably has two or more kinds thereof. In addition, the hydrophobic resin preferably has a hydrocarbon group having 5 or more carbon atoms. These groups may be contained in the main chain of the resin or may be substituted in a side chain.

Examples of the hydrophobic resin include the compounds described in paragraphs [0275] to [0279] of WO2020/004306A.

In a case where the resist composition includes a hydrophobic resin, a content of the hydrophobic resin is preferably 0.01% to 20.0% by mass, and more preferably 0.1% to 15.0% by mass with respect to the total solid content of the resist composition.

[Surfactant (E)]

The resist composition may include a surfactant. In a case where the surfactant is included, it is possible to form a pattern having more excellent adhesiveness and fewer development defects.

The surfactant is preferably a fluorine-based and/or silicon-based surfactant.

Examples of the fluorine-based and/or silicon-based surfactant include the surfactants disclosed in paragraphs [0218] and [0219] of WO2018/19395A.

The surfactants may be used alone or in combination of two or more kinds thereof.

In a case where the resist composition includes a surfactant, a content of the surfactant is preferably 0.0001% to 2.0% by mass, more preferably 0.0005% to 1.0% by mass, and still more preferably 0.1% to 1.0% by mass with respect to the total solid content of the resist composition.

[Other Additives]

The resist composition may further include a dissolution inhibiting compound, a dye, a plasticizer, a photosensitizer, a light absorber, and/or a compound accelerating a solubility in a developer (for example, a phenol compound having a molecular weight of 1,000 or less or an alicyclic or aliphatic compound including a carboxyl group), or the like.

The resist composition may further include a dissolution inhibiting compound. Here, the “dissolution inhibiting compound” is intended to be a compound having a molecular weight of 3,000 or less, having a solubility in an organic developer decreases by decomposition by the action of an acid.

The resist composition of the embodiment of the present invention is suitably used as a photosensitive composition for EUV light.

EUV light has a wavelength of 13.5 nm, which is a shorter wavelength than that of ArF (wavelength of 193 nm) light or the like, and therefore, the EUV light has a smaller number of incidence photons upon exposure with the same sensitivity. As a result, an effect that the number of photons is statistically non-uniform (photon shot noise) is significant, and a deterioration in LER and a bridge defect are caused. In order to reduce the photon shot noise, a method in which an exposure amount increases to cause an increase in the number of incidence photons is available, but the method is a trade-off with a demand for a higher sensitivity.

In a case where the A value obtained by Formula (1) is high, the absorption efficiency of EUV light and electron beam of the resist film formed from the resist composition is higher, which is effective in reducing the photon shot noise. The A value represents the absorption efficiency of EUV light and electron beams of the resist film in terms of a mass proportion.

A=([H]×0.04+[C]×1.0+[N]×2.1+[O]×3.6+[F]×5.6+[S]×1.5+[I]×39.5)/([H]×1+[C]×12+[N]×14+[O]×16+[F]×19+[S]×32+[I]×127) Formula (1):

The A value is preferably 0.120 or more. The upper limit is not particularly limited, but in a case where the A value is extremely high, the transmittance of EUV light and electron beams of the resist film is lowered and the optical image profile in the resist film is deteriorated, which results in difficulty in obtaining a good pattern shape, and therefore, the upper limit is preferably 0.240 or less, and more preferably 0.220 or less.

Moreover, in Formula (1), [H] represents a molar ratio of hydrogen atoms derived from the total solid content with respect to all the atoms of the total solid content in the actinic ray-sensitive or radiation-sensitive resin composition, [C] represents a molar ratio of carbon atoms derived from the total solid content with respect to all the atoms of the total solid content in the actinic ray-sensitive or radiation-sensitive resin composition, [N] represents a molar ratio of nitrogen atoms derived from the total solid content with respect to all the atoms of the total solid content in the actinic ray-sensitive or radiation-sensitive resin composition, [O] represents a molar ratio of oxygen atoms derived from the total solid content with respect to all the atoms of the total solid content in the actinic ray-sensitive or radiation-sensitive resin composition, [F] represents a molar ratio of fluorine atoms derived from the total solid content with respect to all the atoms of the total solid content in the actinic ray-sensitive or radiation-sensitive resin composition, [S] represents a molar ratio of sulfur atoms derived from the total solid content with respect to all the atoms of the total solid content in the actinic ray-sensitive or radiation-sensitive resin composition, and [I] represents a molar ratio of iodine atoms derived from the total solid content with respect to all the atoms of the total solid content in the actinic ray-sensitive or radiation-sensitive resin composition.

For example, in a case where the resist composition includes a resin (acid-decomposable resin) of which polarity increases by the action of an acid, a photoacid generator, an acid diffusion control agent, and a solvent, the resin, the photoacid generator, and the acid diffusion control agent correspond to the solid content. That is, all the atoms of the total solid content correspond to a sum of all the atoms derived from the resin, all the atoms derived from the photoacid generator, and all the atoms derived from the acid diffusion control agent. For example, [H] represents a molar ratio of hydrogen atoms derived from the total solid content with respect to all the atoms in the total solid content, and by way of description based on the example above, [H] represents a molar ratio of a sum of the hydrogen atoms derived from the resin, the hydrogen atoms derived from the photoacid generator, and the hydrogen atoms derived from the acid diffusion control agent with respect to a sum of all the atoms derived from the resin, all the atoms derived from the photoacid generator, and all the atoms derived from the acid diffusion control agent.

The A value can be calculated by computation of the structure of constituent components of the total solid content in the resist composition, and the atomic number ratio contained in a case where the content is already known. In addition, even in a case where the constituent component is not known yet, it is possible to calculate a constituent atomic number ratio by subjecting a resist film obtained after evaporating the solvent components of the resist composition to computation according to an analytic approach such as elemental analysis.

[Resist Film and Pattern Forming Method]

The procedure of the pattern forming method using the resist composition is not particularly limited, but preferably has the following steps.

Step 1: A step of forming a resist film on a substrate, using a resist composition

Step 2: A step of exposing the resist film

Step 3: A step of developing the exposed resist film using a developer

Hereinafter, the procedure of each of the steps will be described in detail.

<Step 1: Resist Film Forming Step>

The step 1 is a step of forming a resist film on a substrate, using a resist composition.

The definition of the resist composition is as described above.

Examples of a method in which a resist film is formed on a substrate, using a resist composition include a method in which a resist composition is applied onto a substrate.

Incidentally, it is preferable that the resist composition before the application is filtered through a filter, as necessary. A pore size of the filter is preferably 0.1 m or less, more preferably 0.05 m or less, and still more preferably 0.03 m or less. In addition, the filter is preferably a polytetrafluoroethylene-, polyethylene-, or nylon-made filter.

The resist composition can be applied onto a substrate (for example, silicon and silicon dioxide coating) as used in the manufacture of integrated circuit elements by a suitable application method such as ones using a spinner or a coater. The application method is preferably spin application using a spinner. A rotation speed upon the spin application using a spinner is preferably 1,000 to 3,000 rpm.

After the application of the resist composition, the substrate may be dried to form a resist film. In addition, various underlying films (an inorganic film, an organic film, or an antireflection film) may be formed on the underlayer of the resist film, as necessary.

Examples of the drying method include a method of heating and drying. The heating can be carried out using a unit included in an ordinary exposure machine and/or an ordinary development machine, and may also be carried out using a hot plate or the like. A heating temperature is preferably 80° C. to 150° C., more preferably 80° C. to 140° C., and still more preferably 80° C. to 130° C. A heating time is preferably 30 to 1,000 seconds, more preferably 60 to 800 seconds, and still more preferably 60 to 600 seconds.

A film thickness of the resist film is not particularly limited, but is preferably 10 to 120 nm from the viewpoint that a fine pattern having higher accuracy can be formed. Among those, in a case of performing EUV exposure, the film thickness of the resist film is more preferably 10 to 65 nm, and still more preferably 15 to 50 nm. In addition, in a case of performing ArF liquid immersion exposure, the film thickness of the resist film is more preferably 10 to 120 nm, and still more preferably 15 to 90 nm.

Moreover, a topcoat may be formed on the upper layer of the resist film, using the topcoat composition.

It is preferable that the topcoat composition is not mixed with the resist film and can be uniformly applied onto the upper layer of the resist film. The topcoat is not particularly limited, a topcoat known in the related art can be formed by the methods known in the related art, and the topcoat can be formed, based on the description in paragraphs [0072] to [0082] of JP2014-059543A, for example.

It is preferable that a topcoat including a basic compound as described in JP2013-61648A, for example, is formed on a resist film. Specific examples of the basic compound which can be included in the topcoat include a basic compound which may be included in the resist composition.

In addition, it is also preferable that the topcoat includes a compound which includes at least one group or bond selected from the group consisting of an ether bond, a thioether bond, a hydroxyl group, a thiol group, a carbonyl bond, and an ester bond.

<Step 2: Exposing Step>

The step 2 is a step of exposing the resist film.

Examples of the exposing method include a method of irradiating the resist film formed with actinic rays or radiation through a predetermined mask.

Examples of the actinic rays or radiation include infrared light, visible light, ultraviolet light, far ultraviolet light, extreme ultraviolet light, X-rays, and electron beams, a light at a wavelength of 250 nm or less is preferable, a light at a wavelength of 220 nm or less is more preferable, and examples thereof include a far ultraviolet light at a wavelength of 1 to 200 nm, specifically, KrF excimer laser (a light at a wavelength of 248 nm), ArF excimer laser (a light at a wavelength of 193 nm), F₂ excimer laser (a light at a wavelength of 157 nm), EUV (a light at a wavelength of 13 nm), X-rays, and electron beams.

It is preferable to perform baking (heating) before performing development after the exposure. The baking accelerates a reaction in the exposed portion, and the sensitivity and the pattern shape are improved.

A heating temperature is preferably 80° C. to 150° C., more preferably 80° C. to 140° C., and still more preferably 80° C. to 130° C.

A heating time is preferably 10 to 1,000 seconds, more preferably 10 to 180 seconds, and still more preferably 30 to 120 seconds.

The heating can be carried out using a unit included in an ordinary exposure machine and/or an ordinary development machine, and may also be performed using a hot plate or the like.

This step is also referred to as a post-exposure baking.

<Step 3: Developing Step>

The step 3 is a step of developing the exposed resist film using a developer to form a pattern.

The developer may be either an alkali developer or a developer including an organic solvent (hereinafter also referred to as an “organic developer”).

Examples of the developing method include a method in which a substrate is immersed in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), and a method in which a developer is continuously jetted onto a substrate rotating at a constant rate while scanning a developer jetting nozzle at a constant rate (a dynamic dispense method).

In addition, after the step of performing development, a step of stopping the development may be carried out while substituting the solvent with another solvent.

A developing time is not particularly limited as long as it is a period of time where the unexposed portion of a resin is sufficiently dissolved, and is preferably 10 to 300 seconds, and more preferably 20 to 120 seconds.

The temperature of the developer is preferably 0° C. to 50° C., and more preferably 15° C. to 35° C.

As the alkali developer, it is preferable to use an aqueous alkali solution including an alkali. The type of the aqueous alkali solution is not particularly limited, but examples thereof include an aqueous alkali solution including a quaternary ammonium salt typified by tetramethylammonium hydroxide, an inorganic alkali, a primary amine, a secondary amine, a tertiary amine, an alcoholamine, a cyclic amine, or the like. Among those, the aqueous solutions of the quaternary ammonium salts typified by tetramethylammonium hydroxide (TMAH) are preferable as the alkali developer. An appropriate amount of an alcohol, a surfactant, or the like may be added to the alkali developer. The alkali concentration of the alkali developer is usually 0.1% to 20% by mass. Furthermore, the pH of the alkali developer is usually 10.0 to 15.0.

The organic developer is preferably a developer containing at least one organic solvent selected from the group consisting of a ketone-based solvent, an ester-based solvent, an alcohol-based solvent, an amide-based solvent, an ether-based solvent, and a hydrocarbon-based solvent.

A plurality of the solvents may be mixed or the solvent may be used in admixture with a solvent other than those described above or water. The moisture content in the entire developer (the content of water with respect to the total mass of the developer) is preferably less than 50% by mass, more preferably less than 20% by mass, and still more preferably less than 10% by mass, and particularly preferably moisture is not substantially contained.

The content of the organic solvent with respect to the organic developer is preferably from 50% by mass to 100% by mass, more preferably from 80% by mass to 100% by mass, still more preferably from 90% by mass to 100% by mass, and particularly preferably from 95% by mass to 100% by mass with respect to the total mass amount of the developer.

<Other Steps>

It is preferable that the pattern forming method includes a step of performing cleaning using a rinsing liquid after the step 3.

Examples of the rinsing liquid used in the rinsing step after the step of performing development using an alkali developer include pure water. Furthermore, an appropriate amount of a surfactant may be added to pure water.

An appropriate amount of a surfactant may be added to the rinsing liquid.

The rinsing liquid used in the rinsing step after the developing step with an organic developer is not particularly limited as long as the rinsing liquid does not dissolve the pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

A method for the rinsing step is not particularly limited, but examples thereof include a method in which a rinsing liquid is continuously jetted on a substrate rotated at a constant rate (a rotation application method), a method in which a substrate is dipped in a tank filled with a rinsing liquid for a certain period of time (a dip method), and a method in which a rinsing liquid is sprayed on a substrate surface (a spray method).

Furthermore, the pattern forming method of the embodiment of the present invention may include a heating step (post bake) after the rinsing step. By the present step, the developer and the rinsing liquid remaining between and inside the patterns are removed by baking. In addition, the present step also has an effect that a resist pattern is annealed and the surface roughness of the pattern is improved. The heating step after the rinsing step is usually performed at 40° C. to 250° C. (preferably 90° C. to 200° C.) for usually 10 seconds to 3 minutes (preferably 30 seconds to 120 seconds).

In addition, an etching treatment on the substrate may be carried out using a pattern thus formed as a mask. That is, the substrate (or the underlayer film and the substrate) may be processed using the pattern thus formed in the step 3 as a mask to form a pattern on the substrate.

A method for processing the substrate (or the underlayer film and the substrate) is not particularly limited, but a method in which a pattern is formed on a substrate by subjecting the substrate (or the underlayer film and the substrate) to dry etching using the pattern thus formed in the step 3 as a mask is preferable. Oxygen plasma etching is preferable as the dry etching.

It is preferable that various materials (for example, a solvent, a developer, a rinsing liquid, a composition for forming an antireflection film, and a composition for forming a topcoat) used in the resist composition and the pattern forming method of the embodiment of the present invention do not include impurities such as metals. The content of the impurities included in these materials is preferably 1 ppm by mass or less, more preferably 10 ppb by mass or less, still more preferably 100 ppt by mass or less, particularly preferably 10 ppt by mass or less, and most preferably 1 ppt by mass or less with respect to the total solid content of the resist composition. The lower limit is not particularly limited, and is preferably 0 ppt by mass or more with respect to the total solid content of the resist composition. Here, examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of a method for removing impurities such as metals from the various materials include filtration using a filter. Details of filtration using a filter are described in paragraph [0321] of WO2020/004306A.

In addition, examples of a method for reducing impurities such as metals included in various materials include a method of selecting raw materials having a low content of metals as raw materials constituting various materials, a method of subjecting raw materials constituting various materials to filter filtration, and a method of performing distillation under the condition for suppressing the contamination as much as possible by, for example, lining the inside of a device with TEFLON (registered trademark).

In addition to the filter filtration, removal of impurities by an adsorbing material may be performed, or a combination of filter filtration and an adsorbing material may be used. As the adsorbing material, known adsorbing materials may be used, and for example, inorganic adsorbing materials such as silica gel and zeolite, and organic adsorbing materials such as activated carbon can be used. It is necessary to prevent the incorporation of impurities such as metals in the production process in order to reduce the metal impurities included in the various materials. Sufficient removal of metal impurities from a production device can be confirmed by measuring a content of metal components included in a cleaning liquid used to clean the production device. The content of the metal components included in the cleaning liquid after the use is preferably 100 parts per trillion (ppt) by mass or less, more preferably 10 ppt by mass or less, and still more preferably 1 ppt by mass or less. The lower limit is not particularly limited and is preferably 0 ppt by mass or more.

A conductive compound may be added to an organic treatment liquid such as a rinsing liquid in order to prevent breakdown of chemical liquid pipes and various parts (a filter, an O-ring, a tube, and the like) due to electrostatic charging, and subsequently generated electrostatic discharging. The conductive compound is not particularly limited, but examples thereof include methanol. The addition amount is not particularly limited, but from the viewpoint that preferred development characteristics or rinsing characteristics are maintained, the addition amount is preferably 10% by mass or less, and more preferably 5% by mass or less. The lower limit is not particularly limited and is preferably 0.01% by mass or more.

For members of the chemical liquid pipe, for example, various pipes coated with stainless steel (SUS), or a polyethylene, polypropylene, or fluororesin (a polytetrafluoroethylene or perfluoroalkoxy resin, or the like) that has been subjected to an antistatic treatment can be used. In the same manner, for the filter or the O-ring, polyethylene, polypropylene, or a fluororesin (a polytetrafluoroethylene or perfluoroalkoxy resin, or the like) that has been subjected to an antistatic treatment can be used.

[Method for Manufacturing Electronic Device]

Moreover, the present invention further relates to a method for manufacturing an electronic device, including the pattern forming method, and an electronic device manufactured by the manufacturing method.

Suitable aspects of the electronic device of an embodiment of the present invention include an aspect in which the electronic device is suitably mounted on electric and electronic equipment (for example, home appliances, office automation (OA)-related equipment, media-related equipment, optical equipment, telecommunication equipment, and the like).

### Examples

Hereinbelow, the present invention will be described in more detail with reference to Examples. The materials, the amounts of materials used, the proportions, the treatment details, and the treatment procedure shown in Examples below may be appropriately modified as long as the modifications do not depart from the spirit of the present invention. Accordingly, the scope of the present invention should not be construed as being limited to Examples shown below.

[Various Components of Resist Composition]

[Acid-Decomposable Resin (Resin (A)]

As the resins A-1 to A-46, those synthesized in accordance with known methods were used. The compositional ratio (molar ratio; corresponding in order from the left) of the respective repeating units, the weight-average molecular weight (Mw), and the dispersity (Mw/Mn) are shown in Table 1.

Furthermore, the weight-average molecular weight (Mw) and the dispersity (Mw/Mn) of the resins A-1 to A-46 were measured by GPC (carrier: tetrahydrofuran (THF)) (an amount expressed in terms of polystyrene). In addition, the compositional ratios (molar ratios) of the resins were measured by means of ¹³C-nuclear magnetic resonance (NMR).

TABLE 1

| | Molar ratio of repeating unit | | | | Mw | Dispersity |
|---|---|---|---|---|---|---|
| Resin A-1 | 25 | 30 | 45 | — | 6,000 | 1.71 |
| Resin A-2 | 45 | 15 | 40 | — | 10,200 | 1.64 |
| Resin A-3 | 40 | 20 | 40 | — | 7,500 | 1.54 |
| Resin A-4 | 60 | 40 | — | — | 6,800 | 1.52 |
| Resin A-5 | 20 | 30 | 50 | — | 6,500 | 1.63 |
| Resin A-6 | 15 | 40 | 45 | — | 5,900 | 1.59 |
| Resin A-7 | 40 | 20 | 40 | — | 5,100 | 1.51 |
| Resin A-8 | 40 | 60 | — | — | 6,200 | 1.39 |
| Resin A-9 | 25 | 30 | 45 | — | 7,500 | 1.54 |
| Resin A-10 | 30 | 20 | 50 | — | 7,000 | 1.61 |
| Resin A-11 | 20 | 40 | 35 | — | 6,500 | 1.63 |
| Resin A-12 | 40 | 20 | 40 | — | 7,000 | 1.73 |
| Resin A-13 | 25 | 25 | 50 | — | 8,200 | 1.58 |
| Resin A-14 | 40 | 10 | 50 | — | 9,000 | 1.68 |
| Resin A-15 | 35 | 10 | 55 | — | 8,400 | 1.58 |
| Resin A-16 | 20 | 30 | 50 | — | 6,500 | 1.73 |
| Resin A-17 | 45 | 15 | 40 | — | 7,300 | 1.62 |
| Resin A-18 | 40 | 10 | 50 | — | 7,000 | 1.64 |
| Resin A-19 | 70 | 30 | — | — | 11,000 | 1.71 |
| Resin A-20 | 30 | 10 | 60 | — | 8,500 | 1.68 |
| Resin A-21 | 25 | 25 | 50 | — | 6,000 | 1.69 |
| Resin A-22 | 30 | 10 | 50 | 10 | 7,100 | 1.59 |
| Resin A-23 | 30 | 30 | 40 | — | 11,000 | 1.71 |
| Resin A-24 | 30 | 20 | 50 | — | 6,000 | 1.68 |
| Resin A-25 | 50 | 5 | 45 | — | 7,000 | 1.53 |
| Resin A-26 | 20 | 40 | 40 | — | 10,000 | 1.57 |
| Resin A-27 | 30 | 15 | 55 | — | 5,500 | 1.55 |
| Resin A-28 | 40 | 30 | 30 | — | 7,500 | 1.63 |
| Resin A-29 | 25 | 35 | 40 | — | 9,200 | 1.71 |
| Resin A-30 | 40 | 10 | 50 | — | 7,000 | 1.65 |
| Resin A-31 | 50 | 50 | — | — | 13,000 | 1.69 |
| Resin A-32 | 65 | 35 | — | — | 8,500 | 1.66 |
| Resin A-33 | 50 | 50 | — | — | 7,600 | 1.49 |
| Resin A-34 | 40 | 60 | — | — | 9,500 | 1.68 |
| Resin A-35 | 50 | 50 | — | — | 8,500 | 1.63 |
| Resin A-36 | 15 | 45 | 40 | — | 6,400 | 1.51 |
| Resin A-37 | 40 | 10 | 50 | — | 12,000 | 1.49 |
| Resin A-38 | 50 | 30 | 20 | — | 8,000 | 1.65 |
| Resin A-39 | 25 | 30 | 30 | 15 | 8,500 | 1.61 |
| Resin A-40 | 30 | 50 | 10 | 10 | 5,000 | 1.61 |
| Resin A-41 | 25 | 30 | 30 | 15 | 8,600 | 1.63 |
| Resin A-42 | 40 | 10 | 10 | 40 | 6,500 | 1.63 |
| Resin A-43 | 40 | 30 | 30 | — | 5,900 | 1.59 |
| Resin A-44 | 10 | 30 | 60 | — | 5,200 | 1.53 |
| Resin A-45 | 30 | 20 | 50 | — | 7,600 | 1.56 |
| Resin A-46 | 40 | 10 | 40 | 10 | 7,000 | 1.61 |

The structural formulae of the resins A-1 to A-46 shown in Table 1 are shown below.

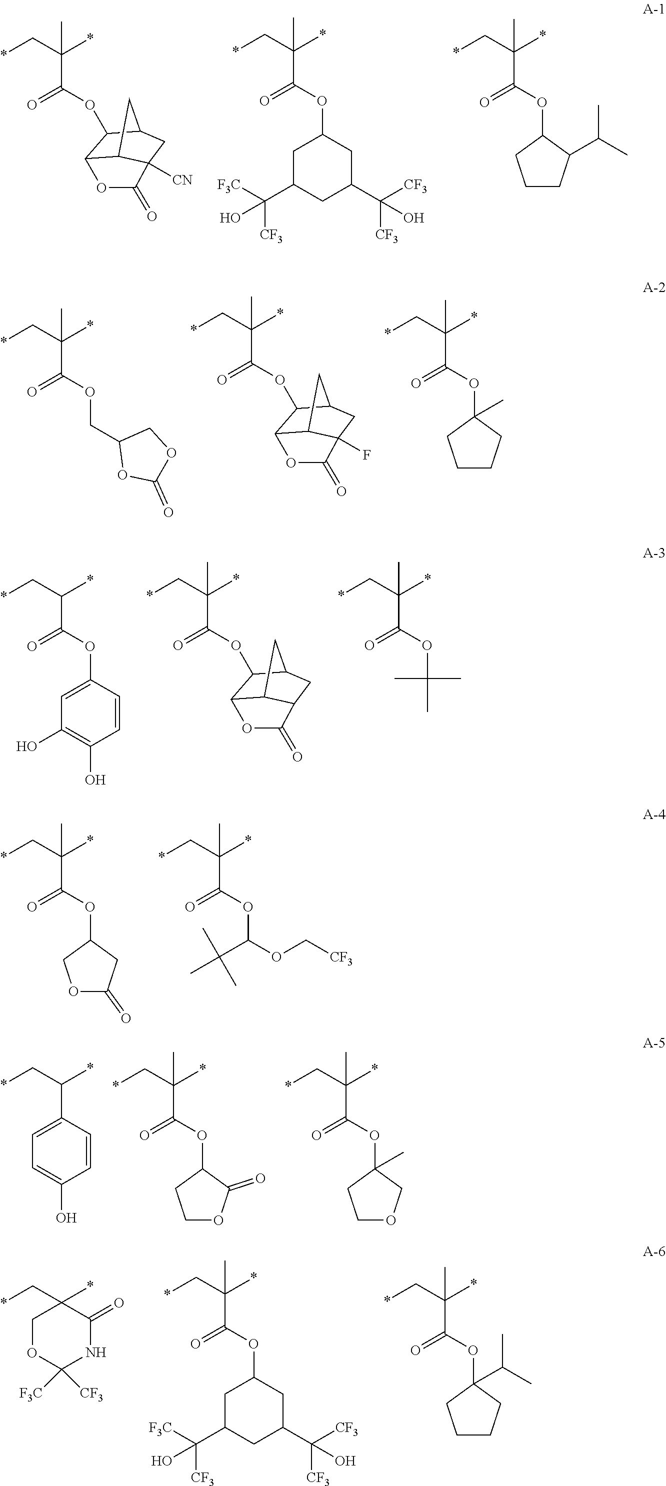

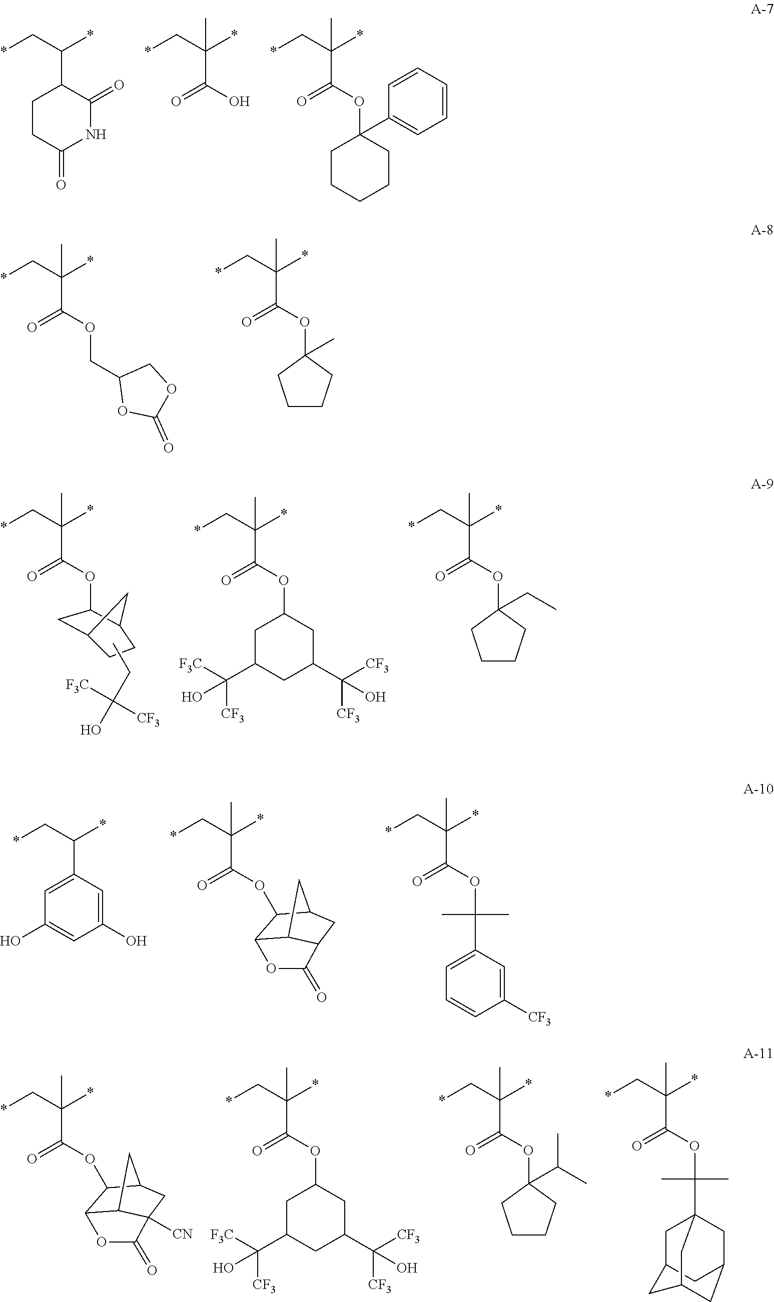

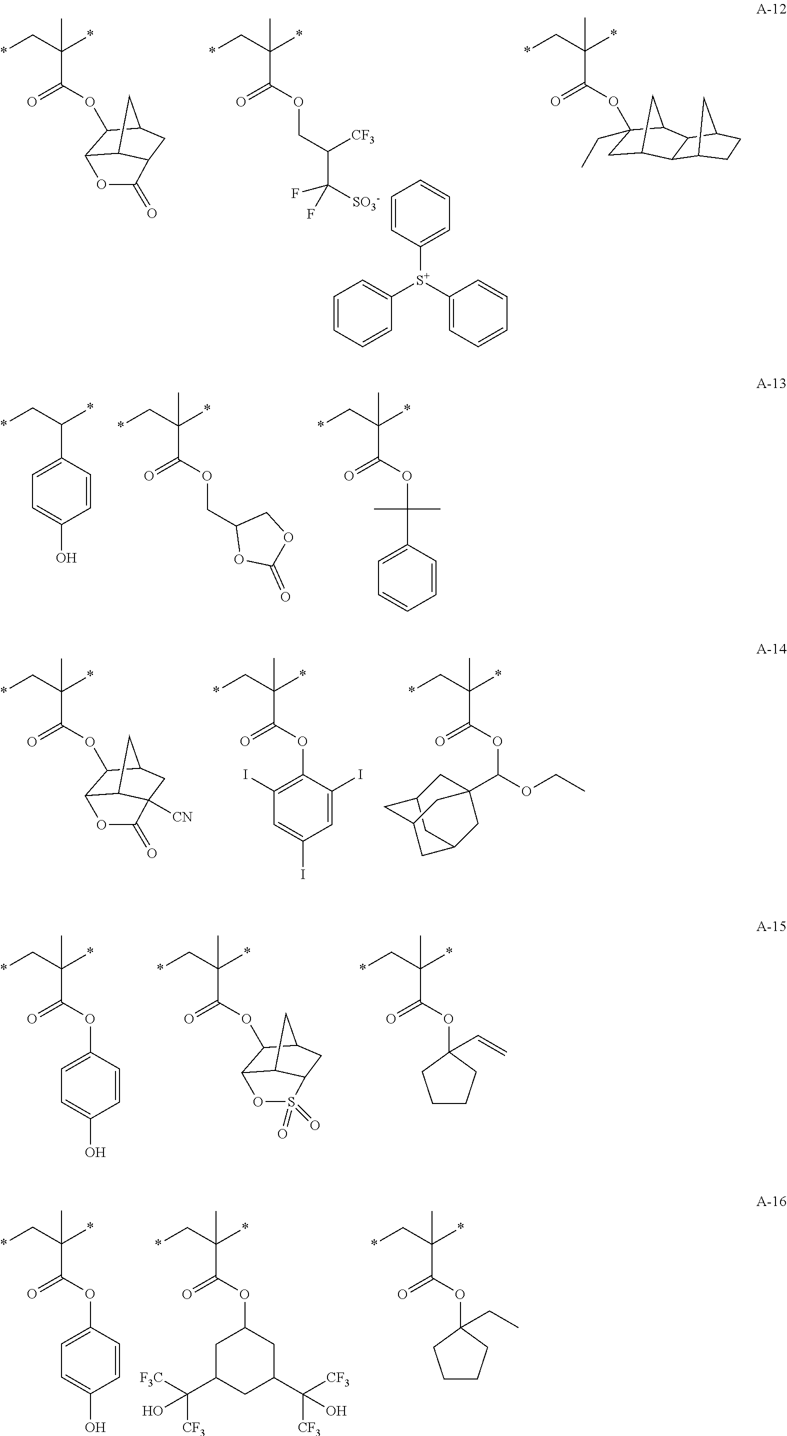

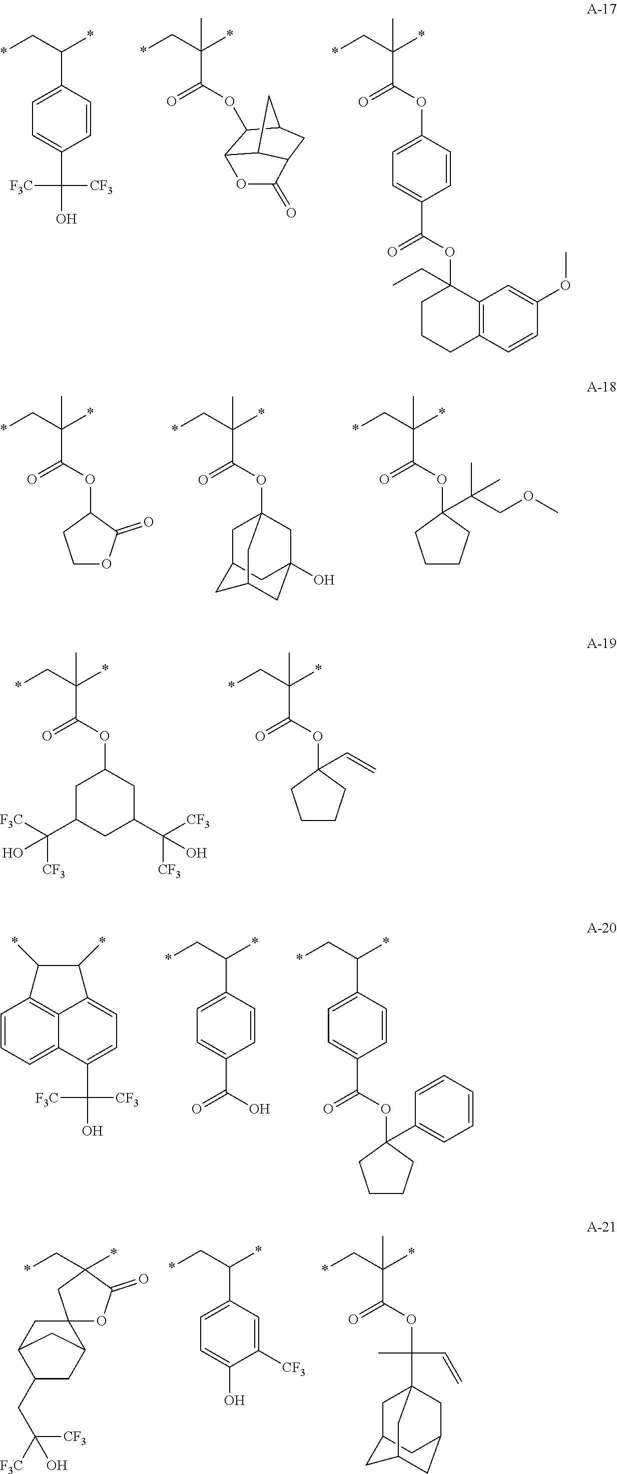

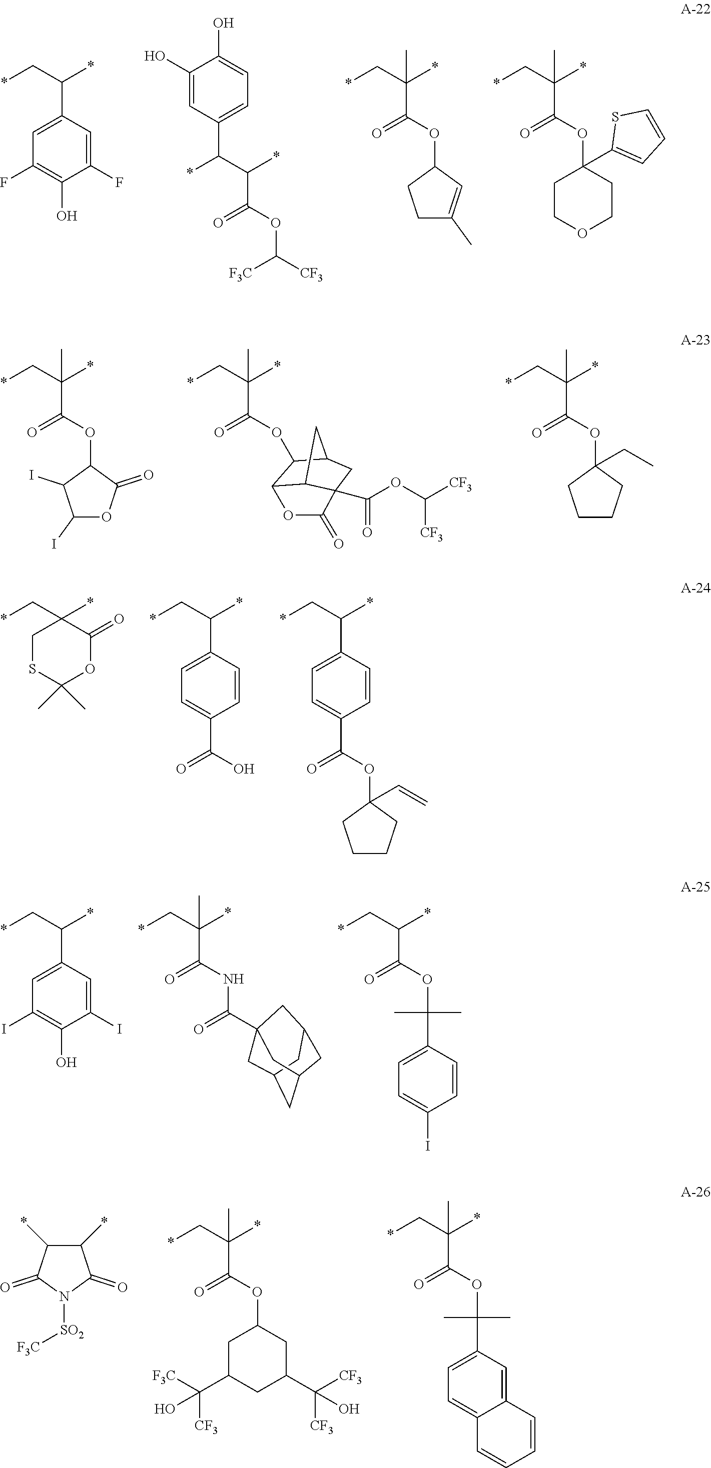

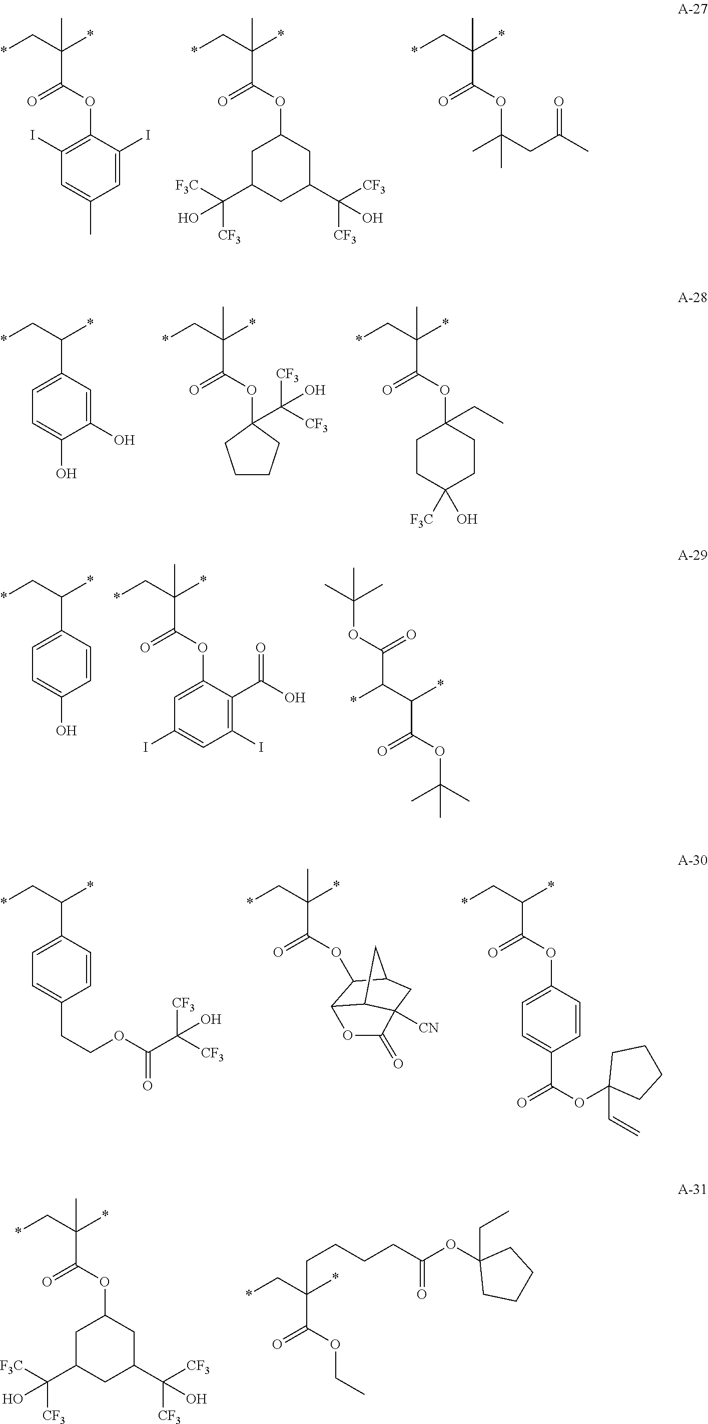

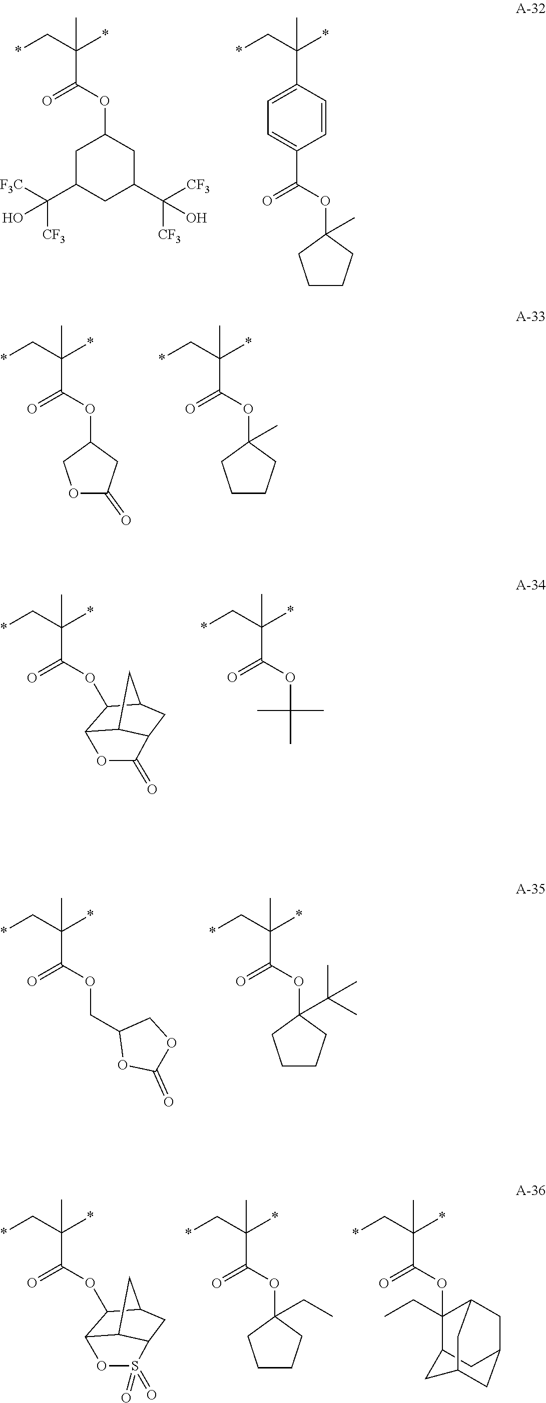

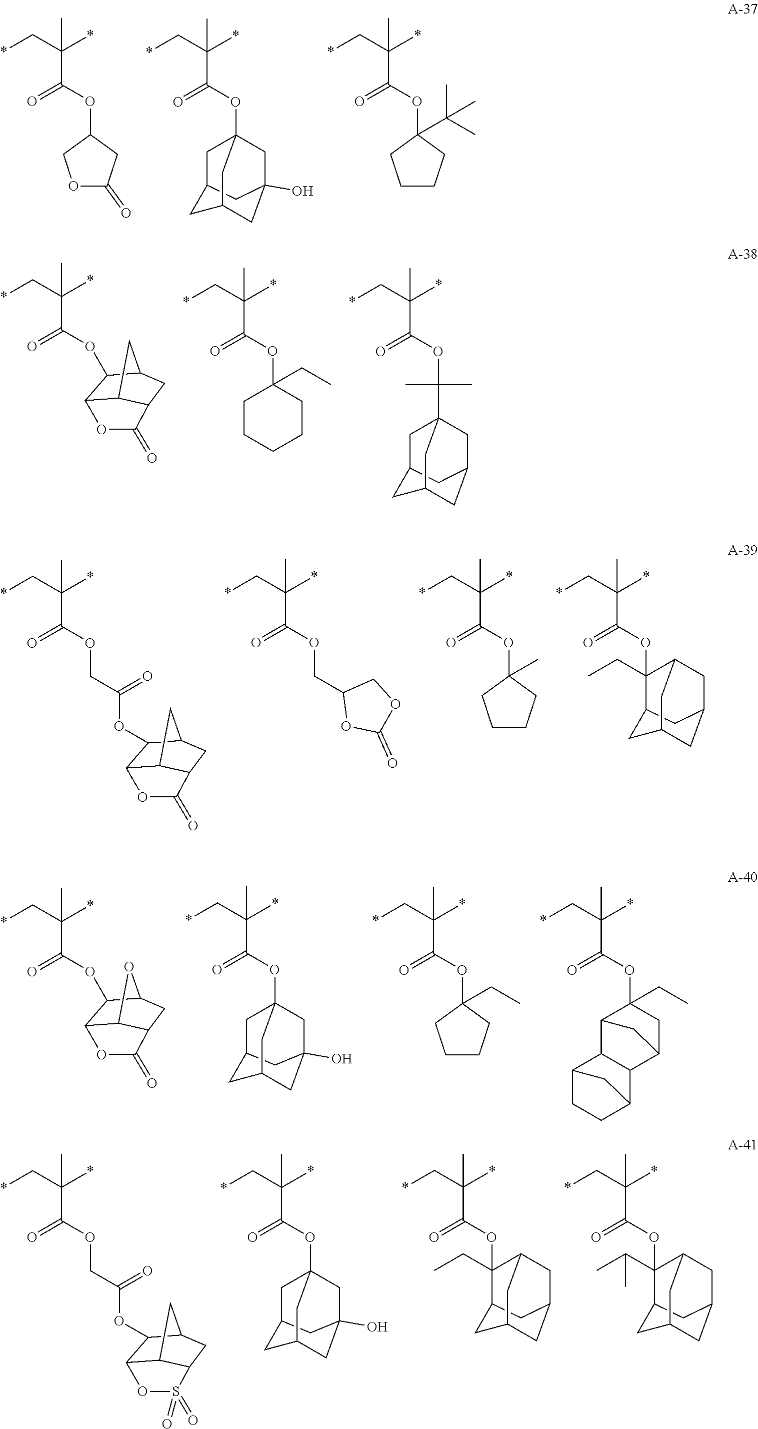

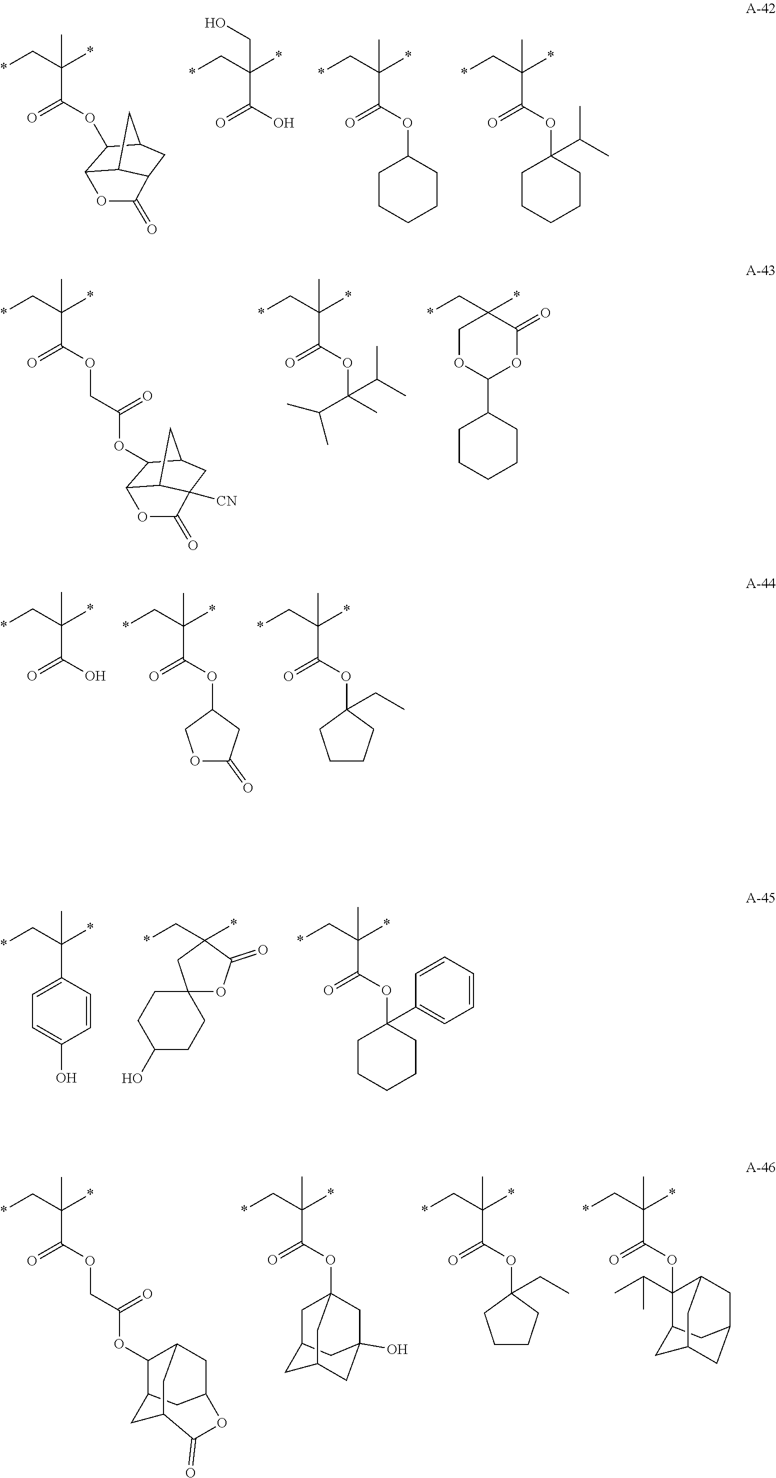

[Photoacid Generator]

<Compound (X) and Comparative Compound>

Hereinafter, a method for synthesizing a compound X-1 will be shown.

In addition, as other compound (I) and comparative compound, those synthesized in accordance with a method for synthesizing the compound X-1 which will be described later were used.

(Synthesis of Compound X-1)

The compound X-1 was synthesized by the following synthesis method.

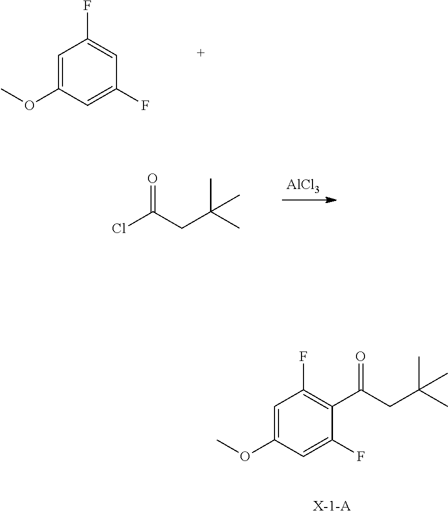

A solution was prepared by dissolving phenyl ether (5.8 g) in dichloromethane (30 mL). The obtained solution was cooled to 0° C., and then aluminum chloride (5.8 g) was added thereto. Then, tert-butylacetyl chloride (5.4 g) was added dropwise to the solution at 0° C. and the reaction mixture was stirred at 0° C. for 2 hours. The obtained reaction mixture was poured into a mixed solution of hexane/ethyl acetate (volume ratio of 3/1, 60 mL) and ice water (60 mL), and the mixture was stirred for 10 minutes. The obtained aqueous phase was extracted 3 times with hexane/ethyl acetate (volume ratio of 3/1, 20 mL). The obtained organic phase was cleaned with 1 N hydrochloric acid, water, saturated multilayer water, and a saline solution, and then the solvent was distilled off under reduced pressure. The crude product was purified by silica gel column chromatography (eluted with a mixed solvent of ethyl acetate/hexane) to obtain a compound X-1-A (5.46 g) as a colorless liquid (yield: 56%).

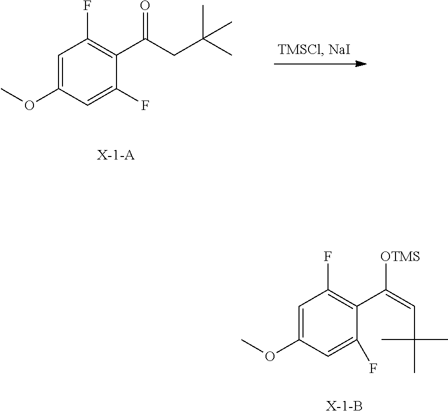

The compound X-1-A (8.5 g) was dissolved in acetonitrile (25 mL), and sodium iodide (7.9 g) and triethylamine (8.9 g) were added thereto. Chlorotrimethylsilane (5.7 g) was added dropwise to the obtained solution and the reaction mixture was stirred at 50° C. for 2 hours. After cooling to room temperature, the reaction mixture was poured into a mixed solution of hexane/ethyl acetate (volume ratio of 3/1, 90 mL) and saturated multilayer water (90 mL), and the mixture was stirred for 10 minutes. The obtained aqueous phase was extracted 3 times with hexane/ethyl acetate (volume ratio of 3/1, 20 mL). The obtained organic phase was cleaned with saturated multilayer water, water, and a saline solution, and then the solvent was distilled off under reduced pressure to obtain a compound X-1-B (11.0 g) as a colorless liquid (yield: 99%).

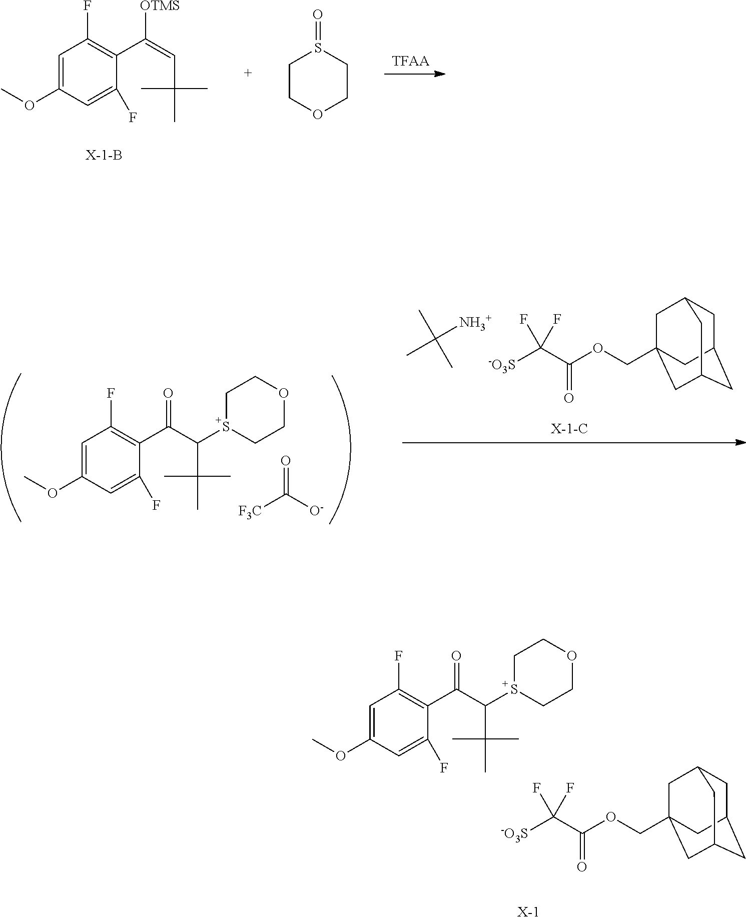

The compound X-1-B (11.0 g) and 1,4-thioxan-4-oxide (6.3 g) were dissolved in dichloromethane (68 mL) and cooled to −40° C. A dichloromethane solution (7.5 mL) of trifluoroacetic anhydride (11.0 g) was added dropwise thereto at −35° C. or lower, and the obtained reaction mixture was stirred at −35° C. for 3 hours. The obtained reaction mixture was heated to 0° C., water (10 mL) was added dropwise thereto at 10° C. or lower, and then saturated multilayer water (135 mL) was added dropwise thereto at 10° C. or lower. After the temperature was raised to room temperature, the mixture was stirred for 15 minutes, the compound X-1-C(14.6 g) was added thereto, and the mixture was stirred for 30 minutes. The obtained aqueous phase was extracted with dichloromethane (60 mL). The obtained organic phase was cleaned with 10% by mass potassium carbonate water (80 mL) twice and with water (80 mL) 5 times, and then the solvent was distilled off under reduced pressure. The obtained crude product was recrystallized from diisopropyl ether to obtain a compound X-1 (16.8 g) as a white solid (yield: 72%).

The structures of the compounds (X) (the compounds X-1 to X-24) and a comparative compound (compound Z-1) shown in Tables 3 and 6 are shown below.

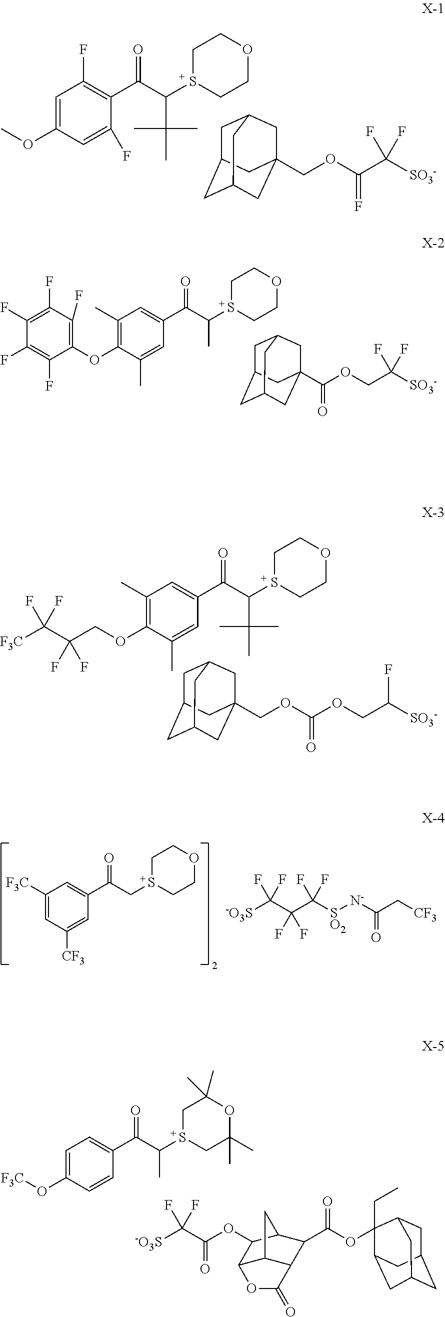

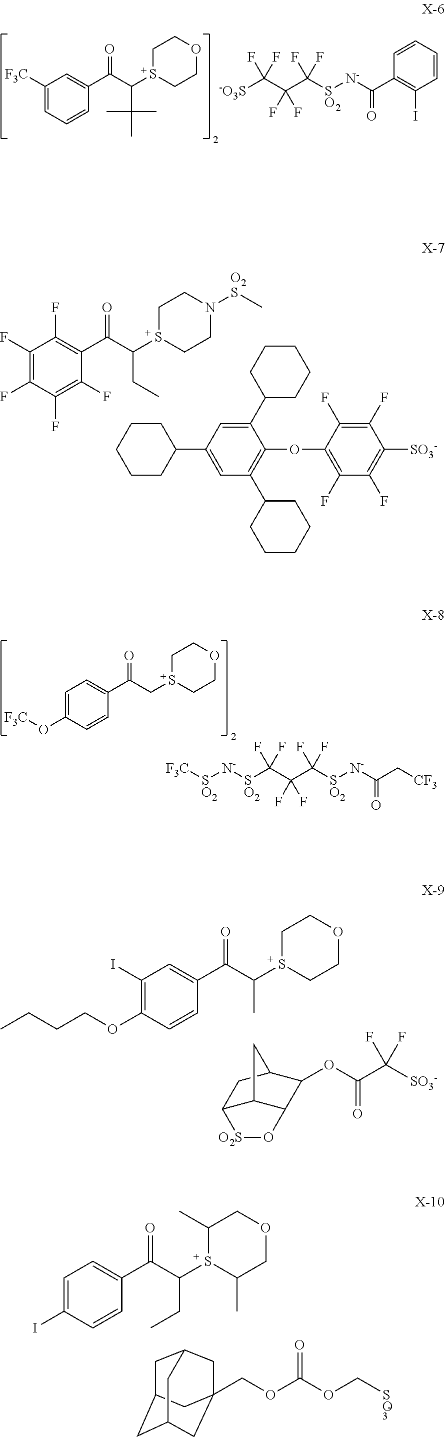

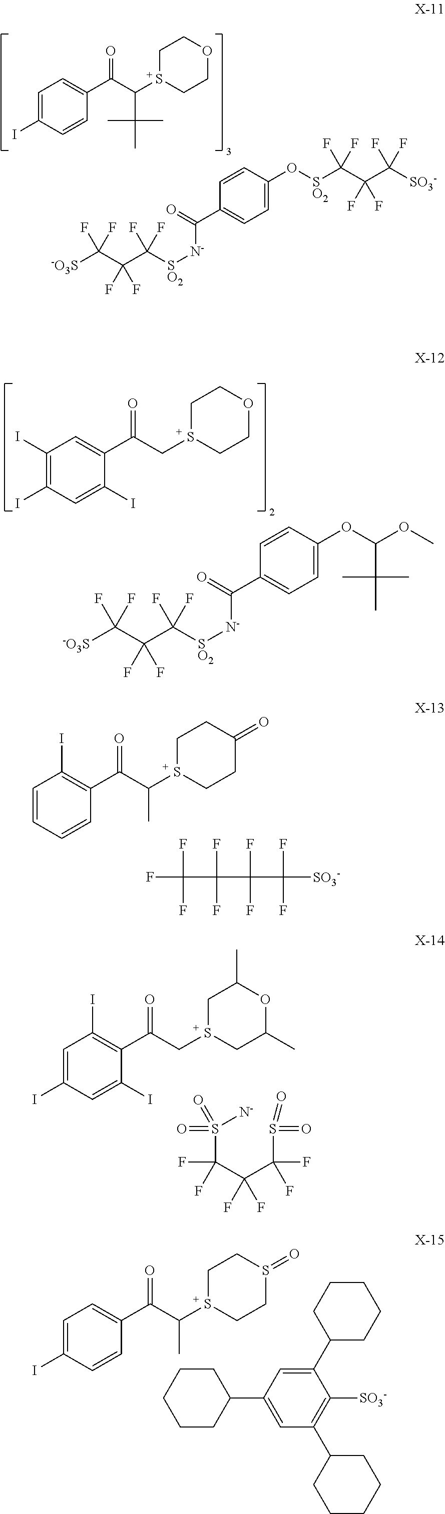

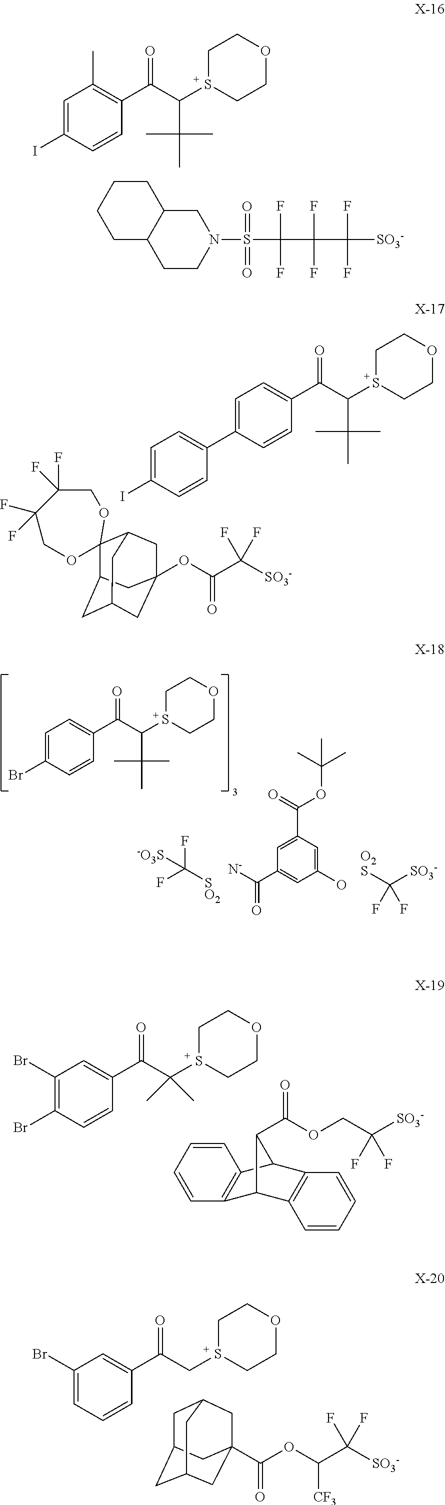

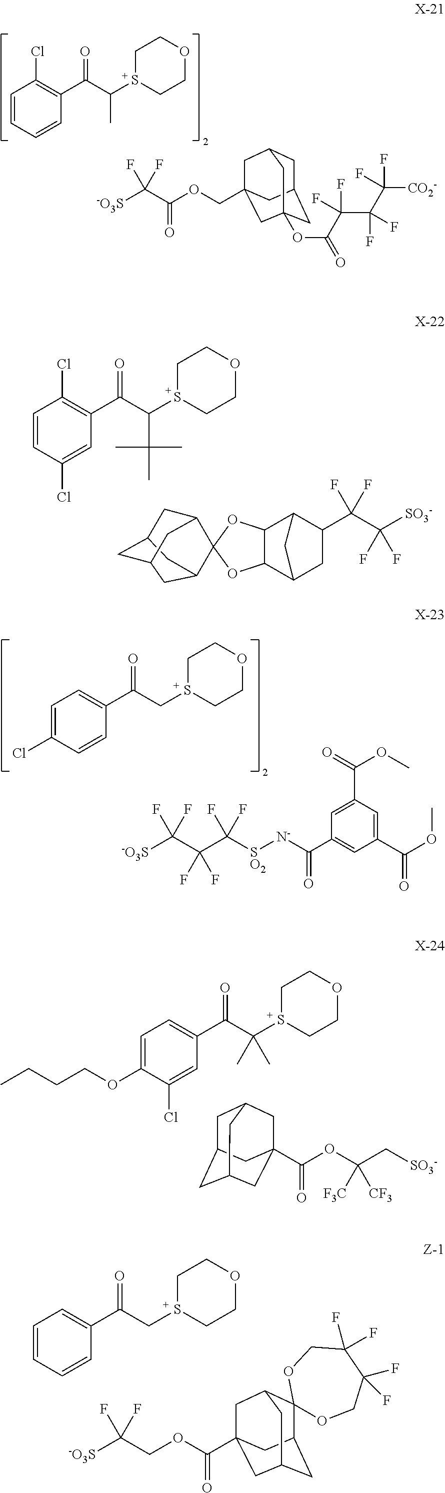

<Photoacid Generator B>

The structures of photoacid generators B (compounds B-1 to B-15) shown in Tables 3 and 6 are shown below.

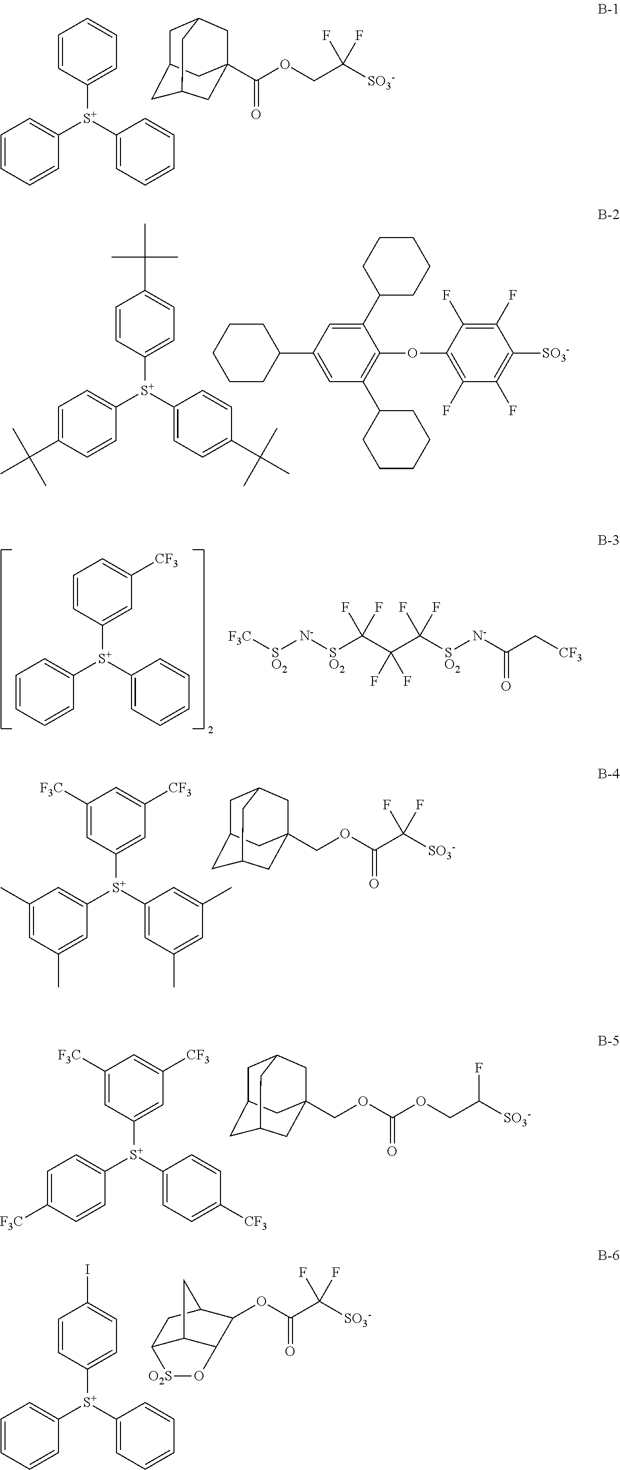

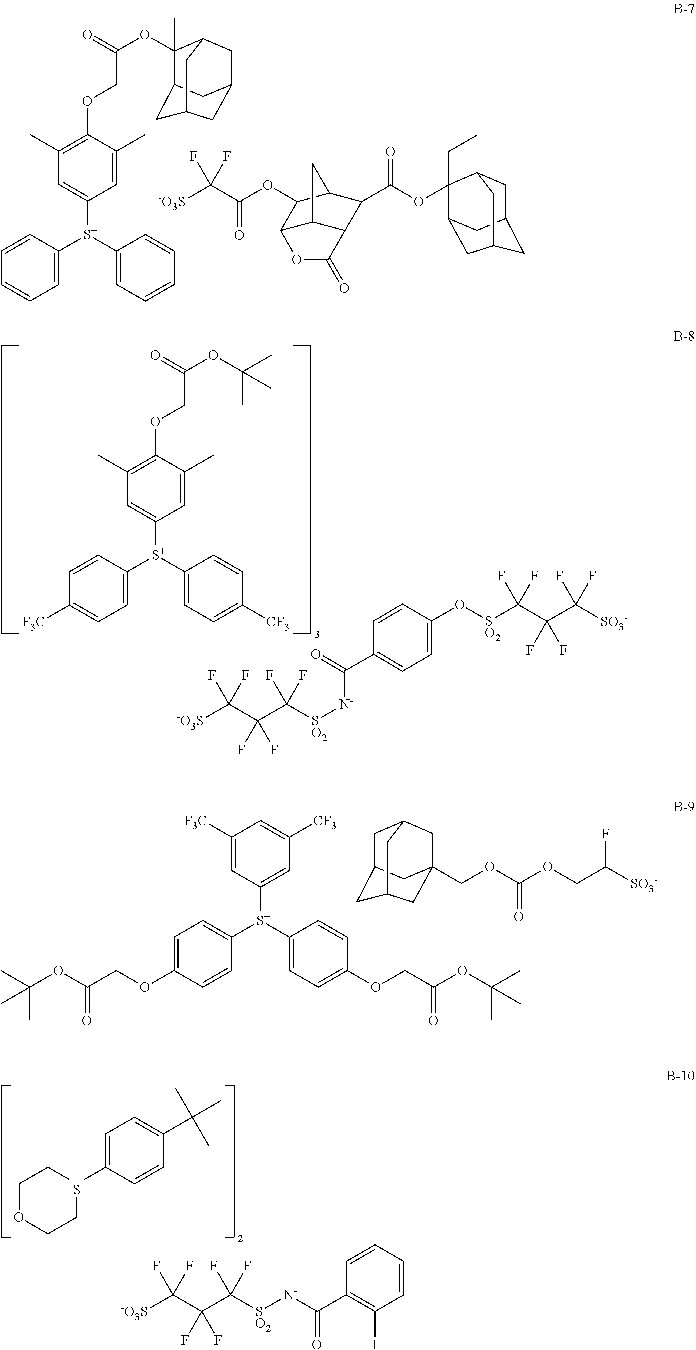

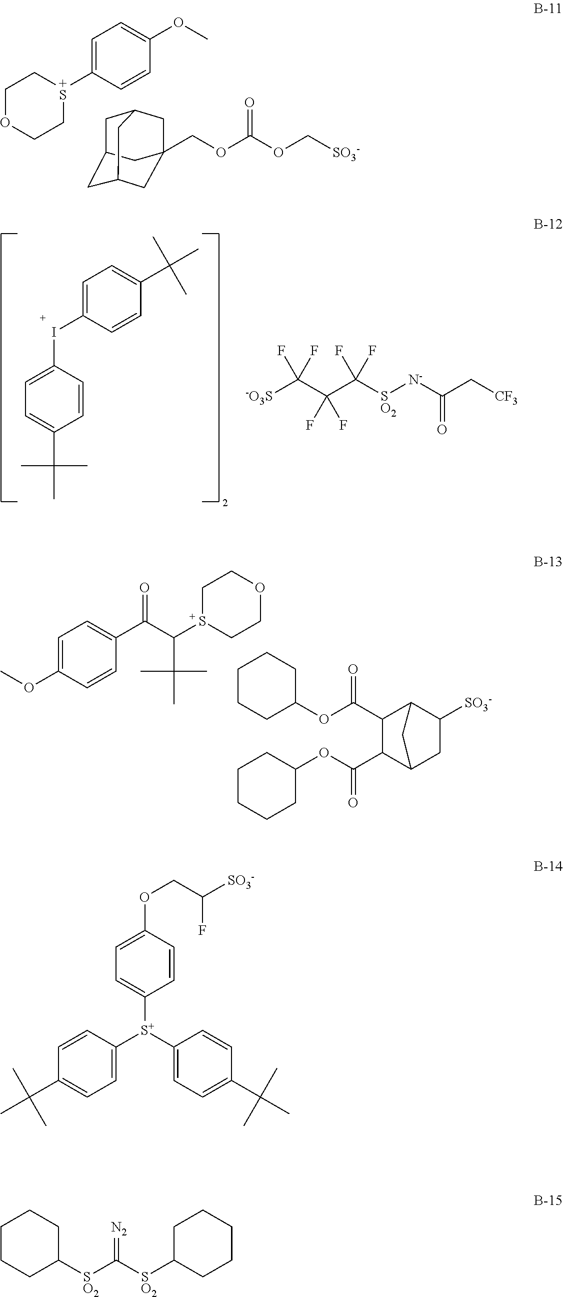

[Acid Diffusion Control Agent]

The structures of acid diffusion control agents C (compounds C-1 to C-13) shown in Tables 3 and 6 are shown below.

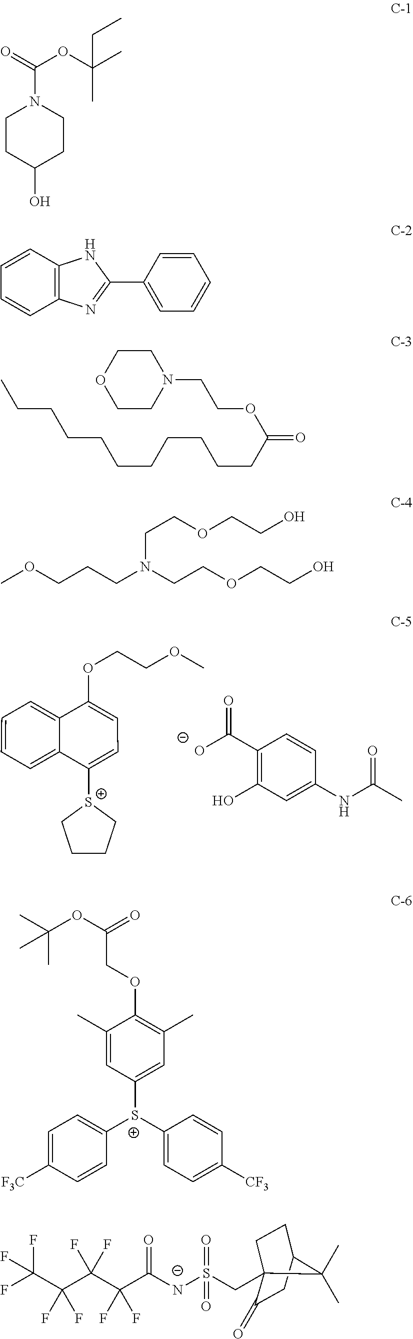

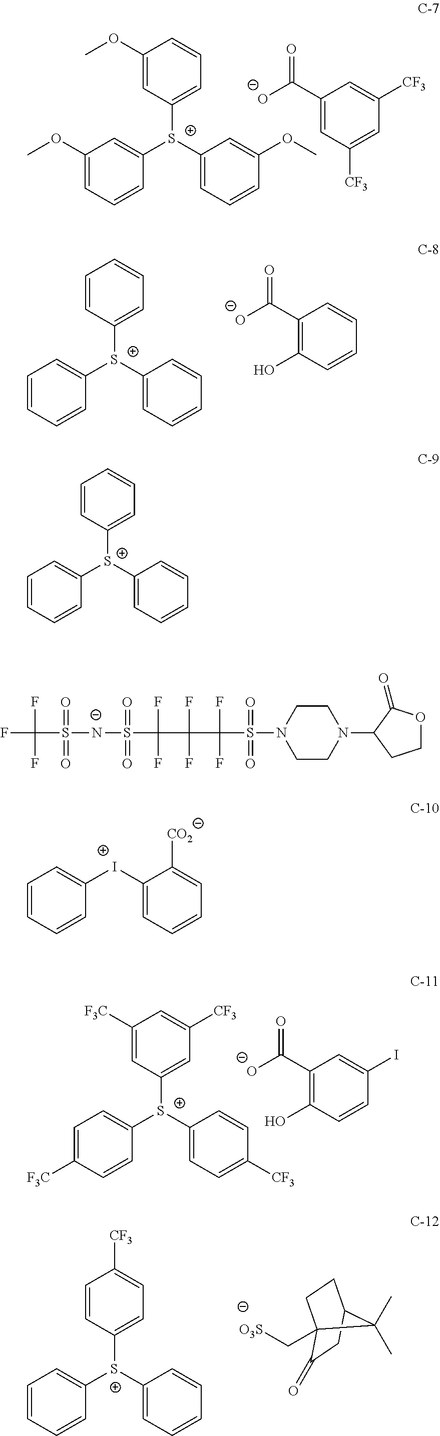

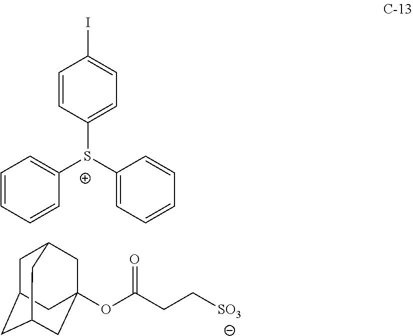

[Hydrophobic Resin and Resin for Topcoat]

As hydrophobic resins (D-1 to D-8) shown in Table 3 and Table 6 and resins (PT-1 to PT-3) for a topcoat shown in Table 7, those synthesized were used.

The molar ratios of the repeating units, the weight-average molecular weights (Mw), and the dispersities (Mw/Mn) in the hydrophobic resins (D-1 to D-8) shown in Table 2, Table 3, and Table 6 and the resins (PT-1 to PT-3) for a topcoat shown in Table 7 are shown.

Furthermore, the weight-average molecular weights (Mw) and the dispersities (Mw/Mn) of the hydrophobic resins D-1 to D-8 and the resins PT-1 to PT-3 for a topcoat were measured by GPC (carrier: tetrahydrofuran (THF)) (an amount expressed in terms of polystyrene). In addition, the compositional ratios (molar ratios) of the resins were measured by means of ¹³C-nuclear magnetic resonance (NMR).

TABLE 2

| | Molar ratio of | | Molar ratio of | | Molar ratio of | | Molar ratio of | | | |
|---|---|---|---|---|---|---|---|---|---|---|
| | repeating unit 1 | | repeating unit 2 | | repeating unit 3 | | repeating unit 4 | | Mw | Mw/Mn |
| Resin D-1 | ME-12 | 50 | ME-1 | 50 | — | — | — | — | 12,000 | 1.5 |
| Resin D-2 | ME-2 | 40 | ME-11 | 50 | ME-7 | 5 | ME-14 | 5 | 6,000 | 1.3 |
| Resin D-3 | ME-8 | 50 | ME-2 | 50 | — | — | — | — | 15,000 | 1.5 |
| Resin D-4 | ME-5 | 100 | — | — | — | — | — | — | 23,000 | 1.7 |
| Resin D-5 | ME-11 | 10 | ME-13 | 85 | ME-7 | 5 | — | — | 11,000 | 1.4 |
| Resin D-6 | ME-6 | 80 | ME-9 | 20 | — | — | — | — | 13,000 | 1.4 |
| Resin D-7 | ME-5 | 50 | ME-15 | 50 | — | — | — | — | 12,000 | 1.5 |
| Resin D-8 | ME-2 | 50 | ME-16 | 50 | — | — | — | — | 10,000 | 1.6 |
| Resin PT-1 | ME-2 | 40 | ME-9 | 30 | ME-7 | 30 | — | — | 8,000 | 1.6 |
| Resin PT-2 | ME-2 | 50 | ME-6 | 40 | ME-3 | 10 | — | — | 5,000 | 1.5 |
| Resin PT-3 | ME-3 | 30 | ME-4 | 65 | ME-10 | 5 | — | — | 8,500 | 1.7 |

The monomer structures used in the synthesis of the hydrophobic resins D-1 to D-8 shown in Table 2 and the resins PT-1 to PT-3 for a topcoat shown in Table 7 are shown below.

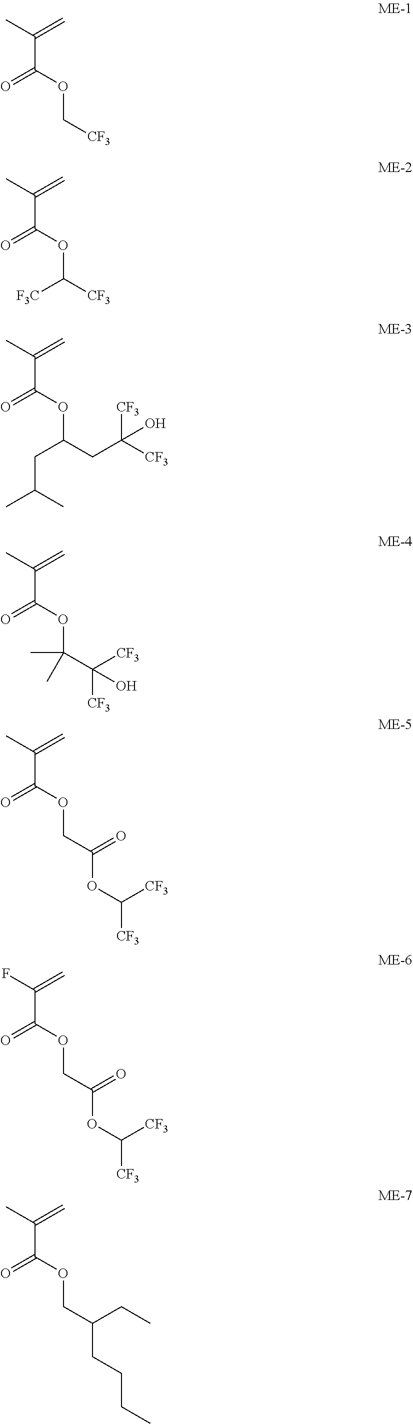

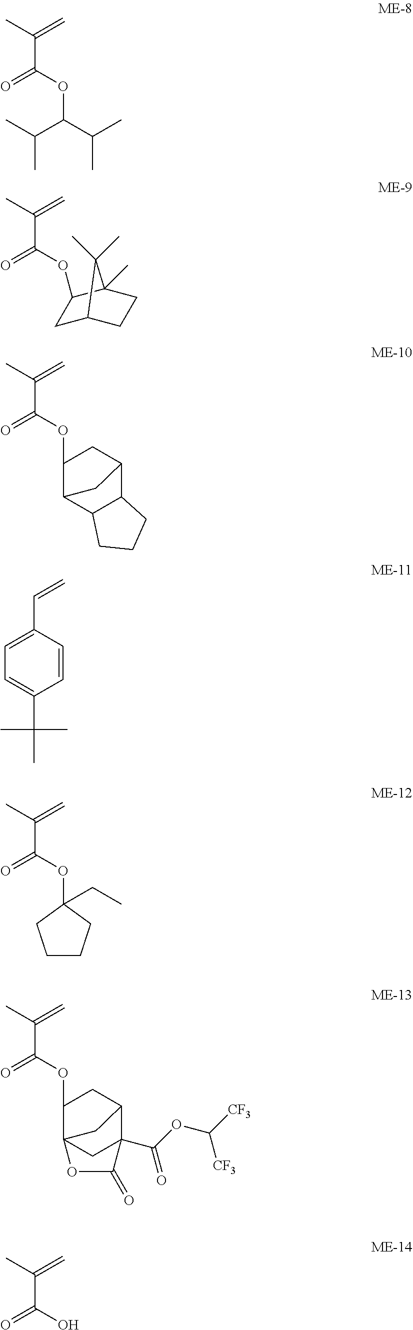

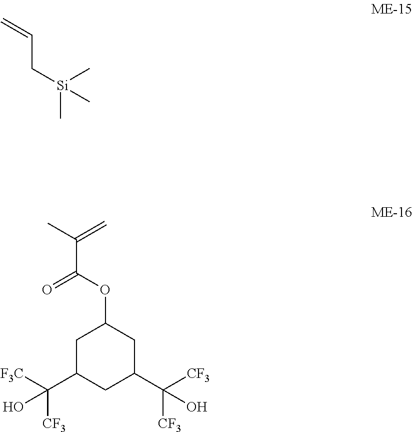

[Surfactant]

Surfactants shown in Table 3 and Table 6 are shown below.

E-1: MEGAFACE F176 (manufactured by DIC Corporation, fluorine-based surfactant)

E-2: MEGAFACE R08 (manufactured by DIC Corporation, fluorine- and silicon-based surfactant)

E-3: PF656 (manufactured by OMNOVA Solutions Inc., fluorine-based surfactant)

[Solvent]

The solvents shown in Table 3 and Table 6 are shown below.

F-1: Propylene glycol monomethyl ether acetate (PGMEA)

F-2: Propylene glycol monomethyl ether (PGME)

F-3: Propylene glycol monoethyl ether (PGEE)

F-4: Cyclohexanone

F-5: Cyclopentanone

F-6: 2-Heptanone

F-7: Ethyl lactate

F-8: 7-Butyrolactone

F-9: Propylene carbonate

[Preparation of Resist Composition and Pattern Formation: EUV Exposure]

[Preparation (1) of Resist Composition]

The respective components shown in Table 3 were mixed so that the concentration of solid contents was 2% by mass. Then, the obtained mixed liquid was filtered initially through a polyethylene-made filter having a pore diameter of 50 nm, then through a nylon-made filter having a pore diameter of 10 nm, and lastly through a polyethylene-made filter having a pore diameter of 5 nm in this order to prepare a resist composition. The obtained resist composition was used in Examples and Comparative Examples. In addition, in the resist composition, the solid content means all the components excluding the solvent.

TABLE 3

| | | | | | Photoacid | | Acid diffusion | | Hydrophobic | | | | | |
|---|---|---|---|---|---|---|---|---|---|---|---|---|---|---|
| | Compound (X) | | Resin A | | generator B | | control agent C | | resin D | | Surfactant E | | Solvent F | |
| Resist | | % by | | % by | | % by | | % by | | % by | | % by | | Mixing |
| composition | Type | mass | Type | mass | Type | mass | Type | mass | Type | mass | Type | mass | Type | ratio |
| Re-1 | X-1 | 19.8 | A-5 | 71.7 | — | — | C-6 | 8.5 | — | — | — | — | F-1/F-8 | 85/15 |
| Re-2 | X-2 | 22.5 | A-11 | 74.3 | — | — | C-3 | 3.2 | — | — | — | — | F-1/F-2 | 70/30 |
| Re-3 | X-3 | 25.5 | A-9 | 68.7 | — | — | C-12 | 5.8 | — | — | — | — | F-1/F-7 | 80/20 |
| Re-4 | X-4 | 34.2 | A-20 | 64.7 | — | — | — | — | D-2 | 1.1 | — | — | F-4 | 100 |
| Re-5 | X-5 | 26.5 | A-28 | 71.4 | — | — | C-2 | 2.0 | — | — | E-3 | 0.1 | F-1/F-9 | 90/10 |
| Re-6 | X-6 | 38.2 | A-3 | 61.8 | — | — | — | — | — | — | — | — | F-1/F-6 | 40/60 |
| Re-7 | X-7 | 29.5 | A-16 | 64.1 | — | — | C-7 | 6.4 | — | — | — | — | F-1/F-5 | 50/50 |
| Re-8 | X-8 | 41.2 | A-32 | 56.5 | — | — | — | — | D-4 | 2.3 | — | — | F-1 | 100 |
| Re-9 | X-9 | 23.5 | A-10 | 72.3 | — | — | C-8 | 4.2 | — | — | — | — | F-1/F-2/ | 70/25/5 |
| | | | | | | | | | | | | | F-8 | |
| Re-10 | X-10 | 21.0 | A-13 | 68.8 | — | — | C-9 | 10.2 | — | — | — | — | F-1 | 100 |
| Re-11 | X-11 | 51.2 | A-26 | 46.8 | — | — | — | — | D-1 | 2.0 | — | — | F-7 | 100 |
| Re-12 | X-12 | 48.6 | A-12 | 51.4 | — | — | — | — | — | — | — | — | F-1/F-2 | 70/30 |
| Re-13 | X-13 | 21.5 | A-4 | 70.5 | — | — | C-11 | 8.0 | — | — | — | — | F-1/F-3 | 90/10 |
| Re-14 | X-14 | 27.6 | A-23 | 69.0 | — | — | C-10 | 3.4 | — | — | — | — | F-1/F-7 | 80/20 |
| Re-15 | X-15 | 24.2 | A-15 | 70.4 | — | — | C-2 | 2.0 | D-6 | 3.4 | — | — | F-1/F-8 | 85/15 |
| Re-16 | X-16 | 32.0 | A-13/A-18 | 29.3/29.4 | — | — | C-13 | 9.1 | — | — | E-1/E-2 | 0.1/0.1 | F-4 | 100 |
| Re-17 | X-17 | 31.0 | A-21 | 66.5 | — | — | C-4 | 2.5 | — | — | — | — | F-1/F-5 | 50/50 |
| Re-18 | X-18 | 46.1 | A-19 | 53.9 | — | — | — | — | — | — | — | — | F-1 | 100 |
| Re-19 | X-19 | 25.1 | A-22 | 71.7 | — | — | C-1 | 2.1 | D-8 | 1.1 | — | — | F-1/F-2/ | 70/25/5 |
| | | | | | | | | | | | | | F-8 | |
| Re-20 | X-20 | 25.0 | A-31 | 69.1 | — | — | C-5 | 5.9 | — | — | — | — | F-1/F-6 | 40/60 |
| Re-21 | X-21 | 32.6 | A-17 | 67.4 | — | — | — | — | — | — | — | — | F-4 | 100 |
| Re-22 | X-22 | 25.1 | A-1 | 69.4 | — | — | C-8 | 5.5 | — | — | — | — | F-1 | 100 |
| Re-23 | X-23 | 34.6 | A-27 | 62.5 | — | — | — | — | D-7 | 2.9 | — | — | F-1 | 100 |
| Re-24 | X-24 | 31.2 | A-8 | 65.4 | — | — | C-9 | 3.4 | — | — | — | — | F-1/F-3 | 90/10 |
| Re-25 | X-4 | 44.2 | A-2 | 50.5 | B-7 | 3.8 | — | — | D-3 | 1.5 | — | — | F-1/F-2 | 70/30 |
| Re-26 | X-12 | 35.0 | A-30 | 55.0 | B-10 | 10.0 | — | — | — | — | — | — | F-4 | 100 |
| Re-27 | X-23 | 42.1 | A-29 | 56.2 | B-15 | 1.7 | — | — | — | — | — | — | F-1/F-9 | 90/10 |
| Re-28 | X-6 | 38.1 | A-14 | 58.9 | B-5 | 3.0 | — | — | — | — | — | — | F-1/F-2 | 70/30 |
| Re-29 | X-18 | 34.5 | A-24 | 57.8 | B-2 | 5.8 | — | — | D-5 | 1.9 | — | — | F-1/F-8 | 85/15 |
| Re-30 | X-2 | 10.1 | A-7 | 65.9 | B-6 | 10.9 | C-9 | 13.1 | — | — | — | — | F-7 | 100 |
| Re-31 | X-3 | 16.1 | A-25 | 59.8 | B-12 | 24.1 | — | — | — | — | — | — | F-1/F-8 | 85/15 |
| Re-32 | X-14 | 6.9 | A-6 | 50.9 | B-8 | 42.1 | — | — | — | — | E-1 | 0.1 | F-1/F-2 | 70/30 |
| Re-33 | X-1 | 6.8 | A-6 | 65.2 | B-3 | 28.0 | — | — | — | — | — | — | F-1/F-7 | 80/20 |
| Re-34 | X-9 | 12.3 | A-13 | 72.2 | B-4 | 10.0 | C-8 | 5.5 | — | — | — | — | F-4 | 100 |
| Re-35 | X-14 | 14.1 | A-22 | 64.6 | B-9 | 14.1 | C-12 | 7.1 | — | — | E-2 | 0.1 | F-1/F-9 | 90/10 |
| Re-36 | X-4 | 15.2 | A-3 | 79.2 | B-11 | 5.6 | — | — | — | — | — | — | F-1/F-6 | 40/60 |
| Re-37 | X-2 | 10.1 | A-26 | 67.1 | B-13 | 16.3 | C-5 | 6.5 | — | — | — | — | F-1/F-5 | 50/50 |
| Re-38 | X-23 | 30.0 | A-30 | 64.8 | B-14 | 5.2 | — | — | — | — | — | — | F-1/F-3 | 70/30 |
| Re-39 | X-1 | 27.6 | A-1/A-5 | 32.0/34.3 | — | — | C-4 | 6.1 | — | — | — | — | F-1/F-8 | 85/15 |
| Re-40 | X-2/X-4 | 7.3/30 | A-17 | 62.7 | — | — | — | — | — | — | — | — | F-1/F-6 | 40/60 |
| Re-41 | X-19/X-20 | 12.1/11.6 | A-22 | 73.2 | — | — | C-2 | 2.0 | D-8 | 1.1 | — | — | F-1/F-2/ | 70/25/5 |
| | | | | | | | | | | | | | F-8 | |
| Re-42 | X-6/X-10 | 33.0/7.5 | A-3 | 59.5 | — | — | — | — | — | — | — | — | F-1/F-6 | 40/60 |
| Re-43 | X-23 | 30.0 | A-27 | 58.3 | B-1/B-2 | 4.1/4.7 | — | — | D-7 | 2.9 | — | — | F-1 | 100 |
| Re-44 | X-4 | 51.6 | A-5 | 48.4 | — | — | — | — | — | — | — | — | F-4 | 100 |
| Re-45 | X-11 | 59.8 | A-1 | 40.2 | — | — | — | — | — | — | — | — | F-1/F-7 | 80/20 |
| Re-C1 | Z-1 | 21.0 | A-5 | 70.5 | — | — | C-6 | 8.5 | — | — | — | — | F-1/F-8 | 85/15 |

[Pattern Formation (1): EUV Exposure and Organic Solvent Development]

A composition for forming an underlayer film, AL412 (manufactured by Brewer Science, Inc.), was applied onto a silicon wafer and baked at 205° C. for 60 seconds to form an underlying film having a film thickness of 20 nm. A resin composition shown in Table 4 was applied thereon and baked at 100° C. for 60 seconds to form a resist film having a film thickness of 30 nm.

The silicon wafer having the obtained resist film was subjected to patternwise irradiation using an EUV exposure device (manufactured by Exitech Ltd., Micro Exposure Tool, NA 0.3, Quadrupol, outer sigma 0.68, inner sigma 0.36). Further, as a reticle, a mask having a line size=20 nm and a line:space=1:1 was used.

The resist film after the exposure was baked at 90° C. for 60 seconds, developed with n-butyl acetate for 30 seconds, and spin-dried to obtain a negative tone pattern.

<Evaluation of Pattern Shape: EUV Exposure and Organic Solvent Development>

A cross-sectional shape of a line pattern having a line width of 20 nm on average was observed, and a pattern line width Lb at the bottom of the resist pattern and a pattern line width La at the upper part of the resist pattern were measured using a length-measuring scanning electron microscope (SEM, S-9380II manufactured by Hitachi, Ltd.).

A case of (Lb/La)≤1.03 was regarded as “Excellent”, a case of 1.03<(Lb/La)≤1.06 was regarded as “Good”, and a case of 1.06<(Lb/La) was regarded as “Poor”. The results are shown in Table 4.

<Temporal Stability of Resist Composition>

The resist composition obtained in [Preparation (1) of Resist Composition] mentioned above was stored at room temperature for 1 month, and then the temporal stability of the resist composition was evaluated according to the following evaluation standard. An exposure amount (mJ/cm²) in the formation of a line pattern having a line width of 20 nm on average was defined as an optimum exposure amount, and a change in the optimum exposure amount between immediately after the preparation of the resist composition and after storage at room temperature for one month (sensitivity variation) was evaluated.

Sensitivity variation (mJ/cm²)=(Sensitivity of resist composition before storage for 1 month (mJ/cm²))−(Sensitivity of resist composition after storage for 1 month (mJ/cm²))|

(Evaluation Standard)

A: The sensitivity variation is less than 1 mJ/cm².

B: The sensitivity variation is from 1 mJ/cm² to 3 mJ/cm².

C: The sensitivity variation is more than 3 mJ/cm²

In Table 4, the following description indicates the following.

In the “Requirement A” column of “Compound (X)”, a case where the requirement A is satisfied is denoted as “A”, and a case where the requirement A is not satisfied is denoted as “B”. “Requirement A” means that at least one of R_{X11}, . . . , or R_{X12} in Formula (X) is a hydrocarbon group. That is, a case where at least one of R_{X11}, . . . , or R_{X12} of the compound (X) is a hydrocarbon group is denoted as “A”.

“Type of halogen atom” column shows the type of the halogen atom contained in Arₓ in Formula (X).

TABLE 4

| | Compound (X) | | | Evaluation results | |
|---|---|---|---|---|---|
| Type of resist | Type of compound (X) or | | Type of | Pattern | Temporal |
| composition | comparative compound | Requirement A | halogen atom | shape | stability |

| | | | | | |
|---|---|---|---|---|---|
| Example 1-1 | Re-1 | X-1 | A | F | A |
| Example 1-2 | Re-2 | X-2 | A | F | A |
| Example 1-3 | Re-3 | X-3 | A | F | A |
| Example 1-4 | Re-4 | X-4 | B | F | B |
| Example 1-5 | Re-5 | X-5 | A | F | A |
| Example 1-6 | Re-6 | X-6 | A | F | A |
| Example 1-7 | Re-7 | X-7 | A | F | A |
| Example 1-8 | Re-8 | X-8 | B | F | B |
| Example 1-9 | Re-9 | X-9 | A | I | A |
| Example 1-10 | Re-10 | X-10 | A | I | A |
| Example 1-11 | Re-11 | X-11 | A | I | A |
| Example 1-12 | Re-12 | X-12 | B | I | B |
| Example 1-13 | Re-13 | X-13 | A | I | A |
| Example 1-14 | Re-14 | X-14 | B | I | B |
| Example 1-15 | Re-15 | X-15 | A | I | A |
| Example 1-16 | Re-16 | X-16 | A | I | A |
| Example 1-17 | Re-17 | X-17 | A | I | A |
| Example 1-18 | Re-18 | X-18 | A | Br | A |
| Example 1-19 | Re-19 | X-19 | A | Br | A |
| Example 1-20 | Re-20 | X-20 | B | Br | B |
| Example 1-21 | Re-21 | X-21 | A | Cl | A |
| Example 1-22 | Re-22 | X-22 | A | Cl | A |
| Example 1-23 | Re-23 | X-23 | B | Cl | B |
| Example 1-24 | Re-24 | X-24 | A | Cl | A |
| Example 1-25 | Re-25 | X-4 | B | F | B |
| Example 1-26 | Re-26 | X-12 | B | I | B |
| Example 1-27 | Re-27 | X-23 | B | Cl | B |
| Example 1-28 | Re-28 | X-6 | A | F | A |
| Example 1-29 | Re-29 | X-18 | A | Br | A |
| Example 1-30 | Re-30 | X-2 | A | F | A |
| Example 1-31 | Re-31 | X-3 | A | F | A |
| Example 1-32 | Re-32 | X-14 | B | I | B |
| Example 1-33 | Re-33 | X-1 | A | F | A |
| Example 1-34 | Re-34 | X-9 | A | I | A |
| Example 1-35 | Re-35 | X-14 | B | I | B |
| Example 1-36 | Re-36 | X-4 | B | F | B |
| Example 1-37 | Re-37 | X-2 | A | F | A |
| Example 1-38 | Re-38 | X-23 | B | Cl | B |
| Example 1-39 | Re-39 | X-1 | A | F | A |
| Example 1-40 | Re-40 | X-2/X-4 | A/B | F/F | B |
| Example 1-41 | Re-41 | X-19/X-20 | A/B | Br/Br | B |
| Example 1-42 | Re-42 | X-6/X-10 | A/A | F/I | A |
| Example 1-43 | Re-43 | X-23 | B | Cl | B |
| Example 1-44 | Re-44 | X-4 | B | F | B |
| Example 1-45 | Re-45 | X-11 | A | I | A |
| Comparative | Re-C1 | Z-1 | B | — | C |
| Example 1-1 | | | | | |

From the evaluation results in Table 4, it was confirmed that a desired effect can be obtained with the resist composition of the embodiment of the present invention.

From a comparison of Examples 1-1 to 1-16, and the like vs. Examples 1-18 to 1-24, and the like, it was confirmed that in a case of an aryl group in which Ar_{X} is substituted with a group selected from the group consisting of a group including a fluorine atom and a group including an iodine atom in Formula (X), the effect of the present invention is more excellent.

From the comparison of Examples 1-1 to 1-3, 1-5 to 1-7, 1-9 to 1-11, 1-13, 1-15 to 1-19, and the like vs. Examples 1-4, 1-8, 1-12, 1-14, and the like, it was confirmed that in a case where at least one of R_{X11}, . . . , or R_{X12} is a hydrocarbon group in Formula (X), the temporal stability is more excellent.

[Pattern Formation (2): EUV Exposure and Aqueous Alkali Solution Development]

A composition for forming an underlayer film, AL412 (manufactured by Brewer Science, Inc.), was applied onto a silicon wafer and baked at 205° C. for 60 seconds to form an underlying film having a film thickness of 20 nm. A resin composition shown in Table 5 was applied thereon and baked at 100° C. for 60 seconds to form a resist film having a film thickness of 30 nm.

The silicon wafer having the obtained resist film was subjected to patternwise irradiation using an EUV exposure device (manufactured by Exitech Ltd., Micro Exposure Tool, NA 0.3, Quadrupol, outer sigma 0.68, inner sigma 0.36). Further, as a reticle, a mask having a line size=20 nm and a line:space=1:1 was used.

The resist film after the exposure was baked at 90° C. for 60 seconds, developed with an aqueous tetramethylammonium hydroxide solution (2.38% by mass) for 30 seconds, and then rinsed with pure water for 30 seconds. Thereafter, the resist film was spin-dried to obtain a positive tone pattern.

<Evaluation of Pattern Shape: EUV Exposure, Aqueous Alkali Solution Development>

A cross-sectional shape of a line pattern having a line width of 20 nm on average was observed, and a pattern line width Lb at the bottom of the resist pattern and a pattern line width La at the upper part of the resist pattern were measured using a length-measuring scanning electron microscope (SEM, S-9380II manufactured by Hitachi, Ltd.).

A case of (La/Lb)<1.03 was regarded as “Excellent”, a case of 1.03<(La/Lb)<1.06 was regarded as “Good”, and a case of 1.06<(La/Lb) was regarded as “Poor”. The results are shown in Table 5.

<Temporal Stability of Resist Composition>

The temporal stability of the resist composition was evaluated by the same procedure as that in <Temporal Stability of Resist composition> in Pattern Formation (1) mentioned above.

TABLE 5

| | Compound (X) | | | Evaluation results | |
|---|---|---|---|---|---|
| Type of resist | Type of compound (X) or | | Type of | Pattern | Temporal |
| composition | comparative compound | Requirement A | halogen atom | shape | stability |

| | | | | | |
|---|---|---|---|---|---|
| Example 2-1 | Re-1 | X-1 | A | F | A |
| Example 2-2 | Re-2 | X-2 | A | F | A |
| Example 2-3 | Re-3 | X-3 | A | F | A |
| Example 2-4 | Re-4 | X-4 | B | F | B |
| Example 2-5 | Re-5 | X-5 | A | F | A |
| Example 2-6 | Re-6 | X-6 | A | F | A |
| Example 2-7 | Re-7 | X-7 | A | F | A |
| Example 2-8 | Re-8 | X-8 | B | F | B |
| Example 2-9 | Re-9 | X-9 | A | I | A |
| Example 2-10 | Re-10 | X-10 | A | I | A |
| Example 2-11 | Re-11 | X-11 | A | I | A |
| Example 2-12 | Re-12 | X-12 | B | I | B |
| Example 2-13 | Re-13 | X-13 | A | I | A |
| Example 2-14 | Re-14 | X-14 | B | I | B |
| Example 2-15 | Re-15 | X-15 | A | I | A |
| Example 2-16 | Re-16 | X-16 | A | I | A |
| Example 2-17 | Re-17 | X-17 | A | I | A |
| Example 2-18 | Re-18 | X-18 | A | Br | A |
| Example 2-19 | Re-19 | X-19 | A | Br | A |
| Example 2-20 | Re-20 | X-20 | B | Br | B |
| Example 2-21 | Re-21 | X-21 | A | Cl | A |
| Example 2-22 | Re-22 | X-22 | A | Cl | A |
| Example 2-23 | Re-23 | X-23 | B | Cl | B |
| Example 2-24 | Re-24 | X-24 | A | Cl | A |
| Example 2-25 | Re-25 | X-4 | B | F | B |
| Example 2-26 | Re-26 | X-12 | B | I | B |
| Example 2-27 | Re-27 | X-23 | B | Cl | B |
| Example 2-28 | Re-28 | X-6 | A | F | A |
| Example 2-29 | Re-29 | X-18 | A | Br | A |
| Example 2-30 | Re-30 | X-2 | A | F | A |
| Example 2-31 | Re-31 | X-3 | A | F | A |
| Example 2-32 | Re-32 | X-14 | B | I | B |
| Example 2-33 | Re-33 | X-1 | A | F | A |
| Example 2-34 | Re-34 | X-9 | A | I | A |
| Example 2-35 | Re-35 | X-14 | B | I | B |
| Example 2-36 | Re-36 | X-4 | B | F | B |
| Example 2-37 | Re-37 | X-2 | A | F | A |
| Example 2-38 | Re-38 | X-23 | B | Cl | B |
| Example 2-39 | Re-39 | X-1 | A | F | A |
| Example 2-40 | Re-40 | X-2/X-4 | A/B | F/F | B |
| Example 2-41 | Re-41 | X-19/X-20 | A/B | Br/Br | B |
| Example 2-42 | Re-42 | X-6/X-10 | A/A | F/I | A |
| Example 2-43 | Re-43 | X-23 | B | Cl | B |
| Example 2-44 | Re-44 | X-4 | B | F | B |
| Example 2-45 | Re-45 | X-11 | A | I | A |
| Comparative | Re-C1 | Z-1 | B | — | C |
| Example 2-1 | | | | | |

From the evaluation results in Table 5, it was confirmed that a desired effect can be obtained with the resist composition of the embodiment of the present invention.

From a comparison of Examples 2-1 to 2-16, and the like vs. Examples 2-18 to 2-24, and the like, it was confirmed that in a case of an aryl group in which Ar_{X} is substituted with a group selected from the group consisting of a group including a fluorine atom and a group including an iodine atom in Formula (X), the effect of the present invention is more excellent.

From the comparison of Examples 2-1 to 2-3, 2-5 to 2-7, 2-9 to 2-11, 2-13, 2-15 to 2-19, and the like vs. Examples 2-4, 2-8, 2-12, 2-14, and the like, it was confirmed that in a case where at least one of R_{X11} or R_{X12} is a hydrocarbon group in Formula (X), the temporal stability is more excellent.

[Preparation of Resist Composition and Pattern Formation: ArF Immersion Exposure]

[Preparation (2) of Resist Composition]

The respective components shown in Table 6 were mixed so that the concentration of solid contents was 4% by mass. Then, the obtained mixed liquid was filtered initially through a polyethylene-made filter having a pore diameter of 50 nm, then through a nylon-made filter having a pore diameter of 10 nm, and lastly through a polyethylene-made filter having a pore diameter of 5 nm in this order to prepare a resist composition. The obtained resist composition was used in Examples and Comparative Examples. In addition, in the resist composition, the solid content means all the components excluding the solvent.

TABLE 6

| | | | | | Photoacid | | Acid diffusion | | Hydrophobic | | | | | |
|---|---|---|---|---|---|---|---|---|---|---|---|---|---|---|
| | Compound (X) | | Resin A | | generator B | | control agent C | | resin D | | Surfactant E | | Solvent F | |
| Resist | | % by | | % by | | % by | | % by | | % by | | % by | | Mixing |
| composition | Type | mass | Type | mass | Type | mass | Type | mass | Type | mass | Type | mass | Type | ratio |
| Re-46 | X-1 | 15.5 | A-39 | 80.3 | — | — | C-4 | 3.1 | D-3 | 1.1 | — | — | F-1/F-6 | 40/60 |
| Re-47 | X-3 | 16.6 | A-40 | 77.2 | — | — | C-1 | 2.5 | D-1 | 3.7 | — | — | F-4 | 100 |
| Re-48 | X-4 | 27.5 | A-36 | 71.5 | — | — | — | — | D-2 | 1.0 | — | — | F-1 | 100 |
| Re-49 | X-2 | 18.5 | A-41 | 68.3 | — | — | C-9 | 11.1 | D-2 | 2.1 | — | — | F-1 | 100 |
| Re-50 | X-9 | 22.3 | A-44 | 69.4 | — | — | C-5 | 7.1 | D-3 | 1.1 | E-1 | 0.1 | F-1/F-3 | 90/10 |
| Re-51 | X-12 | 34.2 | A-40/A-42 | 30.0/33.0 | — | — | — | — | D-5 | 2.7 | E-2 | 0.1 | F-1/F-2 | 70/30 |
| Re-52 | X-16 | 24.3 | A-33 | 72.1 | — | — | C-2 | 2.8 | D-4 | 0.8 | — | — | F-4 | 100 |
| Re-53 | X-20 | 20.1 | A-42 | 74.4 | — | — | C-10 | 4.6 | D-6 | 0.9 | — | — | F-1/F-8 | 85/15 |
| Re-54 | X-18 | 29.6 | A-46 | 65.2 | — | — | — | — | D-8 | 5.2 | — | — | F-1/F-2 | 70/30 |
| Re-55 | X-23 | 28.5 | A-35 | 69.8 | — | — | — | — | D-5 | 1.5 | E-1/E-2 | 0.1/0.1 | F-1/F-7 | 80/20 |
| Re-56 | X-24 | 22.1 | A-34 | 65.8 | — | — | C-12 | 8.2 | D-2 | 3.9 | — | — | F-4 | 100 |
| Re-57 | X-1/ | 9.2/9.0 | A-45 | 69.7 | — | — | C-6 | 9.2 | D-5 | 2.9 | — | — | F-1/F-9 | 90/10 |
| | X-2 | | | | | | | | | | | | | |
| Re-58 | X-8 | 38.9 | A-33 | 57.9 | — | — | — | — | D-5 | 3.2 | — | — | F-1/F-7 | 80/20 |
| Re-59 | X-4 | 31.2 | A-33/A-34 | 35.4/30.4 | — | — | — | — | D-2 | 3.0 | — | — | F-1/F-8 | 85/15 |
| Re-60 | X-7/ | 15.0/12.0 | A-34 | 64.5 | — | — | C-1l | 7.2 | D-7 | 1.3 | — | — | F-4 | 100 |
| | X-15 | | | | | | | | | | | | | |
| Re-61 | X-21 | 24.2 | A-12 | 74.6 | — | — | — | — | D-5 | 1.2 | — | — | F-1/F-5 | 50/50 |
| Re-62 | X-22 | 33.1 | A-38 | 60.5 | — | — | C-8 | 5.5 | D-4 | 0.9 | — | — | F-1 | 100 |
| Re-63 | X-5 | 23.1 | A-45 | 65.0 | — | — | C-13 | 9.1 | D-8 | 2.8 | — | — | F-1/F-2/ | 70/25/5 |
| | | | | | | | | | | | | | F-8 | |
| Re-64 | X-10 | 19.2 | A-43 | 71.2 | — | — | C-7 | 8.5 | D-4 | 1.1 | — | — | F-1/F-6 | 40/60 |
| Re-65 | X-14 | 26.2 | A-12 | 68.4 | — | — | C-3 | 4.5 | D-6 | 0.9 | — | — | F-4 | 100 |
| Re-66 | X-19 | 22.4 | A-37 | 69.0 | — | — | C-1 | 3.4 | D-6 | 5.2 | — | — | F-1 | 100 |
| Re-67 | X-1l | 26.0 | A-39 | 72.5 | — | — | — | — | D-5 | 1.5 | — | — | F-1/F-8 | 85/15 |
| Re-68 | X-17 | 29.3 | A-38 | 54.4 | — | — | C-9 | 12.5 | D-2 | 3.8 | — | — | F-7 | 100 |
| Re-69 | X-6 | 33.0 | A-37 | 64.1 | — | — | — | — | D-5 | 2.9 | — | — | F-1/F-8 | 85/15 |
| Re-70 | X-13 | 19.0 | A-41 | 72.4 | — | — | C-3 | 4.8 | D-2 | 3.8 | — | — | F-1/F-2 | 70/30 |
| Re-71 | X-4 | 30.0 | A-33 | 62.1 | B-2 | 5.4 | — | — | D-1 | 2.5 | — | — | F-1/F-5 | 50/50 |
| Re-72 | X-1 | 5.4 | A-34 | 69.4 | B-3 | 23.1 | — | — | D-1 | 2.1 | — | — | F-1/F-2 | 70/30 |
| Re-73 | X-10 | 18.5 | A-35 | 70.0 | B-13 | 10.2 | — | — | D-6 | 1.3 | — | — | F-1/F-8 | 85/15 |
| Re-74 | X-5 | 12.1 | A-33 | 78.4 | B-8 | 8.6 | — | — | D-4 | 0.9 | — | — | F-1 | 100 |
| Re-75 | X-3 | 16.0 | A-40 | 69.8 | B-5 | 6.5 | C-1 | 4.0 | D-1 | 3.7 | — | — | F-4 | 100 |
| Re-76 | X-1 | 15.5 | A-39 | 81.4 | — | — | C-4 | 3.1 | — | — | — | — | F-1/F-6 | 40/60 |
| Re-77 | X-3 | 16.6 | A-40 | 80.9 | — | — | C-1 | 2.5 | — | — | — | — | F-4 | 100 |
| Re-78 | X-4 | 27.5 | A-36 | 72.5 | — | — | — | — | — | — | — | — | F-1 | 100 |
| Re-C2 | Z-1 | 13.5 | A-39 | 82.3 | — | — | C-4 | 3.1 | D-3 | 1.1 | — | — | F-1/F-6 | 40/60 |

[Preparation of Topcoat Composition]

Various components included in the topcoat composition shown in Table 7 are shown below.

<Resin>

As the resin shown in Table 7, resins PT-1 to PT-3 shown in Table 2 were used.

<Additive>

The structures of the additives shown in Table 7 are shown below.

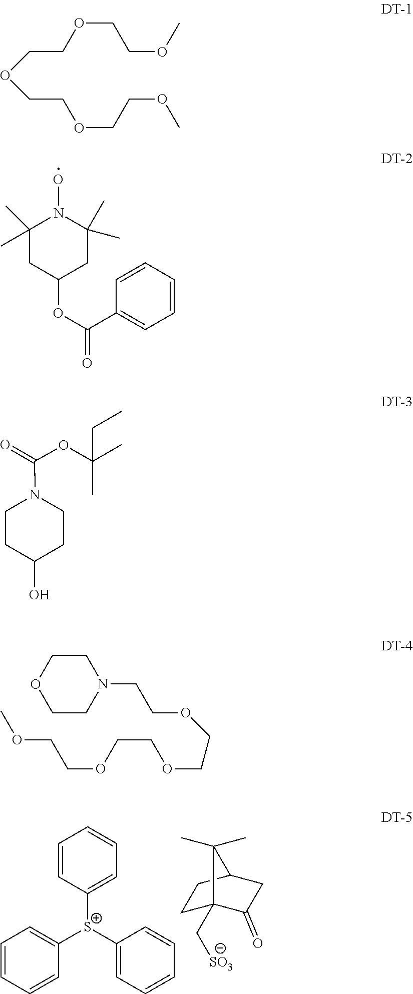

<Surfactant>

Surfactants shown in Table 7 are shown below.

E-3: PF656 (manufactured by OMNOVA Solutions Inc., fluorine-based surfactant)

<Solvent>

Solvents shown in Table 7 are shown below.

FT-1: 4-Methyl-2-pentanol (MIBC)

FT-2: n-Decane

FT-3: Diisoamyl ether

<Preparation of Topcoat Composition>

The respective components shown in Table 7 were mixed so that the concentration of solid contents was 3% by mass, and then the obtained mixed liquid was filtered initially through a polyethylene-made filter having a pore diameter of 50 nm, then through a nylon-made filter having a pore diameter of 10 nm, and lastly through a polyethylene-made filter having a pore diameter of 5 nm in this order to prepare a topcoat composition. The obtained topcoat composition was used in Examples. Furthermore, the solid content means all the components excluding the solvent.

TABLE 7

| | Topcoat composition | | | | | | | |
|---|---|---|---|---|---|---|---|---|
| | Resin | | Additive | | Surfactant | | | Mixing ratio |
| | Type | Mass (g) | Type | Mass (g) | Type | Mass (g) | Type | (mass ratio) |
| TC-1 | PT-1 | 10.0 | DT-1/DT-2 | 1.3/0.06 | — | — | FT-1/FT-2 | 70/30 |
| TC-2 | PT-2 | 10.0 | DT-3/DT-4 | 0.04/0.06 | E-3 | 0.005 | FT-1/FT-3 | 75/25 |
| TC-3 | PT-3 | 10.0 | DT-5 | 0.05 | — | — | FT-1/FT-3 | 10/90 |

[Pattern Formation (3): ArF Liquid Immersion Exposure and Organic Solvent Development]

A composition for forming an organic antireflection film, ARC29SR (manufactured by Brewer Science, Inc.), was applied onto a silicon wafer and baked at 205° C. for 60 seconds to form an antireflection film having a film thickness of 98 nm. The resin composition shown in Table 8 was applied thereon and baked at 100° C. for 60 seconds to form a resist film (actinic ray-sensitive or radiation-sensitive film) having a film thickness of 90 nm. In Examples 3-31 to 3-33, a topcoat film was formed on the upper layer of the resist film (the types of topcoat compositions used are shown in Table 8). The film thickness of the topcoat film was 100 nm in any case.

The resist film was exposed through a 6% halftone mask having a 1:1 line-and-space pattern with a line width of 45 nm, using an ArF excimer laser liquid immersion scanner (XT1700i, manufactured by ASML, NA 1.20, Dipole, outer sigma: 0.950, inner sigma: 0.850, Y deflection). Ultrapure water was used as the immersion liquid.

The resist film after the exposure was baked at 90° C. for 60 seconds, developed with n-butyl acetate for 30 seconds, and then rinsed with 4-methyl-2-pentanol for 30 seconds. Then, the film was spin-dried to obtain a negative tone pattern.

<Evaluation of Pattern Shape: ArF Liquid Immersion Exposure and Organic Solvent Development>

A cross-sectional shape of a line pattern having a line width of 45 nm on average was observed, and a pattern line width Lb at the bottom of the resist pattern and a pattern line width La at the upper part of the resist pattern were measured using a length-measuring scanning electron microscope (SEM, S-9380II manufactured by Hitachi, Ltd.).

A case of (Lb/La)≤1.03 was regarded as “Excellent”, a case of 1.03<(Lb/La)≤1.06 was regarded as “Good”, and a case of 1.06<(Lb/La) was regarded as “Poor”. The results are shown in Table 8.

<Temporal Stability of Resist composition>

The temporal stability of the resist composition was evaluated by the same procedure as that in <Temporal Stability of Resist composition> in Pattern Formation (1) mentioned above, except that the resist composition was changed.

TABLE 8

| | | Compound (X) | | | Evaluation results | |
|---|---|---|---|---|---|---|
| Type of resist | Type of topcoat | Type of compound (X) or | | Type of | Pattern | Temporal |
| composition | composition | comparative compound | Requirement A | halogen atom | shape | stability |

| | | | | | | |
|---|---|---|---|---|---|---|
| Example 3-1 | Re-46 | — | X-1 | A | F | A |
| Example 3-2 | Re-47 | — | X-3 | A | F | A |
| Example 3-3 | Re-48 | — | X-4 | B | F | B |
| Example 3-4 | Re-49 | — | X-2 | A | F | A |
| Example 3-5 | Re-50 | — | X-9 | A | I | A |
| Example 3-6 | Re-51 | — | X-12 | B | I | B |
| Example 3-7 | Re-52 | — | X-16 | A | I | A |
| Example 3-8 | Re-53 | — | X-20 | B | Br | B |
| Example 3-9 | Re-54 | — | X-18 | A | Br | A |
| Example 3-10 | Re-55 | — | X-23 | B | Cl | A |
| Example 3-11 | Re-56 | — | X-24 | A | Cl | A |
| Example 3-12 | Re-57 | — | X-1/X-2 | A/A | F/F | A |
| Example 3-13 | Re-58 | — | X-8 | B | F | B |
| Example 3-14 | Re-59 | — | X-4 | B | F | B |
| Example 3-15 | Re-60 | — | X-7/X-15 | A/A | F/F | A |
| Example 3-16 | Re-61 | — | X-21 | A | Cl | A |
| Example 3-17 | Re-62 | — | X-22 | A | Cl | A |
| Example 3-18 | Re-63 | — | X-5 | A | F | A |
| Example 3-19 | Re-64 | — | X-10 | A | I | A |
| Example 3-20 | Re-65 | — | X-14 | B | I | B |
| Example 3-21 | Re-66 | — | X-19 | A | Br | A |
| Example 3-22 | Re-67 | — | X-1l | A | I | A |
| Example 3-23 | Re-68 | — | X-17 | A | I | A |
| Example 3-24 | Re-69 | — | X-6 | A | F | A |
| Example 3-25 | Re-70 | — | X-13 | A | I | A |
| Example 3-26 | Re-71 | — | X-4 | B | F | B |
| Example 3-27 | Re-72 | — | X-1 | A | F | A |
| Example 3-28 | Re-73 | — | X-10 | A | I | A |
| Example 3-29 | Re-74 | — | X-5 | A | F | A |
| Example 3-30 | Re-75 | — | X-3 | A | F | A |
| Example 3-31 | Re-76 | TC-1 | X-1 | A | F | A |
| Example 3-32 | Re-77 | TC-2 | X-3 | A | F | A |
| Example 3-33 | Re-78 | TC-3 | X-4 | A | F | B |
| Comparative | Re-C2 | — | Z-1 | B | — | C |
| Example 3-1 | | | | | | |

From the evaluation results in Table 8, it was confirmed that a desired effect can be obtained with the resist composition of the embodiment of the present invention.

From a comparison of Examples 3-1 to 3-7, and the like vs. Examples 3-8 to 3-11, and the like, it was confirmed that in a case of an aryl group in which Ar_{X} is substituted with a group selected from the group consisting of a group including a fluorine atom and a group including an iodine atom in Formula (X), the effect of the present invention is more excellent.

From a comparison of Examples 3-1, 3-2, 3-4, 3-5, 3-7, and the like vs. Examples 3-3, 3-6, 3-8, and the like, it was confirmed that in a case where at least one of R_{X11} or R_{X12} is a hydrocarbon group in Formula (X), the temporal stability is more excellent.

[Pattern Formation (4): ArF Liquid Immersion Exposure and Aqueous Alkali Solution Development]

A composition for forming an organic antireflection film, ARC29SR (manufactured by Brewer Science, Inc.), was applied onto a silicon wafer and baked at 205° C. for 60 seconds to form an antireflection film having a film thickness of 98 nm. A resin composition shown in Table 9 was applied thereon and baked at 100° C. for 60 seconds to form a resist film having a film thickness of 90 nm. In Examples 4-31 to 4-33, a topcoat film was formed on the upper layer of the resist film (the types of topcoat compositions used are shown in Table 9). The film thickness of the topcoat film was 100 nm in any case.

The resist film was exposed through a 6% halftone mask having a 1:1 line-and-space pattern with a line width of 45 nm, using an ArF excimer laser liquid immersion scanner (XT1700i, manufactured by ASML, NA 1.20, Dipole, outer sigma: 0.950, inner sigma: 0.890, Y deflection). Ultrapure water was used as the immersion liquid.

The resist film after the exposure was baked at 90° C. for 60 seconds, developed with an aqueous tetramethylammonium hydroxide solution (2.38% by mass) for 30 seconds, and then rinsed with pure water for 30 seconds. Thereafter, the resist film was spin-dried to obtain a positive tone pattern.

<Evaluation of Pattern Shape: ArF Liquid Immersion Exposure, Aqueous Alkali Solution Development>

A cross-sectional shape of a line pattern having a line width of 45 nm on average was observed, and a pattern line width Lb at the bottom of the resist pattern and a pattern line width La at the upper part of the resist pattern were measured using a length-measuring scanning electron microscope (SEM, S-9380II manufactured by Hitachi, Ltd.).

A case of (La/Lb)≤1.03 was regarded as “Excellent”, a case of 1.03<(La/Lb)≤1.06 was regarded as “Good”, and a case of 1.06<(La/Lb) was regarded as “Poor”. The results are shown in Table 9.

<Temporal Stability of Resist Composition>

The temporal stability of the resist composition was evaluated by the same procedure as that in <Temporal Stability of Resist composition> in Pattern Formation (1) mentioned above, except that the resist composition was changed.

TABLE 9

| | | Compound (X) | | | Evaluation results | |
|---|---|---|---|---|---|---|
| Type of resist | Type of topcoat | Type of compound (X) or | | Type of | Pattern | Temporal |
| composition | composition | comparative compound | Requirement A | halogen atom | shape | stability |

| | | | | | | |
|---|---|---|---|---|---|---|
| Example 4-1 | Re-46 | — | X-1 | A | F | A |
| Example 4-2 | Re-47 | — | X-3 | A | F | A |
| Example 4-3 | Re-48 | — | X-4 | B | F | B |
| Example 4-4 | Re-49 | — | X-2 | A | F | A |
| Example 4-5 | Re-50 | — | X-9 | A | I | A |
| Example 4-6 | Re-51 | — | X-12 | B | I | B |
| Example 4-7 | Re-52 | — | X-16 | A | I | A |
| Example 4-8 | Re-53 | — | X-20 | B | Br | B |
| Example 4-9 | Re-54 | — | X-18 | A | Br | A |
| Example 4-10 | Re-55 | — | X-23 | B | Cl | B |
| Example 4-11 | Re-56 | — | X-24 | A | Cl | A |
| Example 4-12 | Re-57 | — | X-1/X-2 | A/A | F/F | A |
| Example 4-13 | Re-58 | — | X-8 | B | F | B |
| Example 4-14 | Re-59 | — | X-4 | B | F | B |
| Example 4-15 | Re-60 | — | X-7/X-15 | A/A | F/F | A |
| Example 4-16 | Re-61 | — | X-21 | A | Cl | A |
| Example 4-17 | Re-62 | — | X-22 | A | Cl | A |
| Example 4-18 | Re-63 | — | X-5 | A | F | A |
| Example 4-19 | Re-64 | — | X-10 | A | I | A |
| Example 4-20 | Re-65 | — | X-14 | B | I | B |
| Example 4-21 | Re-66 | — | X-19 | A | Br | A |
| Example 4-22 | Re-67 | — | X-11 | A | I | A |
| Example 4-23 | Re-68 | — | X-17 | A | I | A |
| Example 4-24 | Re-69 | — | X-6 | A | F | A |
| Example 4-25 | Re-70 | — | X-13 | A | I | A |
| Example 4-26 | Re-71 | — | X-4 | B | F | B |
| Example 4-27 | Re-72 | — | X-1 | A | F | A |
| Example 4-28 | Re-73 | — | X-10 | A | I | A |
| Example 4-29 | Re-74 | — | X-5 | A | F | A |
| Example 4-30 | Re-75 | — | X-3 | A | F | A |
| Example 4-31 | Re-76 | TC-1 | X-1 | A | F | A |
| Example 4-32 | Re-77 | TC-2 | X-3 | A | F | A |
| Example 4-33 | Re-78 | TC-3 | X-4 | B | F | B |
| Comparative | Re-C2 | — | Z-1 | B | — | C |
| Example 4-1 | | | | | | |

From the evaluation results in Table 9, it was confirmed that a desired effect can be obtained with the resist composition of the embodiment of the present invention.

From a comparison of Examples 4-1 to 4-7, and the like vs. Examples 4-8 to 4-11, and the like, it was confirmed that in a case of an aryl group in which Ar_{X} is substituted with a group selected from the group consisting of a group including a fluorine atom and a group including an iodine atom in Formula (X), the effect of the present invention is more excellent.

From a comparison of Examples 4-1, 4-2, 4-4, 4-5, 4-7, and the like vs. Examples 4-3, 4-6, 4-8, and the like, it was confirmed that in a case where at least one of R_{X11} or R_{X12} is a hydrocarbon group in Formula (X), the temporal stability is more excellent.

What is claimed is:

1. An actinic ray-sensitive or radiation-sensitive resin composition comprising:
a salt including a cation represented by Formula (X); and
a resin of which polarity increases through decomposition by an action of an acid, 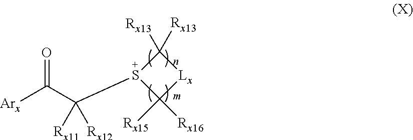
in Formula (X), Ar_{X} represents an aryl group substituted with a group including a halogen atom, the aryl group may be substituted with a substituent including no halogen atom, R_{X11} to R_{X16} each independently represent a hydrogen atom or a hydrocarbon group, L_{X} represents a divalent linking group, and n and m each independently represent an integer of 1 or more.

2. The actinic ray-sensitive or radiation-sensitive resin composition according to claim 1,
wherein in Formula (X), Ar_{X} is an aryl group substituted with a group selected from the group consisting of a group including a fluorine atom and a group including an iodine atom.

3. The actinic ray-sensitive or radiation-sensitive resin composition according to claim 1,
wherein in Formula (X), L_{X} is a divalent linking group including an oxygen atom.

4. The actinic ray-sensitive or radiation-sensitive resin composition according to claim 1,
wherein in Formula (X), at least one of R_{X11}, . . . , or R_{X12} is a hydrocarbon group.

5. The actinic ray-sensitive or radiation-sensitive resin composition according to claim 1,
wherein the salt including the cation represented by Formula (X) is at least one selected from the group consisting of the compounds (I) and (II),
compound (I):
a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation,
structural site X: a structural site which consists of an anionic site A₁⁻ and a cationic site M₁⁺, and forms a first acidic site represented by HA₁ upon irradiation with actinic rays or radiation,
structural site Y: a structural site which consists of an anionic site A₂⁻ and a cationic site M₂⁺, and forms a second acidic site represented by HA₂ upon irradiation with actinic rays or radiation,
provided that at least one of the cationic site M₁⁺ in one or more structural sites X or the cationic site M₂⁺ in one or more structural sites Y represents the cation represented by Formula (X), and
the compound (I) satisfies the following condition I:
condition I: a compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1,
compound (II):
a compound having two or more sites of the structural site X and one or more sites of the following structural site Z, the compound generating an acid including two or more sites of the first acidic site derived from the structural site X and the structural site Z upon irradiation with actinic rays or radiation,
structural site Z: a nonionic site capable of neutralizing an acid,
provided that at least one of the cationic sites M₁⁺ in the two or more structural sites X represents a cation represented by Formula (X).

6. The actinic ray-sensitive or radiation-sensitive resin composition according to claim 1,
wherein the resin of which polarity increases through decomposition by the action of an acid includes an acid group.

7. The actinic ray-sensitive or radiation-sensitive resin composition according to claim 1,
wherein the resin of which polarity increases through decomposition by the action of an acid includes a repeating unit having an acid group.

8. The actinic ray-sensitive or radiation-sensitive resin composition according to claim 1, further comprising a solvent.

9. A resist film formed of the actinic ray-sensitive or radiation-sensitive resin composition according to claim 1.

10. A pattern forming method comprising:
a step of forming a resist film on a substrate using the actinic ray-sensitive or radiation-sensitive resin composition according to claim 1;
a step of exposing the resist film; and
a step of developing the exposed resist film using a developer.

11. A method for manufacturing an electronic device, comprising the pattern forming method according to claim 10.

12. The actinic ray-sensitive or radiation-sensitive resin composition according to claim 2,
wherein in Formula (X), L_{X} is a divalent linking group including an oxygen atom.

13. The actinic ray-sensitive or radiation-sensitive resin composition according to claim 2,
wherein in Formula (X), at least one of R_{X11}, . . . , or R_{X12} is a hydrocarbon group.

14. The actinic ray-sensitive or radiation-sensitive resin composition according to claim 2,
wherein the salt including the cation represented by Formula (X) is at least one selected from the group consisting of the compounds (I) and (II),
compound (I):
a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation,
structural site X: a structural site which consists of an anionic site A₁⁻ and a cationic site M₁⁺, and forms a first acidic site represented by HA₁ upon irradiation with actinic rays or radiation,
structural site Y: a structural site which consists of an anionic site A₂⁻ and a cationic site M₂⁺, and forms a second acidic site represented by HA₂ upon irradiation with actinic rays or radiation,
provided that at least one of the cationic site M₁⁺ in one or more structural sites X or the cationic site M₂⁺ in one or more structural sites Y represents the cation represented by Formula (X), and
the compound (I) satisfies the following condition I:
condition I: a compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1,
compound (II):
a compound having two or more sites of the structural site X and one or more sites of the following structural site Z, the compound generating an acid including two or more sites of the first acidic site derived from the structural site X and the structural site Z upon irradiation with actinic rays or radiation,
structural site Z: a nonionic site capable of neutralizing an acid,
provided that at least one of the cationic sites M₁⁺ in the two or more structural sites X represents a cation represented by Formula (X).

15. The actinic ray-sensitive or radiation-sensitive resin composition according to claim 2,
wherein the resin of which polarity increases through decomposition by the action of an acid includes an acid group.

16. The actinic ray-sensitive or radiation-sensitive resin composition according to claim 2,
wherein the resin of which polarity increases through decomposition by the action of an acid includes a repeating unit having an acid group.

17. The actinic ray-sensitive or radiation-sensitive resin composition according to claim 2, further comprising a solvent.

18. A resist film formed of the actinic ray-sensitive or radiation-sensitive resin composition according to claim 2.

19. A pattern forming method comprising:
a step of forming a resist film on a substrate using the actinic ray-sensitive or radiation-sensitive resin composition according to claim 2;
a step of exposing the resist film; and
a step of developing the exposed resist film using a developer.

20. A method for manufacturing an electronic device, comprising the pattern forming method according to claim 19.
